(19) United States
(12) Patent Application Publication
(10) Pub. No.: US 2021/0125988 A1
(43) Pub. Date: Apr. 29, 2021

(54) Semiconductor Device and Method for Manufacturing Semiconductor Device

(71) Applicant: Semiconductors Energy Laboratory Co., Ltd., Kanagawa-ken (JP)

(72) Inventors: Shunpei YAMAZAKI, Setagaya, Tokyo (JP); Toshihiko TAKEUCHI, Atsugi, Kanagawa (JP); Naoto YAMADE, Isehara, Kanagawa (JP); Hiroshi FUJIKI, Kudamatsu, Yamaguchi (JP); Yuki HATA, Atsugi, Kanagawa (JP); Shuhei NAGATSUKA, Atsugi, Kanagawa (JP)

(73) Assignee: Semiconductors Energy Laboratory Co., Ltd., Kanagawa-ken (JP)

(21) Appl. No.: 16/491,969

(22) PCT Filed: Feb. 27, 2018
(86) PCT No.: PCT/IB2018/051203

§ 371 Date: Sep. 6, 2019

(30) Foreign Application Priority Data
Mar. 13, 2017 (JP) 2017-047924
Mar. 31, 2017 (JP) 2017-072185

(51) Int. Cl. H01L 27/105; H01L 27/12; H01L 29/24; H01L 29/786; H01L 21/02; H01L 29/66

(52) U.S. Cl. CPC H01L 27/1052; H01L 27/1207; H01L 27/1225; H01L 27/124; H01L 27/1255; H01L 29/66969; H01L 29/24; H01L 29/78648; H01L 29/7869; H01L 21/02565; H01L 27/127

(57) ABSTRACT

A semiconductor device that can be miniaturized or highly integrated is provided.

The semiconductor device includes an oxide in a channel formation region; the semiconductor device includes a first transistor, a second transistor, a first wiring, a second wiring, and a third wiring, and the first transistor includes the oxide over a first insulator, a second insulator over the oxide, a first conductor over the second insulator, a third insulator over the first conductor, and a fourth insulator in contact with the second insulator, the first conductor, and the third insulator. The second transistor includes the oxide over a fifth insulator, a sixth insulator over the oxide, a second conductor over the sixth insulator, a seventh insulator over the second conductor, and an eighth insulator in contact with the sixth insulator, the second conductor, and the seventh insulator.

### TECHNICAL FIELD

One embodiment of the present invention relates to a semiconductor device and a driving method of the semiconductor device. Alternatively, one embodiment of the present invention relates to a semiconductor wafer, a module, and an electronic device.

Note that in this specification and the like, a semiconductor device generally means a device that can function by utilizing semiconductor characteristics. As well as a semiconductor element such as a transistor, a semiconductor circuit, an arithmetic unit, and a memory device are each an embodiment of a semiconductor device. In some cases, it can be said that a display device (e.g., a liquid crystal display device and a light-emitting display device), a projection device, a lighting device, an electro-optical device, a power storage device, a memory device, a semiconductor circuit, an imaging device, an electronic device, and the like each include a semiconductor device.

Note that one embodiment of the present invention is not limited to the above technical field. One embodiment of the invention disclosed in this specification and the like relates to an object, a method, or a manufacturing method. Alternatively, one embodiment of the present invention relates to a process, a machine, manufacture, or a composition of matter.

### BACKGROUND ART

Silicon-based semiconductor materials are widely known as semiconductor thin films which can be used in transistors; oxide semiconductors have been attracting attention as other materials. Not only single-component metal oxides, such as indium oxide and zinc oxide, but also multi-component metal oxides are known as oxide semiconductors, for example. Among the multi-component metal oxides, in particular, an In—Ga—Zn oxide (hereinafter also referred to as IGZO) has been actively studied.

From the studies on IGZO, in an oxide semiconductor, a CAAC (c-axis aligned crystalline) structure and an nc (nanocrystalline) structure, which are not single crystal nor amorphous, have been found (see Non-Patent Document 1 to Non-Patent Document 3). In Non-Patent Document 1 and Non-Patent Document 2, a technique for forming a transistor using an oxide semiconductor having a CAAC structure is disclosed. Moreover, Non-Patent Document 4 and Non-Patent Document 5 show that a fine crystal is included even in an oxide semiconductor which has lower crystallinity than the CAAC structure and the nc structure.

In addition, a transistor which uses IGZO as an active layer has an extremely low off-state current (see Non-Patent Document 6), and an LSI and a display utilizing the characteristics have been reported (see Patent Document 1, Patent Document 2, Patent Document 3, Non-Patent Document 7, and Non-Patent Document 8).

### REFERENCES

### Patent Documents

[Patent Document 1] Japanese Published Patent Application No. 2007-123861
[Patent Document 2] Japanese Published Patent Application No. 2007-96055
[Patent Document 3] Japanese Published Patent Application No. 2011-119674

### Non-Patent Documents

[Non-Patent Document 1] S. Yamazaki et al., “SID Symposium Digest of Technical Papers”, 2012, volume 43, issue 1, pp. 183-186.
[Non-Patent Document 2] S. Yamazaki et al., “Japanese Journal of Applied Physics”, 2014, volume 53, Number 4S, pp. 04ED18-1-04ED18-10.
[Non-Patent Document 3] S. Ito et al., “The Proceedings of AM-FPD′13 Digest of Technical Papers”, 2013, pp. 151-154.
[Non-Patent Document 4] S. Yamazaki et al., “ECS Journal of Solid State Science and Technology”, 2014, volume 3, issue 9, pp. Q3012-Q3022.
[Non-Patent Document 5] S. Yamazaki, “ECS Transactions”, 2014, volume 64, issue 10, pp. 155-164.
[Non-Patent Document 6] K. Kato et al., “Japanese Journal of Applied Physics”, 2012, volume 51, pp. 021201-1-021201-7.
[Non-Patent Document 7] S. Matsuda et al., “2015 Symposium on VLSI Technology Digest of Technical Papers”, 2015, pp. T216-T217.
[Non-Patent Document 8] S. Amano et al., “SID Symposium Digest of Technical Papers”, 2010, volume 41, issue 1, pp. 626-629.

### SUMMARY OF THE INVENTION

### Problems to be Solved by the Invention

By the way, the integration of integrated circuits and miniaturization of transistors have progressed with an increase in performance, a reduction in size, or a reduction in weight of electronic devices. At the same time, the process rule for fabricating a transistor has decreased year by year: 45 nm, 32 nm, and 22 nm. This requires transistors including oxide semiconductors to exhibit favorable electrical characteristics as designed even when they have minute structures.

An object of one embodiment of the present invention is to provide a semiconductor device that can be miniaturized or highly integrated. Alternatively, an object of one embodiment of the present invention is to provide a semiconductor device having favorable electrical characteristics. Alternatively, an object of one embodiment of the present invention is to provide a semiconductor device with low off-state current. Alternatively, an object of one embodiment of the present invention is to provide a transistor with high on-state current. Alternatively, an object of one embodiment of the present invention is to provide a highly reliable semiconductor device. Alternatively, an object of one embodiment of the present invention is to provide a semiconductor device with reduced power consumption. Alternatively, an object of one embodiment of the present invention is to provide a semiconductor device with high productivity.

Alternatively, an object of one embodiment of the present invention is to provide a semiconductor device capable of retaining data for a long time. Alternatively, an object of one embodiment of the present invention is to provide a semiconductor device capable of high-speed data writing. Alternatively, an object of one embodiment of the present invention is to provide a semiconductor device with high design flexibility. Alternatively, an object of one embodiment of the present invention is to provide a semiconductor device in which power consumption can be reduced. Alternatively, an object of one embodiment of the present invention is to provide a novel semiconductor device.

Note that the descriptions of these objects do not disturb the existence of other objects. In one embodiment of the present invention, there is no need to achieve all the objects. Objects other than these will be apparent from the descriptions of the specification, the drawings, the claims, and the like, and can be derived from the descriptions of the specification, the drawings, the claims, and the like.

### Means for Solving the Problems

One embodiment of the present invention is a transistor using an oxide semiconductor, in which an insulator is positioned over a gate electrode and in contact with a side surface of the gate electrode and a side surface of a gate insulating film. Note that the insulator is preferably formed by a sputtering method. When the insulator is formed by a sputtering method, a good-quality insulator in which hydrogen is reduced can be obtained. The provision of such an insulator in contact with the side surface of the gate insulating film can prevent outward diffusion of oxygen in the gate insulating film and can prevent entry of impurities such as water or hydrogen into the gate insulating film. In addition, oxidation of the gate electrode can be prevented because the insulator is positioned so as to cover the top of the gate electrode and the side surface of the gate electrode.

In one embodiment of the present invention, an insulating film is provided, a contact hole in contact with the insulating film is formed, and a source electrode connected to a source region and a drain electrode connected to a drain region of a transistor are positioned in the contact hole so as to be close to each other, whereby parasitic resistance of the source region and the drain region can be reduced and favorable electrical characteristics can be obtained. Furthermore, with the miniaturization of the transistor, transistors can be arranged at high density and a semiconductor device can be reduced in size.

One embodiment of the present invention is a semiconductor device including an oxide in a channel formation region. The semiconductor device includes a first transistor, a second transistor, a first wiring, a second wiring, and a third wiring; the first transistor includes the oxide over a first insulator, a second insulator over the oxide, a first conductor over the second insulator, a third insulator over the first conductor, and a fourth insulator in contact with the second insulator, the first conductor, and the third insulator; the second transistor includes the oxide over the first insulator, a fifth insulator over the oxide, a second conductor over the fifth insulator, a sixth insulator over the second conductor, and a seventh insulator in contact with the fifth insulator, the second conductor, and the sixth insulator; and the oxide includes first regions overlapping with the second insulator and the fifth insulator, second regions overlapping with the fourth insulator and the seventh insulator, third regions in contact with the second regions, and a fourth region that is in contact with the second regions and is provided between the first conductor and the second conductor. The first wiring is electrically connected to the third region of the first transistor, the second wiring is electrically connected to the third region of the second transistor, and the third wiring is in contact with the fourth insulator and the seventh insulator and is electrically connected to the fourth region.

The oxide preferably contains In, an element M (M is Al, Ga, Y, or Sn), and Zn.

The third regions and the fourth region preferably have higher carrier density than the second regions, and the second regions preferably have higher carrier density than the first regions.

The fourth insulator and the seventh insulator may be each one or more selected from aluminum oxide, silicon oxynitride, and silicon nitride.

In each of the fourth insulator and the seventh insulator, silicon oxynitride, aluminum oxide, and silicon nitride are preferably stacked in this order.

One embodiment of the present invention is a memory device in which the above semiconductor device and a semiconductor device including silicon in a channel formation region are electrically connected to each other.

One embodiment of the present invention is a semiconductor device including an oxide in a channel formation region. The semiconductor device includes a first transistor, a second transistor, a first wiring, a second wiring, and a third wiring; the first transistor includes the oxide over the first insulator, a second insulator over the oxide, a first conductor over the second insulator, a third insulator over the first conductor, a fourth insulator in contact with the second insulator, the first conductor, and the third insulator, and a fifth insulator in contact with the fourth insulator; the second transistor includes the oxide over the first insulator, a sixth insulator over the oxide, a second conductor over the sixth insulator, a seventh insulator over the second conductor, an eighth insulator in contact with the sixth insulator, the second conductor, and the seventh insulator, and a ninth insulator in contact with the eighth insulator; and the oxide includes first regions overlapping with the second insulator and the sixth insulator, second regions overlapping with the fourth insulator and the eighth insulator, third regions in contact with the second regions, and fourth regions in contact with the third regions. The first wiring is electrically connected to the fourth region of the first transistor, the second wiring is electrically connected to the fourth region of the second transistor, and the third wiring is in contact with the fifth insulator and the ninth insulator and is electrically connected to the fourth region.

The oxide preferably contains In, an element M (M is Al, Ga, Y, or Sn), and Zn.

One embodiment of the present invention is the semiconductor device in which the fourth regions have higher carrier density than the third regions, the third regions have higher carrier density than the second regions, and the second regions have higher carrier density than the first regions.

Each of the fourth insulator and the eighth insulator preferably contains a metal oxide.

The fifth insulator and the ninth insulator may be each one or more selected from aluminum oxide, silicon oxide, silicon oxynitride, silicon nitride oxide, and silicon nitride.

In each of the fifth insulator and the ninth insulator, silicon oxynitride and silicon nitride are preferably stacked in this order.

One embodiment of the present invention is a memory device in which the above semiconductor device and a semiconductor device including silicon in a channel formation region are electrically connected to each other.

One embodiment of the present invention is a method for manufacturing a semiconductor device in which a first insulator is formed over a substrate; an oxide layer is formed over the first insulator; a first insulating film, a first conductive film, and a second insulating film are formed in this order over the oxide layer; the first insulating film, the first conductive film, and the second insulating film are processed to form a second insulator, a third insulator, a first conductor, a second conductor, a fourth insulator, and a fifth insulator; a third insulating film and a fourth insulating film are formed in this order so as to cover the first insulator, the oxide layer, the second insulator, the third insulator, the first conductor, the second conductor, the fourth insulator, and the fifth insulator; the third insulating film and the fourth insulating film are processed to form a sixth insulator, a seventh insulator, an eighth insulator in contact with the sixth insulator, and a ninth insulator in contact with the seventh insulator; a fifth insulating film is formed so as to cover the first insulator, the oxide layer, the eighth insulator, and the ninth insulator; the fifth insulating film is processed to form a tenth insulator in contact with a side surface of the eighth insulator and an eleventh insulator in contact with a side surface of the ninth insulator; a twelfth insulator is formed over the first insulator, the oxide layer, the tenth insulator, and the eleventh insulator; a first opening, a second opening, and a third opening are formed in the twelfth insulator; the second conductor is formed so as to fill the first opening and a third conductor is formed so as to fill the second opening; and a fourth conductor is formed so as to fill the third opening.

One embodiment of the present invention is the method for manufacturing a semiconductor device in which the first opening is formed so as to expose part of the tenth insulator, a top surface of the oxide layer, and at least part of a side surface of the oxide layer; the second opening is formed so as to expose part of the eleventh insulator, the top surface of the oxide layer, and at least part of a side surface of the oxide layer; the third opening is formed so as to expose part of the tenth insulator, part of the eleventh insulator, the top surface of the oxide layer, and at least part of a side surface of the oxide layer; and the third opening is formed between the first opening and the second opening.

One embodiment of the present invention is the method for manufacturing a semiconductor device in which the third insulating film and the fourth insulating film are processed by anisotropic etching utilizing a dry etching method.

One embodiment of the present invention is the method for manufacturing a semiconductor device in which the fifth insulating film is processed by anisotropic etching utilizing a dry etching method.

### Effect of the Invention

One embodiment of the present invention can provide a semiconductor device that can be miniaturized or highly integrated. Alternatively, one embodiment of the present invention can provide a semiconductor device having favorable electrical characteristics. Alternatively, one embodiment of the present invention can provide a semiconductor device with low off-state current. Alternatively, one embodiment of the present invention can provide a transistor with high on-state current. Alternatively, one embodiment of the present invention can provide a highly reliable semiconductor device. Alternatively, one embodiment of the present invention can provide a semiconductor device with reduced power consumption. Alternatively, one embodiment of the present invention can provide a semiconductor device with high productivity.

Alternatively, a semiconductor device capable of retaining data for a long time can be provided. Alternatively, a semiconductor device capable of high-speed data writing can be provided. Alternatively, a semiconductor device with high design flexibility can be provided. Alternatively, a semiconductor device in which power consumption can be reduced can be provided. Alternatively, a novel semiconductor device can be provided.

Note that the descriptions of these effects do not disturb the existence of other effects. In one embodiment of the present invention, there is no need to have all the effects. Effects other than these will be apparent from the descriptions of the specification, the drawings, the claims, and the like, and can be derived from the descriptions of the specification, the drawings, the claims, and the like.

### BRIEF DESCRIPTION OF THE DRAWINGS

FIG. 1 A top view and cross-sectional views of a semiconductor device of one embodiment of the present invention.

FIG. 2 A top view and cross-sectional views of a semiconductor device of one embodiment of the present invention.

FIG. 3 A cross-sectional view of a semiconductor device of one embodiment of the present invention.

FIG. 4 A top view and cross-sectional views illustrating a method for manufacturing a semiconductor device of one embodiment of the present invention.

FIG. 5 A top view and cross-sectional views illustrating a method for manufacturing a semiconductor device of one embodiment of the present invention.

FIG. 6 A top view and cross-sectional views illustrating a method for manufacturing a semiconductor device of one embodiment of the present invention.

FIG. 7 A top view and cross-sectional views illustrating a method for manufacturing a semiconductor device of one embodiment of the present invention.

FIG. 8 A top view and cross-sectional views illustrating a method for manufacturing a semiconductor device of one embodiment of the present invention.

FIG. 9 A top view and cross-sectional views illustrating a method for manufacturing a semiconductor device of one embodiment of the present invention.

FIG. 10 A top view and cross-sectional views illustrating a method for manufacturing a semiconductor device of one embodiment of the present invention.

FIG. 11 A top view and cross-sectional views illustrating a method for manufacturing a semiconductor device of one embodiment of the present invention.

FIG. 12 A top view and cross-sectional views illustrating a method for manufacturing a semiconductor device of one embodiment of the present invention.

FIG. 13 A top view and cross-sectional views illustrating a method for manufacturing a semiconductor device of one embodiment of the present invention.

FIG. 14 A top view and cross-sectional views illustrating a method for manufacturing a semiconductor device of one embodiment of the present invention.

FIG. 15 A top view and cross-sectional views of a semiconductor device of one embodiment of the present invention.

FIG. 16 A top view and cross-sectional views of a semiconductor device of one embodiment of the present invention.

FIG. 17 A top view and cross-sectional views of a semiconductor device of one embodiment of the present invention.

FIG. 18 A top view and cross-sectional views of a semiconductor device of one embodiment of the present invention.

FIG. 19 A cross-sectional view of a semiconductor device of one embodiment of the present invention.

FIG. 20 A top view and cross-sectional views illustrating a method for manufacturing a semiconductor device of one embodiment of the present invention.

FIG. 21 A top view and cross-sectional views illustrating a method for manufacturing a semiconductor device of one embodiment of the present invention.

FIG. 22 A top view and cross-sectional views illustrating a method for manufacturing a semiconductor device of one embodiment of the present invention.

FIG. 23 A top view and cross-sectional views illustrating a method for manufacturing a semiconductor device of one embodiment of the present invention.

FIG. 24 A top view and cross-sectional views illustrating a method for manufacturing a semiconductor device of one embodiment of the present invention.

FIG. 25 A top view and cross-sectional views illustrating a method for manufacturing a semiconductor device of one embodiment of the present invention.

FIG. 26 A top view and cross-sectional views illustrating a method for manufacturing a semiconductor device of one embodiment of the present invention.

FIG. 27 A top view and cross-sectional views illustrating a method for manufacturing a semiconductor device of one embodiment of the present invention.

FIG. 28 A top view and cross-sectional views illustrating a method for manufacturing a semiconductor device of one embodiment of the present invention.

FIG. 29 A top view and cross-sectional views illustrating a method for manufacturing a semiconductor device of one embodiment of the present invention.

FIG. 30 A top view and cross-sectional views illustrating a method for manufacturing a semiconductor device of one embodiment of the present invention.

FIG. 31 A top view and cross-sectional views illustrating a method for manufacturing a semiconductor device of one embodiment of the present invention.

FIG. 32 A top view and cross-sectional views illustrating a method for manufacturing a semiconductor device of one embodiment of the present invention.

FIG. 33 A top view and cross-sectional views illustrating a method for manufacturing a semiconductor device of one embodiment of the present invention.

FIG. 34 A top view and cross-sectional views illustrating a method for manufacturing a semiconductor device of one embodiment of the present invention.

FIG. 35 A top view and cross-sectional views illustrating a method for manufacturing a semiconductor device of one embodiment of the present invention.

FIG. 36 A top view and cross-sectional views illustrating a method for manufacturing a semiconductor device of one embodiment of the present invention.

FIG. 37 A top view and cross-sectional views illustrating a method for manufacturing a semiconductor device of one embodiment of the present invention.

FIG. 38 A top view and cross-sectional views illustrating a method for manufacturing a semiconductor device of one embodiment of the present invention.

FIG. 39 A top view and cross-sectional views illustrating a method for manufacturing a semiconductor device of one embodiment of the present invention.

FIG. 40 A top view and cross-sectional views illustrating a method for manufacturing a semiconductor device of one embodiment of the present invention.

FIG. 41 A top view and cross-sectional views illustrating a method for manufacturing a semiconductor device of one embodiment of the present invention.

FIG. 42 A diagram illustrating an energy band structure of an oxide semiconductor.

FIG. 43 A cross-sectional view illustrating a structure of a memory device of one embodiment of the present invention.

FIG. 44 A cross-sectional view illustrating a structure of a memory device of one embodiment of the present invention.

FIG. 45 A cross-sectional view illustrating a structure of a memory device of one embodiment of the present invention.

FIG. 46 A circuit diagram of a memory device of one embodiment of the present invention.

FIG. 47 A top view illustrating a structure example of a memory device of one embodiment of the present invention.

FIG. 48 A top view illustrating a structure example of a memory device of one embodiment of the present invention.

FIG. 49 A cross-sectional view illustrating a structure of a memory device of one embodiment of the present invention.

FIG. 50 A cross-sectional view illustrating a structure of a memory device of one embodiment of the present invention.

FIG. 51 A cross-sectional view illustrating a structure of a memory device of one embodiment of the present invention.

FIG. 52 A block diagram illustrating a structure example of a memory device of one embodiment of the present invention.

FIG. 53 Circuit diagrams illustrating structure examples of a memory device of one embodiment of the present invention.

FIG. 54 A circuit diagram illustrating a structure example of a memory device of one embodiment of the present invention.

FIG. 55 A cross-sectional view illustrating a structure of a memory device of one embodiment of the present invention.

FIG. 56 A block diagram illustrating a structure example of a memory device of one embodiment of the present invention.

FIG. 57 A block diagram and a circuit diagram illustrating a structure example of a memory device of one embodiment of the present invention.

FIG. 58 A block diagram illustrating a structure example of an AI system of one embodiment of the present invention.

FIG. 59 Block diagrams illustrating application examples of an AI system of one embodiment of the present invention.

FIG. 60 A schematic perspective view illustrating a structure example of an IC incorporating an AI system of one embodiment of the present invention.

FIG. 61 Diagrams illustrating electronic devices of one embodiment of the present invention.

### MODE FOR CARRYING OUT THE INVENTION

Hereinafter, embodiments will be described with reference to drawings. Note that the embodiments can be implemented with many different modes, and it will be readily appreciated by those skilled in the art that modes and details can be changed in various ways without departing from the spirit and scope thereof. Thus, the present invention should not be interpreted as being limited to the following description of the embodiments.

In the drawings, the size, the layer thickness, or the region is exaggerated for clarity in some cases. Thus, the size, the layer thickness, or the region is not limited to the illustrated scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings and repeated description thereof is omitted, in some cases. Furthermore, the same hatching pattern is used for portions having similar functions and the portions are not denoted by particular reference numerals, in some cases.

Especially in a top view (also referred to as a “plan view”), a perspective view, or the like, some components might not be illustrated for easy understanding of the invention. In addition, some hidden lines and the like might not be illustrated.

The ordinal numbers such as first and second in this specification and the like are used for convenience and do not denote the order of steps or the stacking order of layers. Thus, for example, description can be made even when “first” is replaced with “second,” “third,” or the like, as appropriate. In addition, the ordinal numbers in this specification and the like do not correspond to the ordinal numbers which are used to specify one embodiment of the present invention in some cases.

In this specification, terms for describing arrangement, such as “over” and “under,” are used for convenience in describing a positional relationship between components with reference to drawings. Furthermore, the positional relationship between components changes as appropriate depending on a direction in which each component is described. Thus, description can be rephrased appropriately according to the situation, without being limited by the terms used in the specification.

In this specification and the like, a transistor is an element having at least three terminals including a gate, a drain, and a source. In addition, the transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Functions of the source and the drain might be switched when the polarity of the employed transistor is different or a direction of current is changed in circuit operation, for example. Thus, the terms “source” and “drain” can be used interchangeably in this specification and the like in some cases.

Note that the channel length refers to, for example, the distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. In one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

The channel width refers to, for example, the length of a channel formation region in a direction perpendicular to a channel length direction in a region where a semiconductor (or a portion where current flows in a semiconductor when a transistor is in an on state) and a gate electrode overlap with each other, or a region where a channel is formed in a top view of the transistor. In one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter also referred to as an “effective channel width”) is different from a channel width shown in a top view of a transistor (hereinafter also referred to as an “apparent channel width”) in some cases. For example, in the case where a gate electrode covers a side surface of a semiconductor, an effective channel width is larger than an apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, an effective channel width is larger than an apparent channel width.

In such a case, an effective channel width is difficult to estimate by actual measurement in some cases. For example, to estimate an effective channel width from a design value, an assumption that the shape of a semiconductor is known is necessary. Accordingly, in the case where the shape of a semiconductor is not known accurately, it is difficult to measure an effective channel width accurately.

Thus, in this specification, an apparent channel width is referred to as a “surrounded channel width (SCW)” in some cases. Furthermore, in the case where the term “channel width” is simply used in this specification, it may represent a surrounded channel width or an apparent channel width. Alternatively, in the case where the term “channel width” is simply used in this specification, it may represent an effective channel width. Note that the values of a channel length, a channel width, an effective channel width, an apparent channel width, a surrounded channel width, and the like can be determined by analyzing a cross-sectional TEM image or the like, for example.

Note that impurities in a semiconductor refer to, for example, elements other than the main components of the semiconductor. For example, elements with a concentration lower than 0.1 atomic % can be regarded as impurities. When impurities are contained, for example, the density of states (DOS) in a semiconductor may be increased, or the crystallinity may be decreased. In the case where a semiconductor is an oxide semiconductor, examples of impurities which change the characteristics of the semiconductor include Group 1 elements, Group 2 elements, Group 13 elements, Group 14 elements, Group 15 elements, and transition metals other than the main components of the oxide semiconductor, such as hydrogen, lithium, sodium, silicon, boron, phosphorus, carbon, and nitrogen. In addition, water serves as an impurity for an oxide semiconductor in some cases. In the case of an oxide semiconductor, entry of impurities may lead to formation of oxygen vacancies, for example. When the semiconductor is silicon, examples of impurities which change the characteristics of the semiconductor include oxygen, Group 1 elements except hydrogen, Group 2 elements, Group 13 elements, and Group 15 elements.

Note that in this specification and the like, a silicon oxynitride film contains more oxygen than nitrogen in its composition. A silicon oxynitride film preferably contains, for example, oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively. A silicon nitride oxide film contains more nitrogen than oxygen in its composition. A silicon nitride oxide film preferably contains, for example, nitrogen, oxygen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively.

In this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

In addition, in this specification and the like, the term “insulator” can be replaced with the term “insulating film” or “insulating layer.” Moreover, the term “conductor” can be replaced with the term “conductive film” or “conductive layer.” Furthermore, the term “semiconductor” can be replaced with the term “semiconductor film” or “semiconductor layer.”

Furthermore, unless otherwise specified, transistors described in this specification and the like are field effect transistors. Unless otherwise specified, transistors described in this specification and the like are n-channel transistors. Thus, unless otherwise specified, the threshold voltage (also referred to as “Vₜₕ”) is larger than 0 V.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, “substantially parallel” indicates a state where two straight lines are placed at an angle of greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. In addition, “substantially perpendicular” indicates a state where two straight lines are placed at an angle of greater than or equal to 60° and less than or equal to 120°.

In this specification, in the case where a crystal is a trigonal crystal or a rhombohedral crystal, the crystal is described as a hexagonal crystal system.

Note that in this specification, a barrier film refers to a film having a function of inhibiting the penetration of oxygen and impurities such as hydrogen; in the case where the barrier film has conductivity, it is referred to as a conductive barrier film in some cases.

In this specification and the like, a metal oxide means an oxide of metal in a broad expression. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is called an oxide semiconductor in some cases. In other words, in the case where an OS FET (Field Effect Transistor) is stated, it can also be referred to as a transistor including an oxide or an oxide semiconductor.

### Embodiment 1

A semiconductor device of one embodiment of the present invention is a semiconductor device including an oxide in a channel formation region, and the semiconductor device includes a first transistor, a second transistor, a first wiring, a second wiring, and a third wiring.

The first transistor includes an oxide over a first insulator, a second insulator over the oxide, a first conductor over the second insulator, a third insulator over the first conductor, and a fourth insulator in contact with the second insulator, the first conductor, and the third insulator. The second transistor includes the oxide over a fifth insulator, a sixth insulator over the oxide, a second conductor over the sixth insulator, a seventh insulator over the second conductor, and an eighth insulator in contact with the sixth insulator, the second conductor, and the seventh insulator.

The oxide includes first regions overlapping with the second insulator and the sixth insulator, second regions overlapping with the fourth insulator and the eighth insulator, third regions in contact with the second regions, and a fourth region that is in contact with the second regions and is provided between the first conductor and the second conductor. The first wiring is electrically connected to the third region of the first transistor, the second wiring is electrically connected to the third region of the second transistor, and the third wiring is in contact with the fourth insulator and the eighth insulator and is electrically connected to the fourth region.

In one embodiment of the present invention, the above-described connection of the plurality of transistors and the plurality of wirings can lead to provision of a semiconductor device that can be miniaturized or highly integrated.

Details are described with reference to drawings.

### <Structure Example 1 of Semiconductor Device>

An example of a semiconductor device of one embodiment of the present invention including a transistor 200a and a transistor 200b is described below.

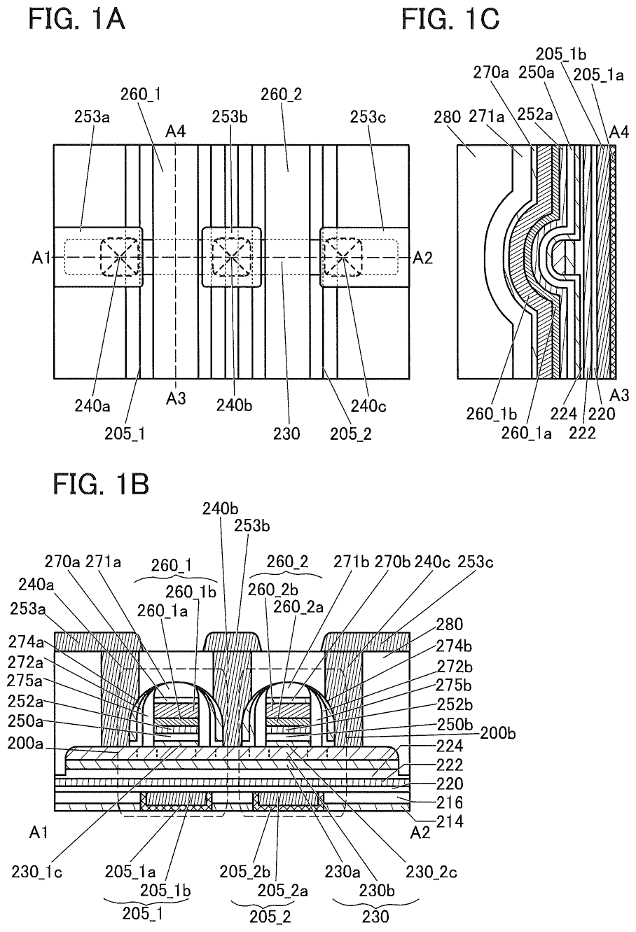

FIG. 1(A) is a top view of the semiconductor device including the transistor 200a and the transistor 200b. FIG. 1(B) is a cross-sectional view of a portion indicated by a dashed-dotted line A1-A2 in FIG. 1(A) and also is a cross-sectional view of the transistor 200a and the transistor 200b in a channel length direction. FIG. 1(C) is a cross-sectional view of a portion indicated by a dashed-dotted line A3-A4 in FIG. 1(A) and also is a cross-sectional view of the transistor 200a in a channel width direction. For simplification of the drawing, some components are not illustrated in the top view in FIG. 1(A).

The semiconductor device of one embodiment of the present invention includes the transistor 200a, the transistor 200b, and an insulator 280 functioning as an interlayer film. In addition, conductors 240 (a conductor 240a, a conductor 240b, and a conductor 240c) functioning as plugs and conductors 253 (a conductor 253a, a conductor 253b, and a conductor 253c) functioning as wirings are included.

As in FIG. 1, the transistor 200a and the transistor 200b include an insulator 214 and an insulator 216 positioned over a substrate (not illustrated); a conductor 205_1 and a conductor 205_2 positioned to be embedded in the insulator 214 and the insulator 216; an insulator 220 positioned over the conductor 205_1, the conductor 205_2, and the insulator 216; an insulator 222 positioned over the insulator 220; an insulator 224 positioned over the insulator 222; an oxide 230 (an oxide 230a and an oxide 230b) positioned over the insulator 224; an oxide 230_1c and an oxide 230_2c positioned over the oxide 230; an insulator 250a positioned over the oxide 230_1c; an insulator 250b positioned over the oxide 230_2c; an insulator 252a positioned over the insulator 250a; an insulator 252b positioned over the insulator 250b; a conductor 260_1 (a conductor 260_1a and a conductor 260_1b) positioned over the insulator 252a; a conductor 260_2 (a conductor 260_2a and a conductor 260_2b) positioned over the insulator 252b; an insulator 270a positioned over the conductor 260_1; an insulator 270b positioned over the conductor 260_2; an insulator 271a positioned over the insulator 270a; an insulator 271b positioned over the insulator 270b; an insulator 275a positioned to be in contact with at least side surfaces of the oxide 230_1c, the insulator 250a, the insulator 252a, the conductor 260_1, and the insulator 270a; an insulator 275b positioned to be in contact with at least side surfaces of the oxide 230_2c, the insulator 250b, the insulator 252b, the conductor 260_2, and the insulator 270b; an insulator 272a positioned to be in contact with at least a side surface of the insulator 275a; an insulator 272b positioned to be in contact with at least a side surface of the insulator 275b; an insulator 274a positioned to be in contact with at least a side surface of the insulator 272a; and an insulator 274b positioned to be in contact with at least a side surface of the insulator 272b.

Note that the oxide 230a and the oxide 230b in the transistor 200a and the transistor 200b are collectively referred to as the oxide 230 in some cases. Although structures of the transistor 200a and the transistor 200b in which the oxide 230a and the oxide 230b are stacked are illustrated, the present invention is not limited to this. For example, structures in which only the oxide 230b is provided may be employed. Furthermore, the conductor 260_1a and the conductor 260_1b are collectively referred to as the conductor 260_1, and the conductor 260_2a and the conductor 260_2b are collectively referred to as the conductor 260_2, in some cases. Although structures of the transistor 200a and the transistor 200b in which the conductor 260_1a and the conductor 260_1b are stacked and the conductor 260_2a and the conductor 260_2b are stacked are illustrated, the present invention is not limited to this. For example, structures in which only the conductor 260_1b and the conductor 260_2b are provided may be employed.

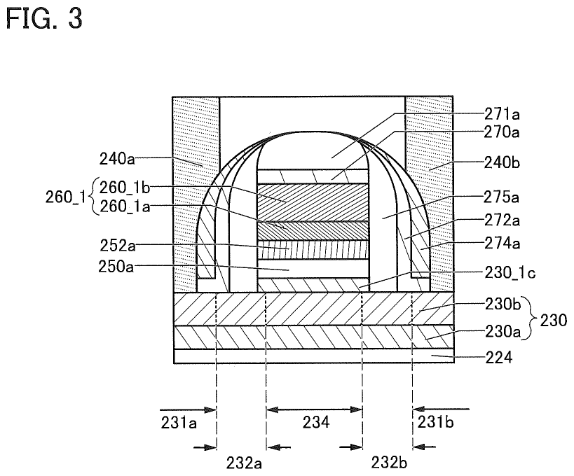

Here, an enlarged view of a channel of the transistor 200a and a region in the vicinity thereof, which are surrounded by a dashed line in FIG. 1(B), is illustrated in FIG. 3. Note that the transistor 200a and the transistor 200b have similar structures. Thus, unless otherwise specified, the description for the transistor 200a can be referred to for the transistor 200b below. In other words, the oxide 230c_1, the insulator 250a, the insulator 252a, the insulator 275a, the insulator 272a, the insulator 274a, the conductor 260_1, the insulator 270a, and the insulator 271a of the transistor 200a correspond to the oxide 230c_2, the insulator 250b, the insulator 252b, the insulator 275b, the insulator 272b, the insulator 274b, the conductor 260_2, the insulator 270b, and the insulator 271b of the transistor 200b, respectively.

As illustrated in FIG. 3, the oxide 230 includes a junction region 232 (a junction region 232a and a junction region 232b) between a region 234 functioning as a channel formation region of the transistor 200a and a region 231 (a region 231a and a region 231b) functioning as a source region or a drain region. The region 231 functioning as the source region or the drain region is a region whose carrier density is high and resistance is reduced. The region 234 functioning as the channel formation region is a region whose carrier density is lower than the region 231 functioning as the source region or the drain region. The junction region 232 is a region whose carrier density is lower than the region 231 functioning as the source region or the drain region and is higher than the region 234 functioning as the channel formation region. That is, the junction region 232 functions as a junction region between the channel formation region and the source region or the drain region.

When the junction region is provided, a high-resistance region is not formed between the region 231 functioning as the source region or the drain region and the region 234 functioning as the channel formation region, thereby increasing the on-state current of the transistor.

The junction region 232 sometimes functions as what is called an overlap region (also referred to as an Lov region) that overlaps with the conductor 260_1 functioning as a gate electrode.

Note that it is preferred that the region 231 be in contact with the insulator 272a and the insulator 274a be placed over the insulator 272a. In addition, it is preferred that the region 231 have higher concentration of at least one of a metal element such as indium and an impurity element such as hydrogen and nitrogen than the junction region 232 and the region 234.

The junction region 232 has a region overlapping with the insulator 275a and the insulator 272a. It is preferred that the junction region 232 have higher concentration of at least one of a metal element such as indium and an impurity element such as hydrogen and nitrogen than the region 234. Meanwhile, it is preferred that the junction region 232 have lower concentration of at least one of a metal element such as indium and an impurity element such as hydrogen and nitrogen than the region 231.

The region 234 overlaps with the conductor 260_1. The region 234 is positioned between the junction region 232a and the junction region 232b, and it is preferred that the region 234 have lower concentration of at least one of a metal element such as indium and an impurity element such as hydrogen and nitrogen than the region 231 and the junction region 232.

In the oxide 230, boundaries between the region 231, the junction region 232, and the region 234 cannot be found clearly in some cases. The concentrations of a metal element such as indium and an impurity element such as hydrogen and nitrogen detected in each region may be not only gradually changed between the regions, but also continuously changed (also referred to as gradation) in each region. In other words, the region closer to the region 234, from the region 231 to the junction region 232, has a lower concentration of a metal element such as indium and an impurity element such as hydrogen and nitrogen.

The region 234, the region 231, and the junction region 232 are formed in the oxide 230b in FIG. 3 without being limited thereto; for example, these regions may be formed in the oxide 230a. Furthermore, although the boundaries between the regions are shown substantially perpendicular to a top surface of the oxide 230 in FIG. 3, this embodiment is not limited thereto. For example, the junction region 232 projects to the conductor 260 side in the vicinity of a surface of the oxide 230b and recedes to the conductor 240a side or the conductor 240b side in the vicinity of a bottom surface of the oxide 230b in some cases.

Note that in the transistor 200a, it is preferred to use a metal oxide functioning as an oxide semiconductor (hereinafter, also referred to as an oxide semiconductor) for the oxide 230. Since a transistor using an oxide semiconductor has an extremely low leakage current (off-state current) in a non-conduction state, a semiconductor device with low power consumption can be provided. In addition, an oxide semiconductor can be formed by a sputtering method or the like and thus can be used for a transistor consisting in a highly integrated semiconductor device.

On the other hand, the transistor using an oxide semiconductor is likely to have its electrical characteristics changed by impurities and oxygen vacancies in the oxide semiconductor; as a result, the reliability is reduced, in some cases. Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. A transistor using an oxide semiconductor containing oxygen vacancies in a channel formation region is likely to have normally-on characteristics. Thus, it is preferred that oxygen vacancies in the channel formation region be reduced as much as possible.

In particular, when oxygen vacancies exist at the interface between the oxide 230_1c and the insulator 250a functioning as a gate insulating film, it is likely that the electrical characteristics are changed, or the reliability is reduced in some cases.

In view of the above, the insulator 250a which overlaps with the region 234 of the oxide 230 preferably contains oxygen at a higher proportion than oxygen in the stoichiometric composition (also referred to as “excess oxygen”). That is, excess oxygen in the insulator 250a is diffused into the region 234, whereby oxygen vacancies in the region 234 can be reduced.

It is also preferred that the insulator 272a be provided in contact with the side surface of the insulator 275a that is in contact with the side surface of the insulator 250a. For example, the insulator 272a preferably has a function of inhibiting diffusion of at least one of oxygen atoms, oxygen molecules, and the like, or at least one of the oxygen atoms, oxygen molecules, and the like is less likely to penetrate the insulator 272a. When the insulator 272a has a function of inhibiting diffusion of oxygen, oxygen in the insulator 250a is not diffused to the insulator 274a side and supplied to the region 234 efficiently. Accordingly, formation of oxygen vacancies at the interface between the oxide 230_1c and the insulator 250a can be inhibited, leading to an improvement in the reliability of the transistor 200a.

Moreover, the transistor 200a is preferably covered with an insulator having a barrier property that prevents entry of impurities such as water or hydrogen. The insulator having a barrier property is an insulator using an insulating material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms, or an insulating material through which the impurities are less likely to pass. The insulator is preferably formed using an insulating material having a function of inhibiting diffusion of at least one of oxygen atoms and oxygen molecules, or an insulating material through which at least one of the oxygen atoms and oxygen molecules is less likely to pass.

The structure of the semiconductor device including the transistor 200a and the transistor 200b of one embodiment of the present invention is described in detail below. Note that also in the following description, the description of the transistor 200a can be referred to for the structure of the transistor 200b.

The conductor 205_1 functioning as a second gate electrode of the transistor 200a is positioned to overlap with the oxide 230 and the conductor 260_1.

Here, the conductor 205_1 is preferably provided such that the length in the channel width direction becomes larger than that of the region 234 in the oxide 230. It is particularly preferred that the conductor 205_1 extend also in a region on an outer side than an end portion of the region 234 in the oxide 230 that intersects with the channel width direction. In other words, the conductor 205_1 and the conductor 260_1 preferably overlap with each other with an insulator provided therebetween at a side surface of the oxide 230 in the channel width direction.

Here, the conductor 260_1 functions as a first gate electrode of the transistor 200a in some cases. Furthermore, the conductor 205_1 functions as the second gate electrode of the transistor 200a in some cases. In that case, by changing a potential applied to the conductor 205_1 not in synchronization with but independently of a potential applied to the conductor 260_1, the threshold voltage of the transistor 200a can be controlled. In particular, by applying a negative potential to the conductor 205_1, the threshold voltage of the transistor 200a can be higher than 0 V and the off-state current can be reduced. Accordingly, a drain current when a voltage applied to the conductor 260_1 is 0 V can be low.

As illustrated in FIG. 1(A), the conductor 205_1 is provided to overlap with the oxide 230 and the conductor 260_1. Here, the conductor 205_1 is preferably provided to overlap with the conductor 260_1 also in the region on an outer side than the end portion of the oxide 230 that intersects with the channel width direction (W length direction). In other words, the conductor 205_1 and the conductor 260_1 preferably overlap with each other with an insulator therebetween outside the side surface of the oxide 230 in the channel width direction.

With the above structure, when potentials are applied to the conductor 260_1 and the conductor 205_1 and an electric field generated from the conductor 260_1 and an electric field generated from the conductor 205_1 are connected, a closed circuit is formed and the channel formation region formed in the oxide 230 can be covered.

That is, the channel formation region in the region 234 can be electrically surrounded by the electric field of the conductor 260_1 functioning as the first gate electrode and the electric field of the conductor 205_1 functioning as the second gate electrode. In this specification, a transistor structure in which the channel formation region is electrically surrounded by the electric fields of the first gate electrode and the second gate electrode is referred to as a surrounded channel (S-channel) structure.

In the conductor 205_1, a conductor 205_1a is formed in contact with an inner wall of an opening of the insulator 214 and the insulator 216, and a conductor 205_1b is formed further inside. Here, a top surface of the conductor 205_1b can be substantially level with a top surface of the insulator 216. Although a structure in which the conductor 205_1a and the conductor 205_1b are stacked in the transistor 200a is illustrated, the present invention is not limited thereto. For example, a structure in which only the conductor 205_1b is provided may be employed.

Here, it is preferred to use a conductive material that has a function of inhibiting the passage of impurities such as water or hydrogen, or a conductive material through which the impurities are less likely to pass, for the conductor 205_1a. For example, tantalum, tantalum nitride, ruthenium, ruthenium oxide, or the like is preferably used, and a single layer or stacked layers are used. This can inhibit diffusion of impurities such as hydrogen or water from a layer below the insulator 214 into an upper layer through the conductor 205_1. Note that it is preferred that the conductor 205_1a have a function of inhibiting the passage of at least one of oxygen atoms, oxygen molecules, and the like and impurities such as hydrogen atoms, hydrogen molecules, water molecules, oxygen atoms, oxygen molecules, nitrogen atoms, nitrogen molecules, nitrogen oxide molecules (e.g., N₂O, NO, and NO₂), and copper atoms. In the case where a conductive material having a function of inhibiting the passage of impurities is described in the following description, the conductive material preferably has a similar function. The conductor 205_1a with a function of inhibiting the passage of oxygen can prevent the conductor 205_1b from being oxidized and reduced in conductivity.

The conductor 205_1b is preferably formed using a conductive material whose main component is tungsten, copper, or aluminum. Although not illustrated, the conductor 205_1b may have a stacked-layer structure and may be, for example, stacked layers of titanium, titanium nitride, and the above-described conductive material.

The insulator 214 and the insulator 222 can function as barrier insulating films that prevent impurities such as water or hydrogen from entering the transistor from a lower layer. The insulator 214 and the insulator 222 are preferably formed using an insulating material having a function of inhibiting the passage of impurities such as water or hydrogen. For example, it is preferred that silicon nitride or the like be used for the insulator 214 and aluminum oxide, hafnium oxide, an oxide containing aluminum and hafnium (hafnium aluminate), or the like be used for the insulator 222. This can inhibit diffusion of impurities such as hydrogen or water to a layer positioned above the insulator 214 and the insulator 222. Note that it is preferred that the insulator 214 and the insulator 222 have a function of inhibiting the passage of at least one of impurities such as hydrogen atoms, hydrogen molecules, water molecules, nitrogen atoms, nitrogen molecules, nitrogen oxide molecules (e.g., N₂O, NO, and NO₂), and copper atoms.

Furthermore, the insulator 214 and the insulator 222 are preferably formed using an insulating material having a function of inhibiting the passage of oxygen (e.g., oxygen atoms or oxygen molecules). This can inhibit downward diffusion of oxygen contained in the insulator 224 or the like.

Moreover, the concentration of impurities such as water, hydrogen, or nitrogen oxide in the insulator 222 is preferably lowered. The amount of hydrogen released from the insulator 222, which is converted into hydrogen molecules per unit area of the insulator 222, is less than or equal to 2×10¹⁵ molecules/cm², preferably less than or equal to 1×10¹⁵ molecules/cm², further preferably less than or equal to 5×10¹⁴ molecules/cm² in thermal desorption spectroscopy (TDS) within the surface temperature range of the insulator 222 of 50° C. to 500° C., for example. The insulator 222 is preferably formed using an insulator from which oxygen is released by heating.

The insulator 250a can function as a first gate insulating film of the transistor 200a, and the insulator 220, the insulator 222, and the insulator 224 can function as second gate insulating films of the transistor 200a. Although a structure in which the insulator 220, the insulator 222, and the insulator 224 are stacked in the transistor 200a is illustrated, the present invention is not limited thereto. For example, a structure in which any two of the insulator 220, the insulator 222, and the insulator 224 are stacked may be employed, or a structure in which any one of them is used may be employed.

It is preferred to use a metal oxide functioning as an oxide semiconductor (hereinafter, also referred to as an oxide semiconductor) for the oxide 230. A metal oxide whose energy gap is greater than or equal to 2 eV, preferably greater than or equal to 2.5 eV, is preferably used as the metal oxide. With the use of a metal oxide having such a wide energy gap, the off-state current of the transistor can be reduced.

Since a transistor using an oxide semiconductor has an extremely low leakage current in a non-conduction state, a semiconductor device with low power consumption can be provided. In addition, an oxide semiconductor can be formed by a sputtering method or the like and thus can be used for a transistor consisting in a highly integrated semiconductor device.

An oxide semiconductor preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an In-M-Zn oxide that contains indium, an element M, and zinc is considered. The element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, magnesium, and the like. Note that a plurality of the above-described elements may be used in combination as the element M.

Note that in this specification and the like, a metal oxide containing nitrogen is also collectively called a metal oxide in some cases. Moreover, a metal oxide containing nitrogen may be called a metal oxynitride.

Here, the atomic ratio of the element M to constituent elements in a metal oxide used as the oxide 230a is preferably greater than the atomic ratio of the element M to constituent elements in a metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element M in the metal oxide used as the oxide 230b is preferably greater than the atomic ratio of In to the element Min the metal oxide used as the oxide 230a.

It is preferred that the above metal oxide be used as the oxide 230a and the conduction band minimum of the oxide 230a be higher than the conduction band minimum of the oxide 230b. In other words, the electron affinity of the oxide 230a is preferably smaller than the electron affinity of the oxide 230b.

Here, the conduction band minimum gently changes in the oxide 230a and the oxide 230b. In other words, a continuous change or continuous connection occurs. To obtain such a structure, the density of defect states in a mixed layer formed at the interface between the oxide 230a and the oxide 230b is decreased.

Specifically, when the oxide 230a and the oxide 230b contain a common element (as a main component) in addition to oxygen, a mixed layer with a low density of defect states can be formed. For example, in the case where the oxide 230b is an In-Ga—Zn oxide, an In-Ga—Zn oxide, a Ga—Zn oxide, gallium oxide, or the like is used for the oxide 230a.

At this time, a narrow-gap portion formed in the oxide 230b functions as a main carrier path. Since the density of defect states at the interface between the oxide 230a and the oxide 230b can be decreased, the influence of interface scattering on carrier conduction can be small and a high on-state current can be obtained.

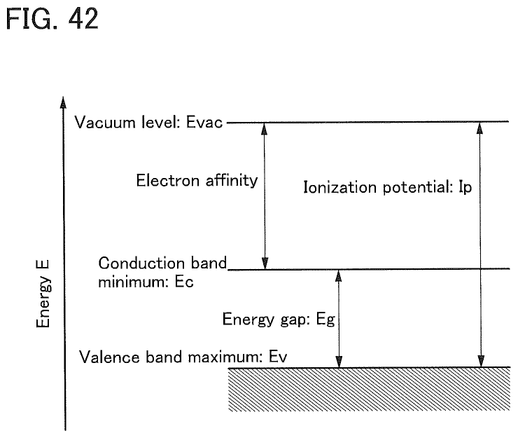

Electron affinity or conduction band minimum Ec can be obtained from an energy gap Eg and an ionization potential Ip, which is a difference between a vacuum level Evac and valence band maximum By, as shown in FIG. 42. The ionization potential Ip can be measured with, for example, an ultraviolet photoelectron spectroscopy (UPS) apparatus. The energy gap Eg can be measured with, for example, a spectroscopic ellipsometer.

The insulator 275a is provided to be in contact with at least the side surfaces of the oxide 230_1c, the insulator 250a, the insulator 252a, the conductor 260_1, and the insulator 270a. The insulator 272a is provided to be in contact with the side surface of the insulator 275a. The insulator 272a is preferably formed by an ALD method. In that case, the insulator 272a can be formed to have a thickness of approximately more than or equal to 0.5 nm and less than or equal to 10 nm, preferably more than or equal to 0.5 nm and less than or equal to 3 nm. Note that a precursor used in an ALD method sometimes contains impurities such as carbon. Thus, the insulator 272a may contain impurities such as carbon. In the case where the insulator 252a is formed by a sputtering method and the insulator 272a is formed by an ALD method, for example, the insulator 272a may contain more impurities such as carbon than the insulator 252a even when aluminum oxide is deposited as the insulator 272a and the insulator 252a. Note that impurities can be quantified by X-ray photoelectron spectroscopy (XPS).

The region 231 and the junction region 232 of the oxide 230 are formed by impurity elements that are added when an insulator to be the insulator 274a is formed. Thus, the insulator to be the insulator 274a preferably contains at least one of hydrogen and nitrogen. Moreover, the insulator to be the insulator 274a is preferably formed using an insulating material having a function of inhibiting the passage of oxygen and impurities such as water or hydrogen. For example, the insulator to be the insulator 274a is preferably formed using silicon nitride, silicon nitride oxide, silicon oxynitride, aluminum nitride, or aluminum nitride oxide.

In the case where the transistor is miniaturized to have a channel length of approximately 10 nm to 30 nm, impurity elements contained in the source region or the drain region might be diffused to bring electrical connection between the source region and the drain region. However, since the insulator 272a is formed between the insulator 274a and the region 231 as described in this embodiment, excessive diffusion of the impurity elements can be inhibited. In addition, absorption of oxygen in the region 234 by the insulator 274a can be inhibited. Moreover, the width of the region 234 in the oxide 230 can be kept because the insulator 275a is provided; thus, the source region and the drain region can be prevented from being electrically connected to each other.

Here, the insulator 272a is preferably formed using an insulating material that has a function of inhibiting the passage of oxygen and impurities such as water or hydrogen; for example, aluminum oxide or hafnium oxide is preferably used. Accordingly, oxygen in the insulator 250a can be prevented from diffusing outward by the insulator 272a. In addition, entry of impurities such as hydrogen or water into the oxide 230 from an end portion of the insulator 250a or the like can be inhibited.

The insulator 275a is formed by forming an insulator to be the insulator 275a and then performing anisotropic etching. By the etching, the insulator 275a is formed so that a portion in contact with at least the side surfaces of the oxide 230_1c, the insulator 250a, the insulator 252a, the conductor 2601, and the insulator 270a remains.

The insulator 272a and the insulator 274a are formed by forming an insulator to be the insulator 272a, forming the insulator to be the insulator 274a, and then performing anisotropic etching. By the etching, the insulator 272a is formed so that a portion in contact with the side surface of the insulator 275a remains and the insulator 274a is formed so that a portion in contact with the side surface of the insulator 272a remains.

Furthermore, the insulator 280 is preferably provided to cover the transistor 200a and the transistor 200b in the semiconductor device. The concentration of impurities such as water or hydrogen in the insulator 280 is preferably lowered.

Openings in the insulator 280 are formed such that inner walls of the openings in the insulator 280 are in contact with side surfaces of the insulator 274a and the insulator 274b. To form such openings, opening conditions are preferably set such that the etching rates of the insulator 274a and the insulator 274b are much lower than the etching rate of the insulator 280 at the time of forming the openings in the insulator 280. When the etching rates of the insulator 274a and the insulator 274b are 1, the etching rate of the insulator 280 is preferably 5 or more, further preferably 10 or more. Formation of the openings in this manner allows the openings to be formed in a self-aligned manner and enables a wide design margin for alignment of the openings and the gate electrodes.

Here, the conductor 240a, the conductor 240b, and the conductor 240c are formed in contact with the inner walls of the openings in the insulator 280. The region 231 of the oxide 230 is positioned in at least part of bottom portions of the openings, and thus the conductor 240a, the conductor 240b, and the conductor 240c are each in contact with the region 231.

The conductor 240a and the conductor 240b are preferably provide to face each other with the conductor 260_1 positioned therebetween; such a structure can reduce a gap between the conductor 240a and the conductor 240b. Furthermore, the conductor 240b and the conductor 240c are preferably provide to face each other with the conductor 260_2 positioned therebetween; such a structure can reduce a gap between the conductor 240b and the conductor 240c. Such a structure enables a reduction in a gap between the transistor 200a and the transistor 200b adjacent to each other; thus, the transistors can be arranged with high density, leading to size reduction of the semiconductor device.

As illustrated in FIG. 1(B), parasitic capacitance is formed between the conductor 260_1 and the conductor 240a and parasitic capacitance is formed between the conductor 260_1 and the conductor 240b in the transistor 200a. Similarly, parasitic capacitance is formed between the conductor 260_2 and the conductor 240b and parasitic capacitance is formed between the conductor 260_2 and the conductor 240c in the transistor 200b.

When the insulator 275a is provided in the transistor 200a and the insulator 275b is provided in the transistor 200b, the parasitic capacitance can be reduced. A material having a low dielectric constant is preferably used for the insulator 275a and the insulator 275b. For example, silicon oxide or silicon oxynitride can be used. A reduction in the parasitic capacitance leads to high-speed operation of the transistor 200a and the transistor 200b.

The conductor 240a, the conductor 240b, and the conductor 240c can be formed using a material similar to that for the conductor 205_1. The conductor 240a, the conductor 240b, and the conductor 240c may be formed after aluminum oxide is formed on side wall portions of the openings. By forming aluminum oxide on the side wall portions of the openings, the passage of oxygen from the outside can be inhibited and oxidation of the conductor 240a, the conductor 240b, and the conductor 240c can be prevented. Furthermore, impurities such as water or hydrogen can be prevented from being diffused from the conductor 240a, the conductor 240b, and the conductor 240c to the outside. The aluminum oxide can be formed by depositing aluminum oxide in the openings by an ALD method or the like and then performing anisotropic etching.

It is preferred that the conductor 253a be positioned in contact with a top surface of the conductor 240a, the conductor 253b be positioned in contact with a top surface of the conductor 240b, and the conductor 253c be positioned in contact with a top surface of the conductor 240c. The conductor 253a, the conductor 253b, and the conductor 253c are preferably formed using a conductive material whose main component is tungsten, copper, or aluminum. Although not illustrated, the conductor 253a, the conductor 253b, and the conductor 253c may have stacked-layer structures and may be, for example, stacked layers of titanium, titanium nitride, and the above-described conductive material.

Note that in this embodiment, the insulator 220, the insulator 222, and the insulator 224 are referred to as a first insulator in some cases. Furthermore, the insulator 250a and the insulator 252a are referred to as a second insulator in some cases. The insulator 270a and the insulator 271a are referred to as a third insulator and the insulator 270b and the insulator 271b are referred to as a sixth insulator, in some cases. Moreover, the insulator 250b and the insulator 252b are referred to as a fifth insulator in some cases. The insulator 275a, the insulator 272a, and the insulator 274a are each referred to as a fourth insulator in some cases. The insulator 275b, the insulator 272b, and the insulator 274b are each referred to as a seventh insulator in some cases.

In this embodiment, the oxide 230 is simply referred to as an oxide in some cases. Furthermore, the conductor 260_1 and the conductor 260_2 are referred to as a first conductor and a second conductor, respectively, in some cases. Furthermore, the conductor 240a, the conductor 240c, and the conductor 240b are referred to as a first wiring, a second wiring, and a third wiring, respectively, in some cases.

### <Structure Example 2 of Semiconductor Device>

An example of a semiconductor device of one embodiment of the present invention including the transistor 200a and the transistor 200b is described below.

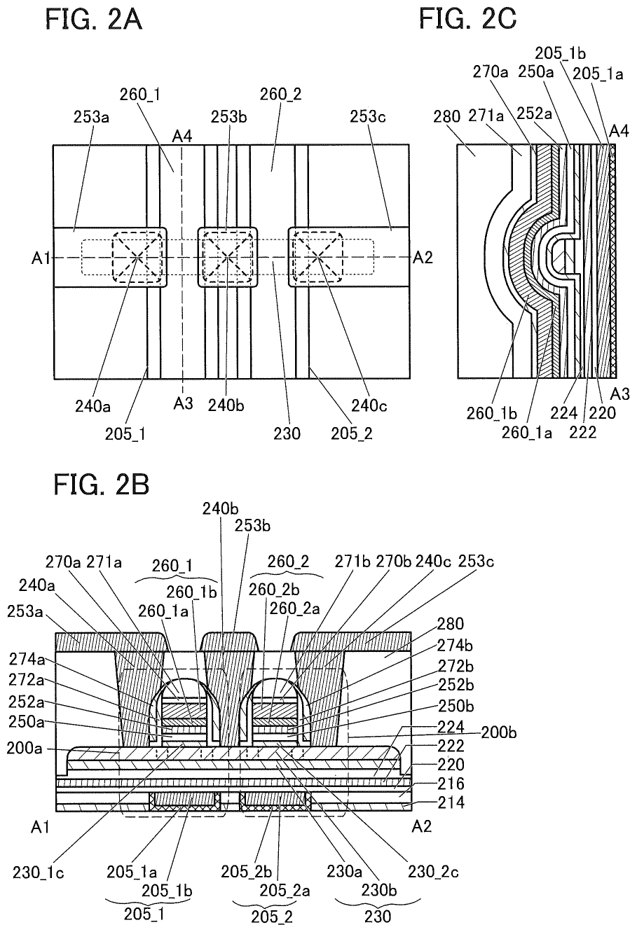

FIG. 2(A) is a top view of the semiconductor device including the transistor 200a and the transistor 200b. FIG. 2(B) is a cross-sectional view of a portion indicated by a dashed-dotted line A1-A2 in FIG. 2(A) and also is a cross-sectional view of the transistor 200a and the transistor 200b in the channel length direction. FIG. 2(C) is a cross-sectional view of a portion indicated by a dashed-dotted line A3-A4 in FIG. 2(A) and also is a cross-sectional view of the transistor 200a in the channel width direction. For simplification of the drawing, some components are not illustrated in the top view in FIG. 2(A).

The transistor 200a and the transistor 200b, as illustrated in FIG. 2, are different from the transistor 200a and the transistor 200b illustrated in FIG. 1 in that the transistor 200a has a structure not having the insulator 275a and similarly the transistor 200b has a structure not having the insulator 275b. Such a structure enables a reduction in a gap between the transistor 200a and the transistor 200b; thus, the transistors can be arranged with high density, leading to size reduction of the semiconductor device. The description for the semiconductor device illustrated in FIG. 1 is referred to for the other structures and effects.

### <Substrate>

Examples of a substrate where the transistors are formed include an insulator substrate, a semiconductor substrate, and a conductor substrate. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like, and a compound semiconductor substrate of silicon carbide, silicon germanium, gallium arsenide, indium phosphide, zinc oxide, or gallium oxide. In addition, a semiconductor substrate in which an insulator region is included in the above semiconductor substrate, e.g., an SOI (Silicon On Insulator) substrate and the like are given. Examples of the conductor substrate include a graphite substrate, a metal substrate, an alloy substrate, and a conductive resin substrate. Alternatively, a substrate including a metal nitride, a substrate including a metal oxide, and the like are given. Furthermore, a substrate in which an insulator substrate is provided with a conductor or a semiconductor, a substrate in which a semiconductor substrate is provided with a conductor or an insulator, a substrate in which a conductor substrate is provided with a semiconductor or an insulator, and the like are given. Alternatively, these substrates provided with elements may be used. Examples of the elements provided for the substrates include a capacitor, a resistor, a switching element, a light-emitting element, and a memory element.

A flexible substrate may be used as the substrate. Note that as a method of providing a transistor over a flexible substrate, there is a method in which the transistor is fabricated over a non-flexible substrate and then the transistor is separated and transferred to a flexible substrate. In that case, a separation layer is preferably provided between the non-flexible substrate and the transistor. Note that as the substrate, a film, a foil, or a sheet containing a fiber may be used. The substrate may have elasticity. The substrate may have a property of returning to its original shape when bending or pulling is stopped, or may have a property of not returning to its original shape. The substrate includes, for example, a region with a thickness greater than or equal to 5 μm and less than or equal to 700 μm, preferably greater than or equal to 10 μm and less than or equal to 500 μm, and further preferably greater than or equal to 15 μm and less than or equal to 300 μm. When the substrate is thin, the weight of the semiconductor device including the transistor can be reduced. Moreover, when the substrate is thin, the substrate may have elasticity or a property of returning to its original shape when bending or pulling is stopped, even in the case of using glass or the like. Thus, an impact applied to the semiconductor device over the substrate due to dropping or the like can be reduced. That is, a durable semiconductor device can be provided.

For the flexible substrate, metal, an alloy, a resin, glass, or fiber thereof can be used, for example. The flexible substrate preferably has a lower coefficient of linear expansion because deformation due to an environment is inhibited. For the flexible substrate, a material whose coefficient of linear expansion is lower than or equal to 1×10⁻³/K, lower than or equal to 5×10⁻⁵/K, or lower than or equal to 1×10⁻⁵/K can be used, for example. Examples of the resin include polyester, polyolefin, polyamide (e.g., nylon or aramid), polyimide, polycarbonate, and acrylic. In particular, aramid is preferable for the flexible substrate because of its low coefficient of linear expansion.

### <Insulator>

Examples of an insulator include an oxide, a nitride, an oxynitride, a nitride oxide, a metal oxide, a metal oxynitride, and a metal nitride oxide, each of which has an insulating property.

When a transistor is surrounded by an insulator having a function of inhibiting the passage of oxygen and impurities such as hydrogen, the transistor can have stable electrical characteristics. For example, an insulator having a function of inhibiting the passage of oxygen and impurities such as hydrogen can be used as the insulator 214, the insulator 222, the insulator 270a, the insulator 270b, the insulator 272a, and the insulator 272b.

As the insulator having a function of inhibiting the passage of oxygen and impurities such as hydrogen, for example, a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used.

For the insulator 214, the insulator 222, the insulator 270a, the insulator 270b, the insulator 272a, and the insulator 272b, for example, a metal oxide such as aluminum oxide, magnesium oxide, gallium oxide, germanium oxide, yttrium oxide, zirconium oxide, lanthanum oxide, neodymium oxide, hafnium oxide, an oxide containing silicon and hafnium, an oxide containing aluminum and hafnium, or tantalum oxide; silicon nitride oxide; or silicon nitride may be used. Note that the insulator 214, the insulator 222, the insulator 270a, the insulator 270b, the insulator 272a, and the insulator 272b preferably contain aluminum oxide, hafnium oxide, and the like.

As the insulator 274a and the insulator 274b, for example, a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. For example, the insulator 274a and the insulator 274b preferably contain silicon oxide, silicon oxynitride, or silicon nitride.

The insulator 222, the insulator 224, the insulator 250a, the insulator 250b, the insulator 252a, and the insulator 252b preferably include an insulator with a high dielectric constant. For example, the insulator 222, the insulator 224, the insulator 250a, the insulator 250b, the insulator 252a, and the insulator 252b preferably contain gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like. The insulator 250a and the insulator 250b preferably have a stacked-layer structure of an insulator with a high dielectric constant and silicon oxide or silicon oxynitride. When silicon oxide and silicon oxynitride, which are thermally stable, are combined with an insulator with a high dielectric constant, the stacked-layer structure can have thermal stability and a high dielectric constant. For example, when a structure is employed in which aluminum oxide, gallium oxide, or hafnium oxide in the insulator 250a and the insulator 250b is in contact with the oxide 2301c and the oxide 230_2c, silicon contained in silicon oxide or silicon oxynitride can be inhibited from entering the oxide 230. Furthermore, for example, when a structure is employed in which silicon oxide or silicon oxynitride in the insulator 250a and the insulator 250b is in contact with the oxide 230_1c and the oxide 230_2c, trap centers are formed at the interface between aluminum oxide, gallium oxide, or hafnium oxide and silicon oxide or silicon oxynitride, in some cases. The trap centers can shift the threshold voltage of the transistor in the positive direction by trapping electrons in some cases.

The insulator 216, the insulator 280, the insulator 275a, and the insulator 275b preferably include an insulator with a low dielectric constant. For example, the insulator 216, the insulator 280, the insulator 275a, and the insulator 275b preferably contain silicon oxide, silicon oxynitride, silicon nitride oxide, silicon nitride, silicon oxide to which fluorine is added, silicon oxide to which carbon is added, silicon oxide to which carbon and nitrogen are added, silicon oxide having pores, a resin, or the like. Alternatively, the insulator 216, the insulator 280, the insulator 275a, and the insulator 275b preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or silicon oxide having pores. When silicon oxide and silicon oxynitride, which are thermally stable, are combined with a resin, the stacked-layer structure can have thermal stability and a low dielectric constant. Examples of the resin include polyester, polyolefin, polyamide (e.g., nylon or aramid), polyimide, polycarbonate, and acrylic.

### <Conductor>

For the conductor 205_1, the conductor 205_2, the conductor 260_1, the conductor 260_2, the conductor 240, and the conductor 253, a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor with high electrical conductivity, typified by polycrystalline silicon containing an impurity element such as phosphorus, or silicide such as nickel silicide may be used.

In particular, a conductive material containing oxygen and a metal element contained in a metal oxide that can be used for the oxide 230 may be used for the conductor 260_1 and the conductor 260_2. A conductive material containing the above metal element and nitrogen may be used. For example, a conductive material containing nitrogen, such as titanium nitride or tantalum nitride, may be used. An indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon is added may be used. An indium gallium zinc oxide containing nitrogen may be used. With the use of such a material, hydrogen contained in the oxide 230 can be captured in some cases. Alternatively, hydrogen entering from an external insulator or the like can be captured in some cases.

Furthermore, a stack of a plurality of conductive layers formed with the above materials may be used. For example, a stacked-layer structure combining a material containing the above-described metal element and a conductive material containing oxygen may be employed. A stacked-layer structure combining a material containing the above-described metal element and a conductive material containing nitrogen may be employed. A stacked-layer structure combining a material containing the above-described metal element, a conductive material containing oxygen, and a conductive material containing nitrogen may be employed.

Note that in the case where an oxide is used for the channel formation region of the transistor, a stacked-layer structure combining a material containing the above-described metal element and a conductive material containing oxygen is preferably used for the gate electrode. In that case, the conductive material containing oxygen is preferably provided on the channel formation region side. When the conductive material containing oxygen is provided on the channel formation region side, oxygen left from the conductive material is easily supplied to the channel formation region.

### <Metal Oxide>

A metal oxide functioning as an oxide semiconductor is preferably used for the oxide 230. A metal oxide applicable to a semiconductor layer of the present invention and the oxide 230 is described below.

The oxide semiconductor preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an In-M-Zn oxide that contains indium, the element M, and zinc is considered. The element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, magnesium, and the like. Note that a plurality of the above-described elements may be used in combination as the element M.

### [Composition of Metal Oxide]

The composition of a CAC (Cloud-Aligned Composite)-OS that can be used for the transistor disclosed in one embodiment of the present invention is described below.

Note that in this specification and the like, CAAC or CAC might be stated. Note that CAAC refers to an example of a crystal structure, and CAC refers to an example of a function or a material composition.

A CAC-OS or a CAC-metal oxide has a conducting function in a part of the material and an insulating function in another part of the material and has a function of a semiconductor as a whole. In the case where the CAC-OS or the CAC-metal oxide is used in an active layer of a transistor, the conducting function is a function of allowing electrons (or holes) serving as carriers to flow, and the insulating function is a function of not allowing electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Furthermore, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide is composed of components having different bandgaps. For example, the CAC-OS or the CAC-metal oxide is composed of a component having a wide gap due to the insulating regions and a component having a narrow gap due to the conductive regions. In the case of the structure, when carriers flow, carriers mainly flow in the component having a narrow gap. Furthermore, the component having a narrow gap complements the component having a wide gap, and carriers flow also in the component having a wide gap in conjunction with the component having a narrow gap. Therefore, in the case where the above-described CAC-OS or CAC-metal oxide is used in the channel formation region of the transistor, high current driving capability in an on state of the transistor, that is, a high on-state current, and high field-effect mobility can be obtained.

In other words, the CAC-OS or the CAC-metal oxide can also be referred to as a matrix composite or a metal matrix composite.

### [Structure of Metal Oxide]

Oxide semiconductors can be classified into single crystal oxide semiconductors and the others, non-single-crystal oxide semiconductors. Examples of the non-single-crystal oxide semiconductors include a CAAC-OS, a polycrystalline oxide semiconductor, an nc-OS, an amorphous-like OS (a-like oxide semiconductor), and an amorphous oxide semiconductor.

The CAAC-OS has c-axis alignment and a crystal structure with distortion in which a plurality of nanocrystals are connected in the a-b plane direction. Note that the distortion refers to a portion where the direction of a lattice arrangement changes between a region with a regular lattice arrangement and another region with a regular lattice arrangement in a region where the plurality of nanocrystals are connected.

A nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) cannot be observed even in the vicinity of distortion in the CAAC-OS. That is, it is found that formation of a crystal grain boundary is inhibited by the lattice arrangement distortion. This is probably because the CAAC-OS can tolerate distortion owing to non-dense arrangement of oxygen atoms in the a-b plane direction, an interatomic bond length changed by metal element substitution, and the like.

The CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other; when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is an oxide semiconductor with high crystallinity. On the other hand, a clear crystal grain boundary cannot be observed in the CAAC-OS; thus, it can be said that a reduction in electron mobility due to the crystal grain boundary is less likely to occur. Furthermore, entry of impurities, formation of defects, or the like might decrease the crystallinity of the oxide semiconductor; thus, it can also be said that the CAAC-OS is an oxide semiconductor having small amounts of impurities and defects (e.g., oxygen vacancies). Thus, an oxide semiconductor including the CAAC-OS is physically stable. Therefore, the oxide semiconductor including the CAAC-OS is resistant to heat and has high reliability.

A microscopic region (e.g., a region greater than or equal to 1 nm and less than or equal to 10 nm, in particular, a region greater than or equal to 1 nm and less than or equal to 3 nm) in the nc-OS has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

The a-like OS is an oxide semiconductor having a structure between those of the nc-OS and an amorphous oxide semiconductor. The a-like OS includes a void or a low-density region. That is, the a-like OS has lower crystallinity than the nc-OS and the CAAC-OS.

An oxide semiconductor can have various structures which show different properties. Two or more of the amorphous oxide semiconductor, the polycrystalline oxide semiconductor, the a-like OS, the nc-OS, and the CAAC-OS may be included in the oxide semiconductor of one embodiment of the present invention.

### [Transistor Including Oxide Semiconductor]

Next, the case where the above oxide semiconductor is used for a transistor is described.

Note that when the above oxide semiconductor is used for a transistor, a transistor with high field-effect mobility can be achieved. In addition, a transistor with high reliability can be achieved.

An oxide semiconductor with a low carrier density is preferably used for a transistor. In the case where the carrier density of the oxide semiconductor is lowered, the impurity concentration in the oxide semiconductor is lowered to lower the density of defect states. In this specification and the like, a state with a low impurity concentration and a low density of defect states is referred to as a highly purified intrinsic or substantially highly purified intrinsic state. For example, the carrier density of the oxide semiconductor is lower than 8×10¹¹/cm³, preferably lower than 1×10¹¹/cm³, further preferably lower than 1×10¹⁰/cm³, and greater than or equal to 1×10⁻⁹/cm³.

In addition, a highly purified intrinsic or substantially highly purified intrinsic oxide semiconductor has a low density of defect states and accordingly has a low density of trap states in some cases.

Furthermore, charges trapped by the trap states in the oxide semiconductor take a long time to disappear and may behave like fixed charges. Thus, a transistor whose channel formation region is formed in an oxide semiconductor with a high density of trap states has unstable electrical characteristics in some cases.

Thus, in order to stabilize electrical characteristics of the transistor, reducing the impurity concentration in the oxide semiconductor is effective. Furthermore, in order to reduce the impurity concentration in the oxide semiconductor, it is preferred that the impurity concentration in an adjacent film be also reduced. Examples of impurities include hydrogen, nitrogen, an alkali metal, an alkaline earth metal, iron, nickel, and silicon.

As an oxide semiconductor used for a semiconductor of the transistor, a thin film having high crystallinity is preferably used. With the use of the thin film, the stability or the reliability of the transistor can be improved. Examples of the thin film include a thin film of a single-crystal oxide semiconductor and a thin film of a polycrystalline oxide semiconductor. However, for forming the thin film of a single-crystal oxide semiconductor or the thin film of a polycrystalline oxide semiconductor over a substrate, a high-temperature process or a laser heating process is needed. Thus, the cost of the manufacturing process is increased, and moreover, the throughput is decreased.

Non-Patent Document 1 and Non-Patent Document 2 have reported that, in 2009, an In-Ga—Zn oxide having a CAAC structure (referred to as CAAC-IGZO) was found. It has been reported that CAAC-IGZO has c-axis alignment and no clearly observed grain boundary, and can be formed over a substrate at low temperatures. It has also been reported that a transistor using CAAC-IGZO has excellent electrical characteristics and reliability.

In addition, in 2013, an In-Ga—Zn oxide having an nc structure (referred to as nc-IGZO) was found (see Non-Patent Document 3). It has been reported that nc-IGZO has periodic atomic arrangement in a microscopic region (e.g., a region greater than or equal to 1 nm and less than or equal to 3 nm) and there is no regularity of crystal orientation between different regions.

Non-Patent Document 4 and Non-Patent Document 5 show a change in average crystal size due to electron beam irradiation of thin films of the above-described CAAC-IGZO, nc-IGZO, and IGZO having low crystallinity. In the thin film of IGZO having low crystallinity, approximately 1-nm crystalline IGZO was observed even before the electron beam irradiation. Thus, it has been reported that a completely amorphous structure was not observed in the IGZO. In addition, it is shown that the thin film of CAAC-IGZO and the thin film of nc-IGZO have higher stability against electron beam irradiation than the thin film of IGZO having low crystallinity. Thus, the semiconductor of the transistor is preferably formed using the thin film of CAAC-IGZO or the thin film of nc-IGZO.

Non-Patent Document 6 shows that a transistor using an oxide semiconductor has an extremely low leakage current in a non-conduction state; specifically, the off-state current per micrometer of the channel width of the transistor is of the order of yA/μm (10⁻²⁴ A/μm). For example, a low-power-consumption CPU and the like utilizing a characteristic of low leakage current of the transistor using an oxide semiconductor is disclosed (see Non-Patent Document 7).

Furthermore, application of a transistor using an oxide semiconductor to a display device that utilizes a characteristic of low leakage current of the transistor has been reported (see Non-Patent Document 8). In the display device, a displayed image is changed several tens of times per second. The number of times an image is changed per second is called a refresh rate. The refresh rate is also referred to as driving frequency. Such high-speed screen change that is less likely to be recognized by human eyes is considered as a cause of eyestrain. Thus, it is proposed that the refresh rate of the display device is lowered to reduce the number of times of image rewriting. Moreover, driving with a lowered refresh rate enables the power consumption of the display device to be reduced. Such a driving method is referred to as idling stop (IDS) driving.

The discovery of the CAAC structure and the nc structure has contributed to an improvement in electrical characteristics and reliability of a transistor using an oxide semiconductor having the CAAC structure or the nc structure, a reduction in cost of the manufacturing process, and an improvement in throughput. Furthermore, applications of the transistor to a display device and an LSI utilizing a characteristic of low leakage current of the transistor have been studied.

### [Impurity]

Here, the influence of each impurity in the oxide semiconductor is described.

When silicon or carbon, which is one of the Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) is set lower than or equal to 2×10¹⁸ atoms/cm³, preferably lower than or equal to 2×10¹⁷ atoms/cm³.

Furthermore, when the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Accordingly, it is preferred to reduce the concentration of an alkali metal or an alkaline earth metal in the oxide semiconductor. Specifically, the concentration of an alkali metal or an alkaline earth metal in the oxide semiconductor obtained by SIMS is set lower than or equal to 1×10¹⁸ atoms/cm³, preferably lower than or equal to 2×10¹⁶ atoms/cm³.

Furthermore, when containing nitrogen, the oxide semiconductor easily becomes n-type by generation of electrons serving as carriers and an increase of carrier density. As a result, a transistor using an oxide semiconductor containing nitrogen as a semiconductor is likely to have normally-on characteristics. For this reason, nitrogen in the oxide semiconductor is preferably reduced as much as possible; the nitrogen concentration in the oxide semiconductor obtained by SIMS is set, for example, lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurities is used for a channel formation region of a transistor, stable electrical characteristics can be given.

### <Method for Manufacturing Semiconductor Device>

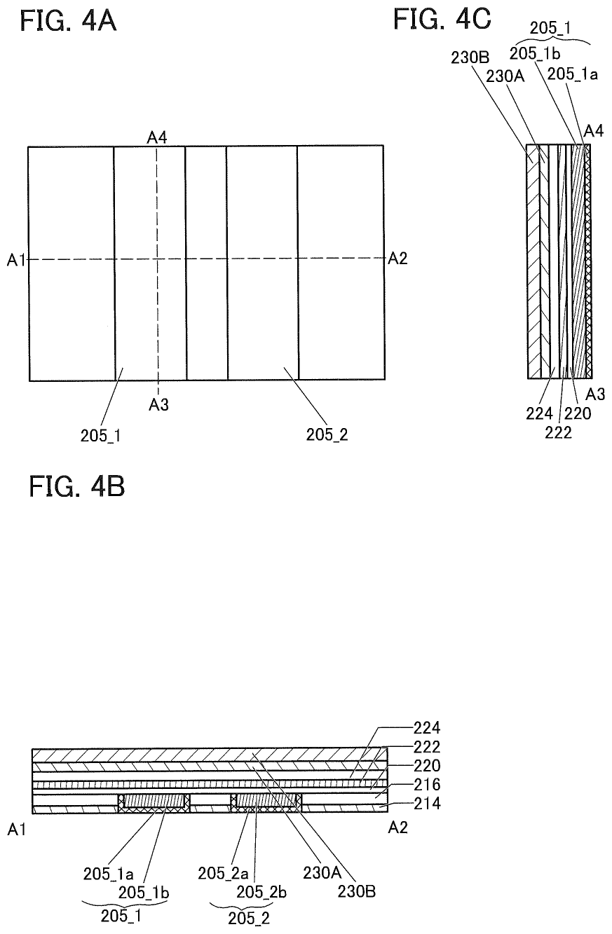

Next, a method for manufacturing the semiconductor device illustrated in FIG. 1 which includes the transistors 200a and 200b of one embodiment of the present invention is described with reference to FIG. 4 to FIG. 14. FIG. 4(A) to FIG. 14(A) are top views. FIG. 4(B) to FIG. 14(B) are cross-sectional views of portions indicated by dashed-dotted lines A1-A2 in FIG. 4(A) to FIG. 14(A). FIG. 4(C) to FIG. 14(C) are cross-sectional views of portions indicated by dashed-dotted lines A3-A4 in FIG. 4(A) to FIG. 14(A).

First, a substrate (not illustrated) is prepared, and the insulator 214 is formed over the substrate. The insulator 214 can be formed by a sputtering method, a chemical vapor deposition (CVD) method, a molecular beam epitaxy (MBE) method, a pulsed laser deposition (PLD) method, an ALD method, or the like.

Note that CVD methods can be classified into a plasma CVD (PECVD: plasma enhanced CVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a film formation method that does not use plasma and thus can cause less plasma damage to an object. For example, a wiring, an electrode, an element (e.g., transistor or capacitor), or the like included in a semiconductor device might be charged up by receiving electric charges from plasma. In that case, accumulated electric charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during film formation, so that a film with few defects can be obtained.

An ALD method is also a film formation method which can cause less plasma damage to an object. An ALD method also does not cause plasma damage during film formation, so that a film with few defects can be obtained.

Unlike in a film formation method in which particles ejected from a target or the like are deposited, a CVD method and an ALD method are film formation methods in which a film is formed by reaction at a surface of an object. Thus, a CVD method and an ALD method are film formation methods that are less likely to be influenced by the shape of an object and thus have favorable step coverage. In particular, an ALD method has excellent step coverage and excellent thickness uniformity, and thus is suitable for the case of covering a surface of an opening portion with a high aspect ratio, for example. Note that an ALD method has a relatively low film formation rate and thus is preferably used in combination with another film formation method with a high film formation rate such as a CVD method, in some cases.

A CVD method and an ALD method enable adjustment of composition of a film to be obtained with a flow rate ratio of the source gases. For example, a CVD method and an ALD method enable formation of a film with any composition depending on a flow rate ratio of source gases. Moreover, a CVD method and an ALD method enable formation of a film whose composition is continuously changed by changing a flow rate ratio of source gases during the film formation, for example. In the case of forming a film while changing a flow rate ratio of source gases, as compared with the case of forming a film with the use of a plurality of film formation chambers, time taken for the film formation can be shortened by the time necessary for transfer and pressure adjustment. Thus, productivity of semiconductor devices can be improved in some cases.

In this embodiment, silicon nitride is deposited as the insulator 214 by a CVD method. As described here, an insulator through which copper is less likely to pass, such as silicon nitride, is used as the insulator 214; accordingly, even when a metal that is easy to diffuse, such as copper, is used for a layer below the insulator 214, the metal can be prevented from diffusing into a layer above the insulator 214.

Next, the insulator 216 is formed over the insulator 214. The insulator 216 can be formed by a sputtering method, a CVD method, an MBE method, a PLD method, an ALD method, or the like. In this embodiment, silicon oxide is deposited as the insulator 216 by a CVD method.

Next, depression portions are formed in the insulator 214 and the insulator 216. Examples of the depression portions include holes and opening portions. The depression portions may be formed by wet etching; however, dry etching is preferably used for microfabrication.

After the formation of the depression portions, a conductive film to be the conductor 205_1a and a conductor 205_2a is formed. The conductive film to be the conductor 205_1a and the conductor 205_2a desirably includes a conductor having a function of inhibiting the passage of oxygen. For example, tantalum nitride, tungsten nitride, or titanium nitride can be used. Alternatively, a stacked-layer film of the above conductor and tantalum, tungsten, titanium, molybdenum, aluminum, copper, or a molybdenum-tungsten alloy can be used. The conductive film to be the conductor 205_1a and the conductor 205_2a can be formed by a sputtering method, a CVD method, an MBE method, a PLD method, an ALD method, or the like.

In this embodiment, tantalum nitride is deposited as the conductive film to be the conductor 205_1a and the conductor 205_2a by a sputtering method.

Next, a conductive film to be the conductor 205_1b and a conductor 205_2b is formed over the conductive film to be the conductor 205_1a and the conductor 2052a. The conductive film to be the conductor 205_1b and the conductor 205_2b can be formed by a sputtering method, a CVD method, an MBE method, a PLD method, an ALD method, or the like.

In this embodiment, for the conductive film to be the conductor 205_1b and the conductor 205_2b, titanium nitride is deposited by a CVD method and tungsten is deposited over the titanium nitride by a CVD method.

Next, CMP treatment is performed to remove the conductive film to be the conductor 205_1a and the conductor 205_2a and the conductive film to be the conductor 205_1b and the conductor 205_2b that are over the insulator 216. Consequently, the conductive film to be the conductor 205_1a and the conductor 205_2a and the conductive film to be the conductor 205_1b and the conductor 205_2b are left only in the depression portion, whereby the conductor 205_1 and the conductor 205_2 with flat top surfaces can be formed (see FIG. 4).

Next, the insulator 220 is formed over the insulator 216, the conductor 205_1, and the conductor 205_2. The insulator 220 can be formed by a sputtering method, a CVD method, an MBE method, a PLD method, an ALD method, or the like.

Next, the insulator 222 is formed over the insulator 220. The insulator 222 can be formed by a sputtering method, a CVD method, an MBE method, a PLD method, an ALD method, or the like.

Next, the insulator 224 is formed over the insulator 222. The insulator 224 can be formed by a sputtering method, a CVD method, an MBE method, a PLD method, an ALD method, or the like.

Next, first heat treatment is preferably performed. The first heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. The first heat treatment is performed in a nitrogen atmosphere, an inert gas atmosphere, or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen. Through the first heat treatment, impurities such as hydrogen and water contained in the insulator 224 can be removed, for example. Alternatively, in the first heat treatment, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be generated, and application of the RF to the substrate side allows the oxygen radicals generated by the high-density plasma to be efficiently introduced into the insulator 224. Alternatively, after plasma treatment containing an inert gas is performed with this apparatus, plasma treatment containing oxygen may be performed to compensate for released oxygen. Note that the first heat treatment is not necessarily performed in some cases.

The heat treatment can be performed after the formation of the insulator 220, after the formation of the insulator 222, and after the formation of the insulator 224. Although the above conditions can be used for the heat treatment, the heat treatment after the formation of the insulator 220 is preferably performed in an atmosphere containing nitrogen.

In this embodiment, as the first heat treatment, treatment is performed at 400° C. in a nitrogen atmosphere for one hour after the formation of the insulator 224.

Next, an oxide film 230A and an oxide film 230B are formed in this order over the insulator 224 (see FIG. 4). Note that it is preferred that the oxide film 230A and the oxide film 230B be successively formed without being exposed to the air. When film formation is performed in such a manner, impurities or moisture from the air can be prevented from being attached to the oxide film 230A, and an interface between the oxide film 230A and the oxide film 230B and the vicinity thereof can be kept clean.

The oxide film 230A and the oxide film 230B can be formed by a sputtering method, a CVD method, an MBE method, a PLD method, an ALD method, or the like.

For example, in the case where the oxide film 230A and the oxide film 230B are formed by a sputtering method, oxygen or a mixed gas of oxygen and a rare gas is used as a sputtering gas. Increasing the proportion of oxygen contained in the sputtering gas can increase the amount of excess oxygen in the oxide film to be formed. In addition, in the case where the oxide film 230A and the oxide film 230B are formed by a sputtering method, an In-M-Zn oxide target can be used.

In particular, at the time of the formation of the oxide film 230A, part of oxygen contained in the sputtering gas is supplied to the insulator 224 in some cases.

Note that the proportion of oxygen contained in the sputtering gas at the time of the formation of the oxide film 230A is higher than or equal to 70%, preferably higher than or equal to 80%, further preferably 100%.

When the proportion of oxygen contained in the sputtering gas at the time of the formation of the oxide film 230B is higher than or equal to 1% and lower than or equal to 30% and preferably higher than or equal to 5% and lower than or equal to 20%, an oxygen-deficient oxide semiconductor is formed. In a transistor using an oxygen-deficient oxide semiconductor, relatively high field-effect mobility can be obtained.

In the case where an oxygen-deficient oxide semiconductor is used for the oxide film 230B, an oxide film containing excess oxygen is preferably used as the oxide film 230A. Oxygen doping treatment may be performed after the formation of the oxide film 230A.

In this embodiment, the oxide film 230A is formed by a sputtering method using a target with In:Ga:Zn=1:3:4 [atomic ratio], and the oxide film 230B is formed by a sputtering method using a target with In:Ga:Zn=4:2:4.1 [atomic ratio].

The, second heat treatment may be performed. For the second heat treatment, the conditions for the first heat treatment can be used. Through the second heat treatment, impurities such as hydrogen and water contained in the oxide film 230A and the oxide film 230B can be removed, for example. In this embodiment, treatment is performed at 400° C. in a nitrogen atmosphere for one hour, and then another treatment is successively performed at 400° C. in an oxygen atmosphere for one hour.

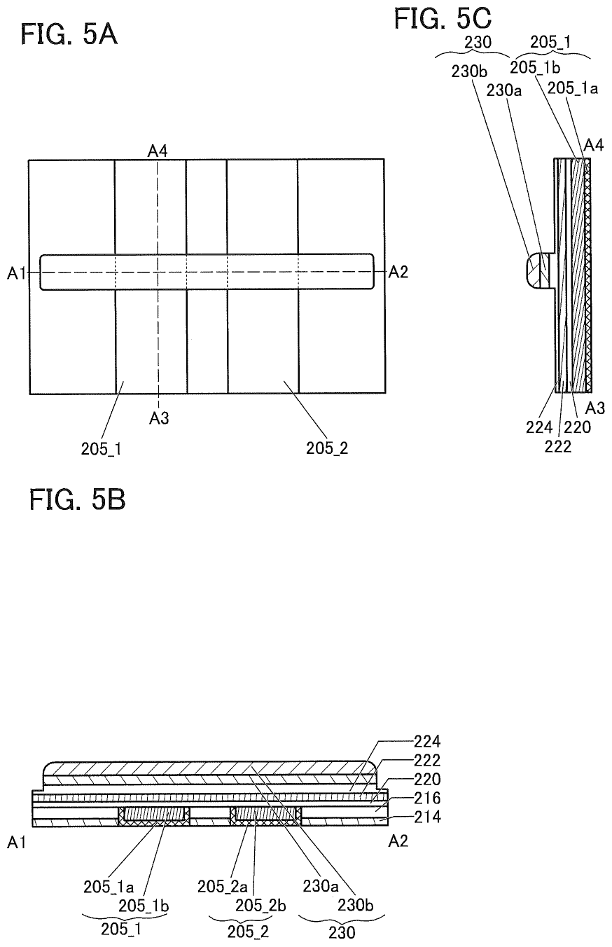

Next, the oxide film 230A and the oxide film 230B are processed into island shapes to form the oxide 230a and the oxide 230b (see FIG. 5).

Here, the oxide 230 is formed to at least partly overlap with the conductors 205. A side surface of the oxide 230 is preferably substantially perpendicular to a top surface of the insulator 222. When the side surface of the oxide 230 is substantially perpendicular to the top surface of the insulator 222, a plurality of transistors 200 can be provided in a small area with high density. Note that a structure in which an angle formed between the side surface of the oxide 230 and the top surface of the insulator 222 is an acute angle may be employed. In that case, it is preferred that the angle formed between the side surface of the oxide 230 and the top surface of the insulator 222 be as large as possible.

There is a curved surface between the side surface of the oxide 230 and the top surface of the oxide 230. That is, an end portion of the side surface and an end portion of the top surface are preferably curved (such a shape is also referred to as a rounded shape). It is preferred that the radius of curvature of the curved surface at an end portion of the oxide 230b be greater than or equal to 3 nm and less than or equal to 10 nm, preferably greater than or equal to 5 nm and less than or equal to 6 nm.

Note that when the end portions are not angular, the coverage of films formed later in the film formation process can be improved.

Note that the oxide films may be processed by a lithography method. The processing can be performed by a dry etching method or a wet etching method. A dry etching method is suitable for microfabrication.

Note that in the lithography method, first, a resist is exposed to light through a mask. Next, a region exposed to light is removed or left using a developing solution, so that a resist mask is formed. Then, etching treatment through the resist mask is performed, so that a conductor, a semiconductor, an insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a space between a substrate and a projection lens is filled with liquid (e.g., water) to perform light exposure. Furthermore, an electron beam or an ion beam may be used instead of the above-described light. Note that a mask is not necessary in the case of using an electron beam or an ion beam. Note that for removal of the resist mask, dry etching treatment such as ashing can be performed, wet etching treatment can be performed, wet etching treatment can be performed after dry etching treatment, or dry etching treatment can be performed after wet etching treatment.

A hard mask formed of an insulator or a conductor may be used instead of the resist mask. In the case of using a hard mask, an insulating film or a conductive film that is the material of the hard mask is formed over the oxide film 230B, a resist mask is formed thereover, and then the material of the hard mask is etched, so that a hard mask with a desired shape can be formed. The etching of the oxide film 230A and the oxide film 230B may be performed after the resist mask is removed or may be performed while the resist mask remains. In the latter case, the resist mask may disappear during the etching. The hard mask may be removed by etching after the etching of the oxide film 230A and the oxide film 230B. Meanwhile, in the case where the material of the hard mask does not affect the following process or can be utilized in the following process, the hard mask does not need to be removed.

As a dry etching apparatus, a capacitively coupled plasma (CCP) etching apparatus including parallel plate electrodes can be used. The capacitively coupled plasma etching apparatus including the parallel plate electrodes may have a structure in which high-frequency power is applied to one of the parallel plate electrodes. Alternatively, a structure may be employed in which different high-frequency powers are applied to one of the parallel plate electrodes. Alternatively, a structure may be employed in which high-frequency powers with the same frequency are applied to the parallel plate electrodes. Alternatively, a structure may be employed in which high-frequency powers with different frequencies are applied to the parallel plate t electrodes. Alternatively, a dry etching apparatus including a high-density plasma source can be used. As the dry etching apparatus including a high-density plasma source, an inductively coupled plasma (ICP) etching apparatus can be used, for example.

In some cases, treatment such as dry etching performed in the above process causes the attachment or diffusion of impurities due to an etching gas or the like to a surface or an inside of the oxide 230a, the oxide 230b, and the like. Examples of the impurities include fluorine and chlorine.

In order to remove the above impurities and the like, cleaning is performed. Examples of a cleaning method include wet cleaning using a cleaning solution or the like, plasma treatment using plasma, and cleaning by heat treatment; the cleaning methods may be performed in appropriate combination.

As the wet cleaning, cleaning treatment may be performed using an aqueous solution obtained by diluting an oxalic acid, a phosphoric acid, a hydrofluoric acid, or the like with carbonated water or pure water. Alternatively, ultrasonic cleaning using pure water or carbonated water may be performed. In this embodiment, ultrasonic cleaning using pure water or carbonated water is performed.

Next, third heat treatment may be performed. As heat treatment conditions, the conditions for the first heat treatment can be used. Note that the third heat treatment is not necessarily performed in some cases. In this embodiment, the third heat treatment is not performed.

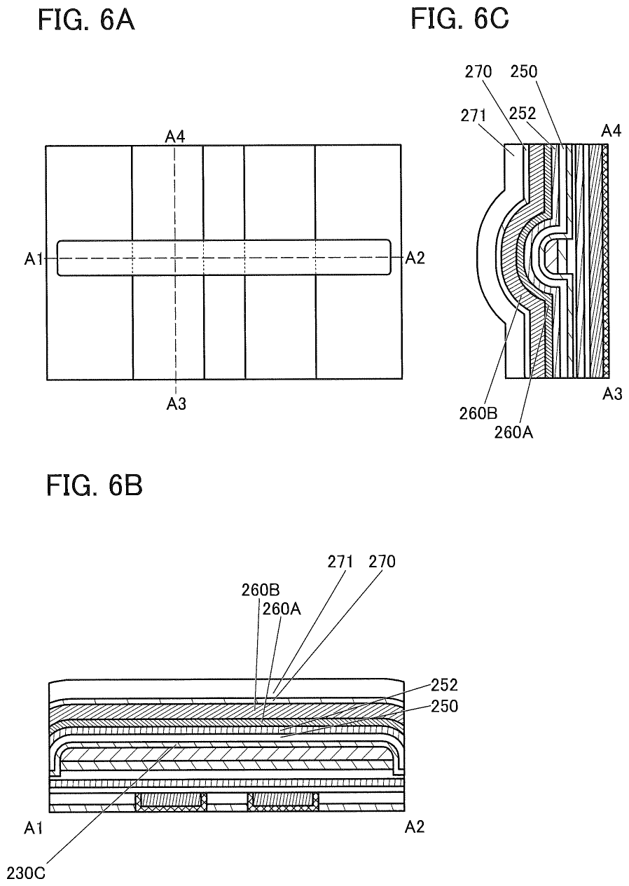

Next, an oxide film 230C, an insulating film 250, an insulating film 252, a conductive film 260A, a conductive film 260B, an insulating film 270, and an insulating film 271 are formed in this order over the insulator 224, the oxide 230a, and the oxide 230b (see FIG. 6).

The insulating film 250 and the insulating film 252 can be formed by a sputtering method, a CVD method, an MBE method, a PLD method, an ALD method, or the like.

Here, fourth heat treatment can be performed. For the fourth heat treatment, the conditions for the first heat treatment can be used. Through the heat treatment, the moisture concentration and the hydrogen concentration in the insulating film 250 can be reduced. Note that the fourth heat treatment is not necessarily performed in some cases.

The conductive film 260A and the conductive film 260B can be formed by a sputtering method, a CVD method, an MBE method, a PLD method, an ALD method, or the like.

The insulating film 270 and the insulating film 271 can be formed by a sputtering method, a CVD method, an MBE method, a PLD method, an ALD method, or the like and are preferably formed by an ALD method, in particular. When the insulating film 270 is formed by an ALD method, the thickness can be approximately 0.5 nm to 10 nm inclusive, preferably approximately 0.5 nm to 3 nm inclusive. The formation of the insulating film 270 can be omitted.

The insulating film 271 can be used as a hard mask in processing the conductive film 260A and the conductive film 260B.

Here, fifth heat treatment can be performed. For the heat treatment, the conditions for the first heat treatment can be used. Note that the fifth heat treatment is not necessarily performed in some cases.

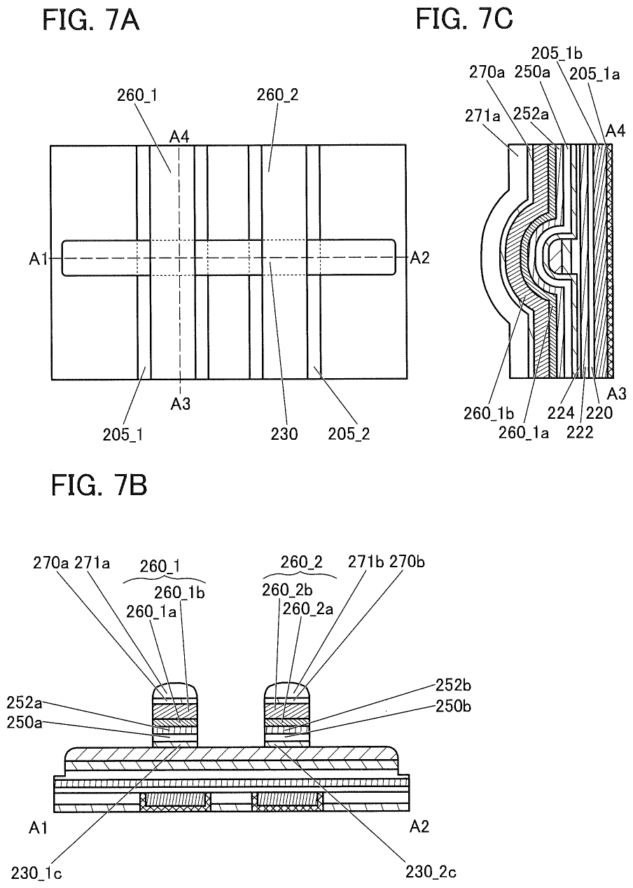

Next, the oxide film 230C, the insulating film 250, the insulating film 252, the conductive film 260A, the conductive film 260B, the insulating film 270, and the insulating film 271 are etched to form the oxide 230_1c, the insulator 250a, the insulator 252a, the conductor 260_1a, the conductor 260_1b, the insulator 270a, the insulator 271a, the oxide 230_2c, the insulator 250b, the insulator 252b, the conductor 260_2a, the conductor 260_2b, the insulator 270b, and the insulator 271b (see FIG. 7). This processing is performed by a lithography method.

Here, it is preferred that the cross-sectional shapes of the oxide 230_1c, the insulator 250a, the insulator 252a, the conductor 260_1a, the conductor 260_1b, and the insulator 270a be tapered as little as possible. Similarly, it is preferred that the cross-sectional shapes of the oxide 230_2c, the insulator 250b, the insulator 252b, the conductor 260_2a, the conductor 260_2b, and the insulator 270b be tapered as little as possible. An angle formed between a bottom surface of the oxide 230 and the side surfaces of the oxide 230_1c, the insulator 250a, the insulator 252a, the conductor 260_1a, the conductor 260_1b, and the insulator 270a is preferably greater than or equal to 80° and less than or equal to 100°. Similarly, an angle formed between the bottom surface of the oxide 230 and the side surfaces of the oxide 230_2c, the insulator 250b, the insulator 252b, the conductor 260_2a, the conductor 260_2b, and the insulator 270b is preferably greater than or equal to 80° and less than or equal to 100°. Accordingly, the insulator 275a, the insulator 272a, and the insulator 274a are likely to remain when the insulator 275a, the insulator 272a, and the insulator 274a are formed in a later step. Similarly, the insulator 275b, the insulator 272b, and the insulator 274b are likely to remain when the insulator 275b, the insulator 272b, and the insulator 274b are formed.

Upper portions of the oxide 230b in regions not overlapping with the insulator 250a and the insulator 250b are etched by the above etching in some cases. In that case, the thickness of the oxide 230b in regions overlapping with the insulator 250a and the insulator 250b is larger than the thickness in the regions not overlapping with the insulator 250a and the insulator 250b.

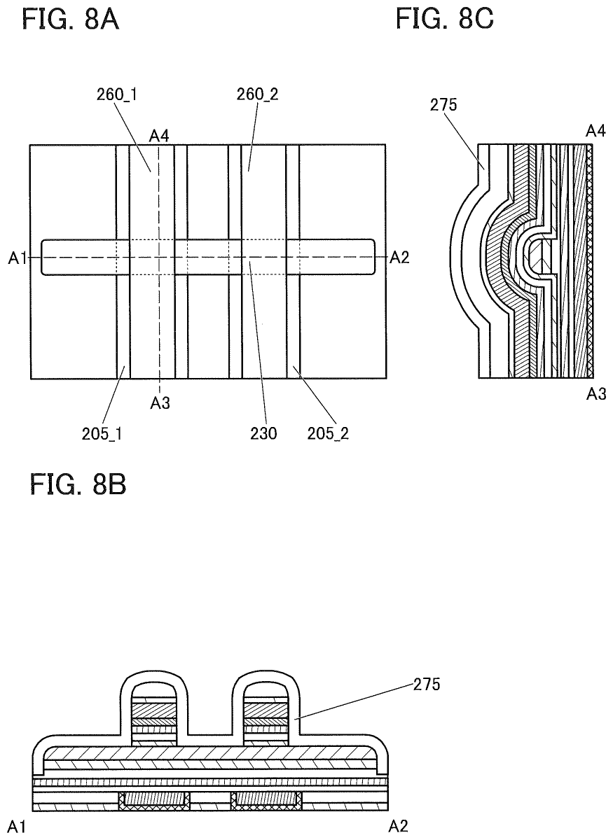

Next, an insulating film 275 is formed to cover the insulator 224, the oxide 230, the oxide 230_1c, the insulator 250a, the insulator 252a, the conductor 260_1, the insulator 270a, the insulator 271a, the oxide 230_2c, the insulator 250b, the insulator 252b, the conductor 260_2, the insulator 270b, and the insulator 271b. In this embodiment, silicon oxynitride is deposited as the insulating film 275 by a CVD method (see FIG. 8).

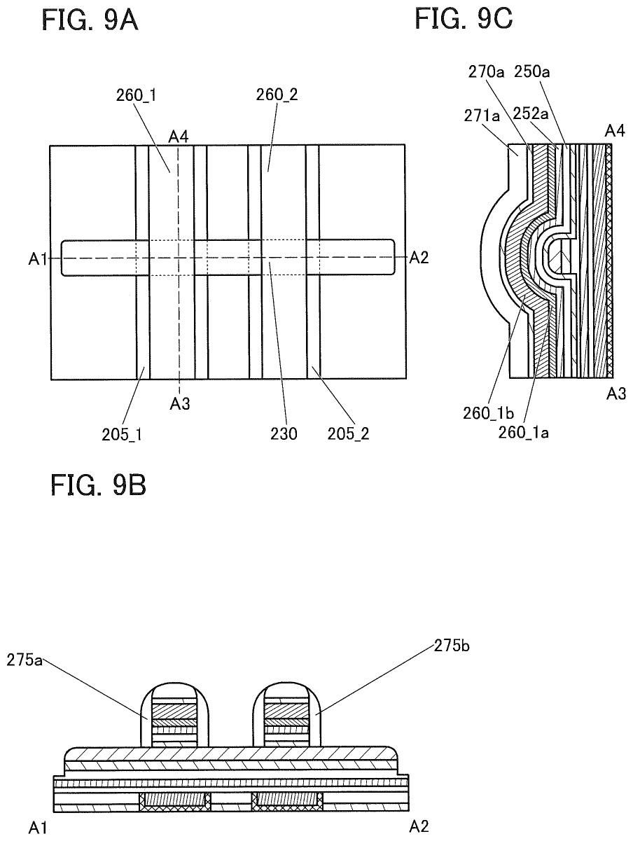

Next, anisotropic etching treatment is performed on the insulating film 275 to form the insulator 275a in contact with the side surfaces of the oxide 230_1c, the insulator 250a, the insulator 252a, the conductor 260_1, the insulator 270a, and the insulator 271a. In a similar manner, the insulator 275b is formed in contact with the side surfaces of the oxide 230_2c, the insulator 250b, the insulator 252b, the conductor 260_2, the insulator 270b, and the insulator 271b (see FIG. 9). Dry etching treatment is preferably performed as the anisotropic etching treatment. Consequently, the insulating film 275 formed on a plane substantially parallel to a substrate surface is removed and the insulator 275a and the insulator 275b can be formed in a self-aligned manner.

Next, an insulating film 272 is formed by an ALD method. When the insulating film 272 is formed by an ALD method, the thickness can be approximately 0.5 nm to 10 nm inclusive, preferably approximately 0.5 nm to 3 nm inclusive. When the insulating film 272 is formed by an ALD method, even when the aspect ratio of a structure body formed of the oxide 230_1c, the insulator 250a, the insulator 252a, the conductor 260_1, the insulator 270a, and the insulator 271a is extremely high, the insulating film 272 having few pinholes and uniform thickness can be formed on a top surface and a side surface of the structure body. The same applies to a structure body formed of the oxide 230_2c, the insulator 250b, the insulator 252b, the conductor 260_2, the insulator 270b, and the insulator 271b. In this embodiment, aluminum oxide is deposited as the insulating film 272 by an ALD method.

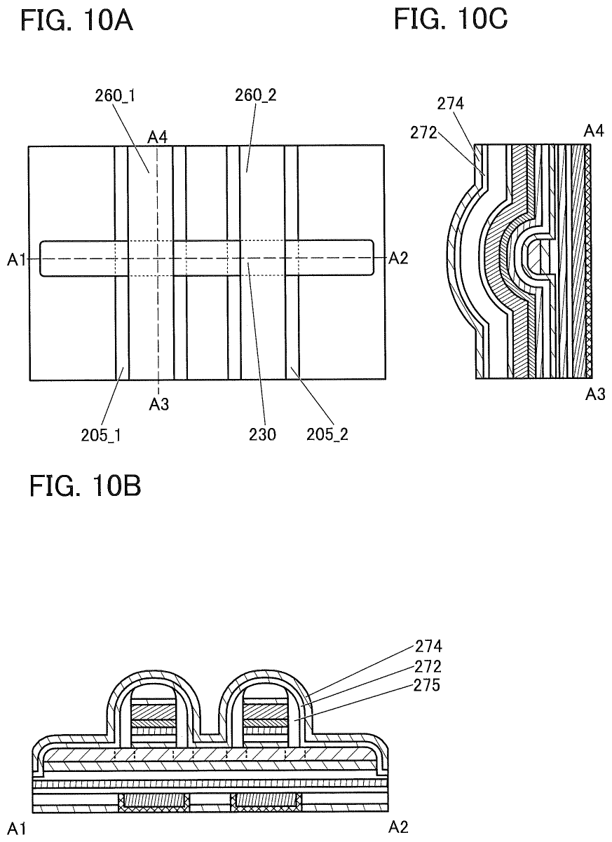

Next, an insulating film 274 is formed over the insulating film 272. The formation of the insulating film 274 is preferably performed in an atmosphere containing at least one of nitrogen and hydrogen. When the formation is performed in such an atmosphere, oxygen vacancies can be formed mainly in the regions of the oxide 230b not overlapping with the insulator 250a and the insulator 250b and the oxygen vacancies and impurity elements such as nitrogen or hydrogen can be bonded to each other, leading to an increase in carrier density. In this manner, the region 231 and the junction region 232 with reduced resistance can be formed. For the insulating film 274, for example, silicon nitride or silicon nitride oxide formed by a CVD method can be used. In this embodiment, silicon nitride oxide is used for the insulating film 274 (see FIG. 10).

As described above, in the method for manufacturing a semiconductor device described in this embodiment, a source region and a drain region can be formed in a self-aligned manner owing to the formation of the insulating film 274, even in a minute transistor whose channel length is approximately 10 nm to 30 nm. Thus, miniaturized or highly integrated semiconductor devices can be manufactured with high yield.

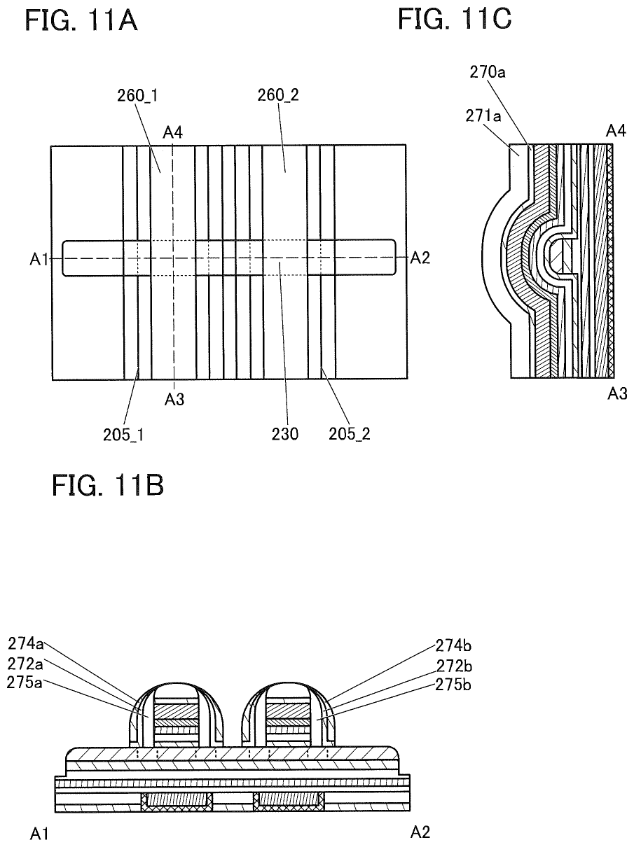

Next, anisotropic etching treatment is performed on the insulating film 272 and the insulating film 274 to form the insulator 272a, the insulator 274a, the insulator 272b, and the insulator 274b (see FIG. 11). Dry etching treatment is preferably performed as the anisotropic etching treatment. Consequently, the insulating film 272 and the insulating film 274 formed on a plane substantially parallel to the substrate surface are removed and the insulator 272a, the insulator 274a, the insulator 272b, and the insulator 274b can each be formed in a self-aligned manner.

Next, the insulator 280 is formed. The insulator 280 can be formed by a sputtering method, a CVD method, an MBE method, a PLD method, an ALD method, or the like. Alternatively, a spin coating method, a dipping method, a droplet discharging method (e.g., an ink-jet method), a printing method (e.g., screen printing or offset printing), a doctor knife method, a roll coater method, a curtain coater method, or the like can be used. In this embodiment, silicon oxynitride is used for the insulator 280.

The insulator 280 is preferably formed to have a flat top surface. For example, the top surface of the insulator 280 may have flatness immediately after the formation. Alternatively, for example, the insulator 280 may have flatness by removing an insulator and the like from the top surface after the formation so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not need to have flatness.

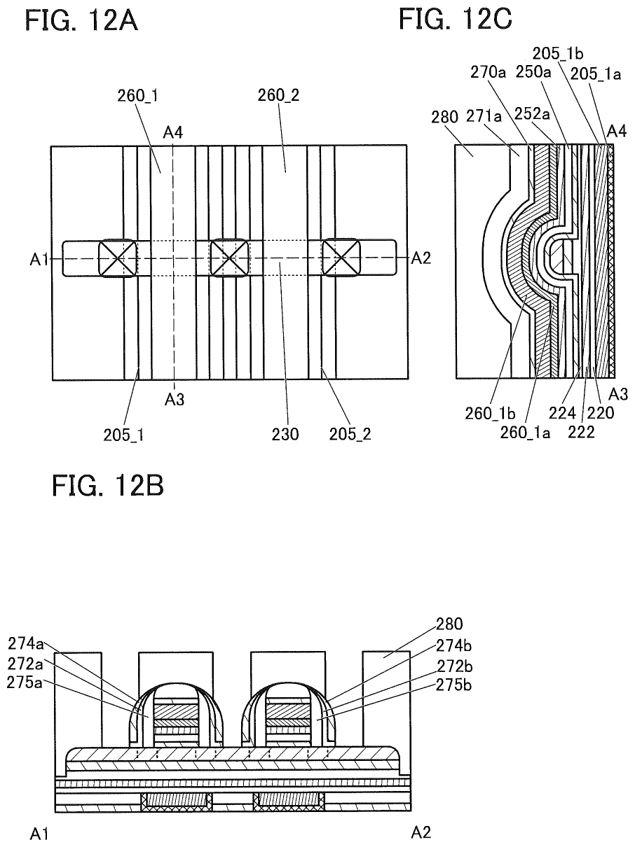

Next, openings reaching the regions 231 of the oxide 230 are formed in the insulator 280 (see FIG. 12). A lithography method is used for the formation of the openings. Here, the openings are formed such that the conductor 240a, the conductor 240b, and the conductor 240c are provided in contact with the side surface of the insulator 274a, the side surfaces of the insulator 274a and the insulator 274b, and the side surface of the insulator 274b, respectively. The opening conditions are preferably conditions where the insulator 274a and the insulator 274b are hardly etched, i.e., conditions where the etching rate of the insulator 280 is higher than the etching rates of the insulator 274a and the insulator 274b. When the etching rates of the insulator 274a and the insulator 274b are 1, the etching rate of the insulator 280 is preferably 5 or more, further preferably 10 or more. With such opening conditions, the opening portions can be positioned on the regions 231 in a self-aligned manner; thus, a miniaturized transistor can be manufactured. In addition, tolerance of misalignment of each opening and the conductor 260_1 and the conductor 260_2 in a lithography process is high; thus, the yield should be improved.

Next, a conductive film to be the conductor 240a, the conductor 240b, and the conductor 240c is formed. The conductive film to be the conductor 240a, the conductor 240b, and the conductor 240c desirably has a stacked-layer structure which includes a conductor having a function of inhibiting the passage of impurities such as water or hydrogen. For example, stacked layers of tantalum nitride, titanium nitride, or the like and tungsten, molybdenum, copper, or the like can be employed. The conductive film to be the conductor 240a, the conductor 240b, and the conductor 240c can be formed by a sputtering method, a CVD method, an MBE method, a PLD method, an ALD method, or the like.

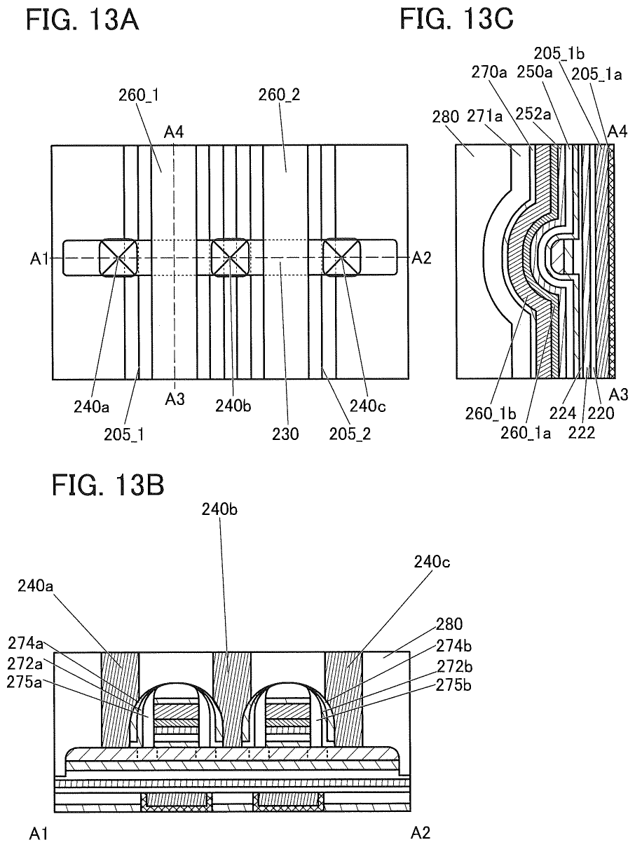

Next, CMP treatment is performed to remove the conductive film to be the conductor 240a, the conductor 240b, and the conductor 240c over the insulator 280. As a result, the conductors remain only in the above-described openings, whereby the conductor 240a, the conductor 240b, and the conductor 240c having flat top surfaces can be formed (see FIG. 13).

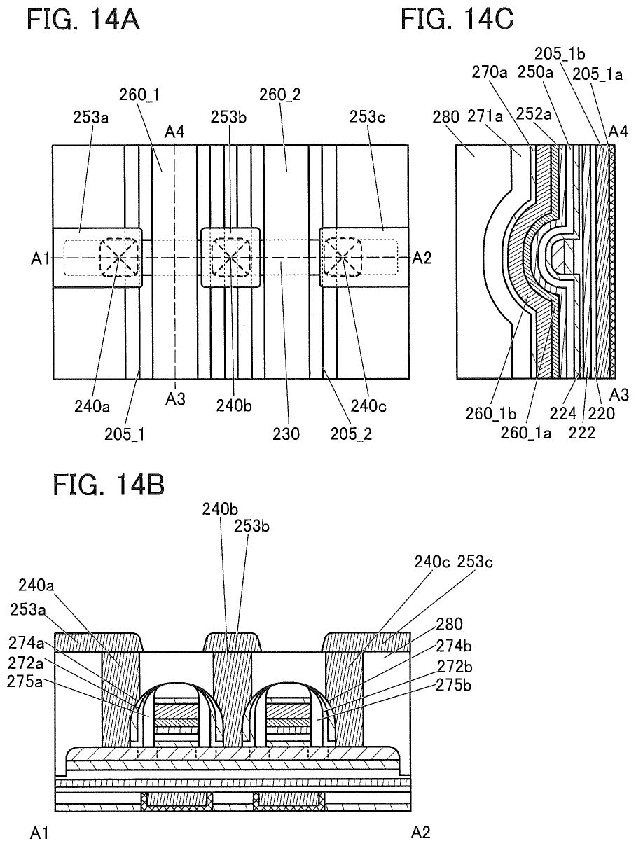

Next, a conductive film to be the conductor 253a, the conductor 253b, and the conductor 253c is formed and the conductive film is processed by a lithography method, so that the conductor 253a, the conductor 253b, and the conductor 253c are formed (see FIG. 14). The conductive film to be the conductor 253a, the conductor 253b, and the conductor 253c can be formed by a sputtering method, a CVD method, an MBE method, a PLD method, an ALD method, or the like. The conductive film to be the conductor 253a, the conductor 253b, and the conductor 253c may be formed to be embedded in an insulator.

Accordingly, the semiconductor device including the transistor 200a and the transistor 200b can be manufactured.

The structures, methods, and the like described above in this embodiment can be used in an appropriate combination with the structures, methods, and the like described in the other embodiments.

### Embodiment 2

In this embodiment, a semiconductor device having a structure different from that in Embodiment 1 is described.

A semiconductor device of one embodiment of the present invention is a semiconductor device including an oxide in a channel formation region, and the semiconductor device includes a first transistor, a second transistor, a first wiring, a second wiring, and a third wiring.

The first transistor includes an oxide over a first insulator, a second insulator over the oxide, a first conductor over the second insulator, a third insulator over the first conductor, a fourth insulator in contact with the second insulator, the first conductor, and the third insulator, and fifth insulator in contact with the fourth insulator. The second transistor includes the oxide over the first insulator, a sixth insulator over the oxide, a second conductor over the sixth insulator, a seventh insulator over the second conductor, an eighth insulator in contact with the sixth insulator, the second conductor, and the seventh insulator, and a ninth insulator in contact with the eighth insulator.

The oxide includes first regions overlapping with the second insulator and the sixth insulator, second regions overlapping with the fourth insulator and the eighth insulator, third regions in contact with the second regions, and fourth regions in contact with the third regions. The first wiring is electrically connected to the fourth region of the first transistor, the second wiring is electrically connected to the fourth region of the second transistor, and the third wiring is in contact with the fifth insulator and the ninth insulator and is electrically connected to the fourth region.

In one embodiment of the present invention, the above-described connection of the plurality of transistors and the plurality of wirings can lead to provision of a semiconductor device that can be miniaturized or highly integrated.

Details are described with reference to drawings.

### <Structure Example 1 of Semiconductor Device>

An example of a semiconductor device of one embodiment of the present invention including the transistor 200a and the transistor 200b is described below.

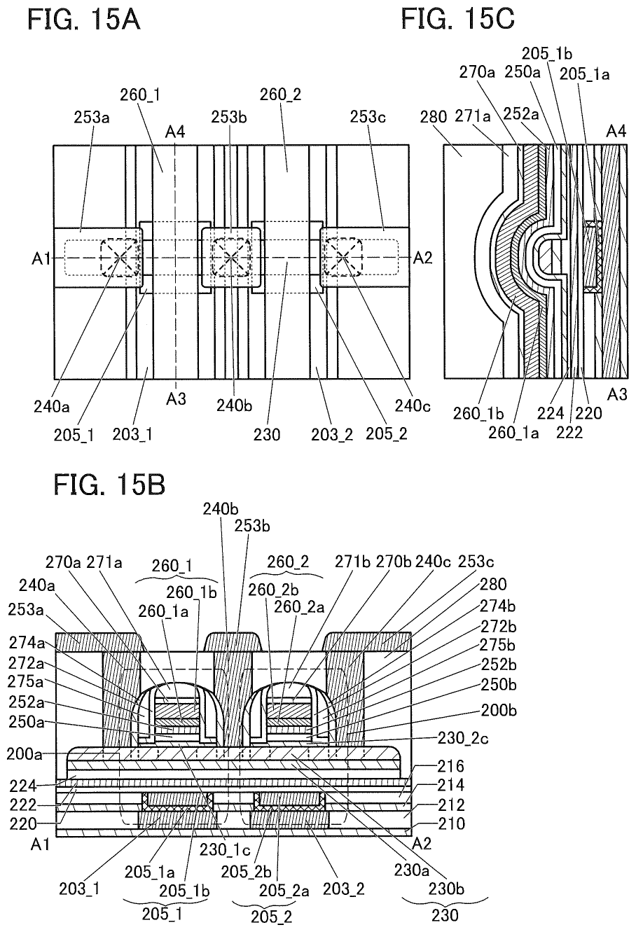

FIG. 15(A) is a top view of the semiconductor device including the transistor 200a and the transistor 200b. FIG. 15(B) is a cross-sectional view of a portion indicated by a dashed-dotted line A1-A2 in FIG. 15(A) and also is a cross-sectional view of the transistor 200a and the transistor 200b in a channel length direction. FIG. 15(C) is a cross-sectional view of a portion indicated by a dashed-dotted line A3-A4 in FIG. 15(A) and also is a cross-sectional view of the transistor 200a in a channel width direction. For simplification of the drawing, some components are not illustrated in the top view in FIG. 15(A).

The semiconductor device of one embodiment of the present invention includes the transistor 200a and the transistor 200b, and an insulator 210, an insulator 212, and the insulator 280 functioning as interlayer films. In addition, a conductor 203_1 that is electrically connected to the transistor 200a and functions as a wiring, a conductor 203_2 that is electrically connected to the transistor 200b and functions as a wiring, the conductors 240 (the conductor 240a, the conductor 240b, and the conductor 240c) functioning as plugs, and the conductors 253 (the conductor 253a, the conductor 253b, and the conductor 253c) functioning as wirings are included.

Note that the conductor 203_1 is formed to be embedded in the insulator 212. Here, a top surface of the conductor 203_1 can be substantially level with a top surface of the insulator 212. Note that although a structure in which the conductor 203_1 is a single layer is illustrated, the present invention is not limited thereto. For example, the conductor 203_1 may have a multilayer film structure of two or more layers.

As with the conductor 203_1, the conductor 203_2 is formed to be embedded in the insulator 212. Here, the top surface of the conductor 203_1 can be substantially level with the top surface of the insulator 212. Note that although a structure in which the conductor 203_1 is a single layer is illustrated, the present invention is not limited thereto. For example, the conductor 203_1 may have a multilayer film structure of two or more layers.

As in FIG. 15, the transistor 200a includes the insulator 214 and the insulator 216 positioned over a substrate (not illustrated); the conductor 205_1 positioned to be embedded in the insulator 214 and the insulator 216; the insulator 220 positioned over the conductor 205_1 and over the insulator 216; the insulator 222 positioned over the insulator 220; the insulator 224 positioned over the insulator 222; the oxide 230 (the oxide 230a and the oxide 230b) positioned over the insulator 224; the oxide 230_1c positioned over the oxide 230; the insulator 250a positioned over the oxide 230_1c; the insulator 252a positioned over the insulator 250a; the conductor 260_1 (the conductor 260_1a and the conductor 260_1b) positioned over the insulator 252a; the insulator 270a positioned over the conductor 260_1; the insulator 271a positioned over the insulator 270a; the insulator 272a positioned to be in contact with at least a top surface of the oxide 230_1c, a side surface of the insulator 250a, a side surface of the insulator 252a, a side surface of the conductor 260_1, and a side surface of the insulator 270a; the insulator 275a positioned to be in contact with at least the insulator 272a; and the insulator 274a positioned to be in contact with at least a top surface of the oxide 230 and a side surface of the insulator 275a.

The transistor 200b includes the insulator 214 and the insulator 216 positioned over the substrate (not illustrated); the conductor 205_2 positioned to be embedded in the insulator 214 and the insulator 216; the insulator 220 positioned over the conductor 205_2 and over the insulator 216; the insulator 222 positioned over the insulator 220; the insulator 224 positioned over the insulator 222; the oxide 230 (the oxide 230a and the oxide 230b) positioned over the insulator 224; the oxide 230_2c positioned over the oxide 230; the insulator 250b positioned over the oxide 230_2c; the insulator 252b positioned over the insulator 250b; the conductor 260_2 (the conductor 260_2a and the conductor 260_2b) positioned over the insulator 252b; the insulator 270b positioned over the conductor 260_2; the insulator 271b positioned over the insulator 270b; the insulator 272b positioned to be in contact with at least a top surface of the oxide 230_2c, a side surface of the insulator 250b, a side surface of the insulator 252b, a side surface of the conductor 260_2, and a side surface of the insulator 270b; the insulator 275b positioned to be in contact with at least the insulator 272b; and the insulator 274b positioned to be in contact with at least the top surface of the oxide 230 and a side surface of the insulator 275b.

Note that the oxide 230a and the oxide 230b in the transistor 200a and the transistor 200b are collectively referred to as the oxide 230 in some cases. Although structures of the transistor 200a and the transistor 200b in which the oxide 230a and the oxide 230b are stacked are illustrated, the present invention is not limited to this. For example, structures in which only the oxide 230b is provided may be employed. Furthermore, the conductor 260_1a and the conductor 260_1b are collectively referred to as the conductor 260_1, and the conductor 260_2a and the conductor 260_2b are collectively referred to as the conductor 260_2, in some cases. Although structures of the transistor 200a and the transistor 200b in which the conductor 260_1a and the conductor 260_1b are stacked and the conductor 260_2a and the conductor 260_2b are stacked are illustrated, the present invention is not limited to this. For example, structures in which only the conductor 260_1b and the conductor 260_2b are provided may be employed. Note that as described above, the transistor 200a and the transistor 200b have similar structures. Thus, unless otherwise specified, the description for the transistor 200a can be referred to for the transistor 200b below. In other words, the conductor 205_1, the oxide 230c_1, the insulator 250a, the insulator 252a, the conductor 260_1, the insulator 270a, the insulator 271a, the insulator 272a, the insulator 275a, and the insulator 274a of the transistor 200a correspond to the conductor 205_2, the oxide 230c_2, the insulator 250b, the insulator 252b, the conductor 260_2, the insulator 270b, the insulator 271b, the insulator 272b, the insulator 275b, and the insulator 274b of the transistor 200b, respectively.

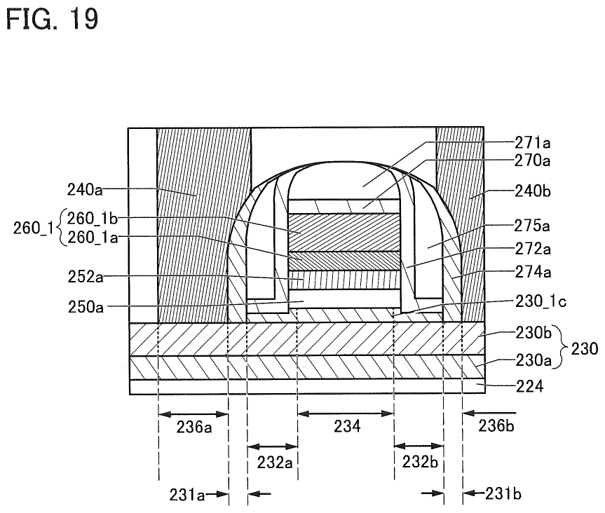

Here, an enlarged view of a channel of the transistor 200a and a region in the vicinity thereof, which are surrounded by a dashed line in FIG. 15(B), is illustrated in FIG. 19.

As illustrated in FIG. 19, the oxide 230 includes the region 234 functioning as a channel formation region of the transistor 200a, the region 231 (the region 231a and the region 231b) functioning as a source region or a drain region, the junction region 232 (the junction region 232a and the junction region 232b) provided between the region 234 and the region 231, and a region 236 (a region 236a and a region 236b) where the oxide 230 is in contact with the conductor 240 (the conductor 240a and the conductor 240b).

Note that in this specification and the like, the region 234 is referred to as a first region in some cases. Furthermore, the junction region 232 is referred to as a second region in some cases. In addition, the region 231 is referred to as a third region in some cases. Moreover, the region 236 is referred to as a fourth region in some cases.

The region 236 where the oxide 230 is in contact with the conductor 240 and the region 231 functioning as the source region or the drain region are both a region whose carrier density is high and resistance is reduced; the region 236 has higher carrier density than the region 231. That is, the region 236 has lower resistance than the region 231. The region 234 functioning as the channel formation region is a region whose carrier density is lower than the region 231 functioning as the source region or the drain region. The junction region 232 is a region whose carrier density is lower than the region 231 functioning as the source region or the drain region and is higher than the region 234 functioning as the channel formation region. That is, the junction region 232 functions as a junction region between the channel formation region and the source region or the drain region.

The region 236 where the oxide 230 is in contact with the conductor 240 makes an electrical connection between the conductor 240 and the oxide 230 favorable; in addition, when the junction region 232 is provided, a high-resistance region is not formed between the region 231 functioning as the source region or the drain region and the region 234 functioning as the channel formation region, thereby increasing the on-state current of the transistor.

The junction region 232 sometimes functions as what is called an overlap region (also referred to as an Lov region) that overlaps with the conductor 260_1 functioning as a gate electrode.

Note that it is preferred that the region 231 be in contact with the insulator 274a. In addition, it is preferred that the region 231 have higher concentration of at least one of a metal element such as indium and an impurity element such as hydrogen and nitrogen than the junction region 232 and the region 234.

The junction region 232 has a region overlapping with the insulator 272a. It is preferred that the junction region 232 have higher concentration of at least one of a metal element such as indium and an impurity element such as hydrogen and nitrogen than the region 234. Meanwhile, it is preferred that the junction region 232 have lower concentration of at least one of a metal element such as indium and an impurity element such as hydrogen and nitrogen than the region 231.

The region 234 overlaps with the conductor 260_1. The region 234 is positioned between the junction region 232a and the junction region 232b, and it is preferred that the region 234 have lower concentration of at least one of a metal element such as indium and an impurity element such as hydrogen and nitrogen than the region 231, the junction region 232, and the region 236.

In the oxide 230, boundaries between the region 231, the junction region 232, the region 234, and the region 236 cannot be found clearly in some cases. The concentrations of a metal element such as indium and an impurity element such as hydrogen and nitrogen detected in each region may be not only gradually changed between the regions, but also continuously changed (also referred to as gradation) in each region. In other words, the region closer to the region 234, from the region 231 to the junction region 232, has a lower concentration of a metal element such as indium and an impurity element such as hydrogen and nitrogen.

The region 234, the region 231, the junction region 232, and the region 236 are formed in the oxide 230b in FIG. 19 without being limited thereto; for example, these regions may be formed in the oxide 230a. Furthermore, although the boundaries between the regions are shown substantially perpendicular to a top surface of the oxide 230 in FIG. 19, this embodiment is not limited thereto. For example, the junction region 232 projects to the conductor 260 side in the vicinity of a surface of the oxide 230b and recedes to the conductor 240a side or the conductor 240b side in the vicinity of a bottom surface of the oxide 230b in some cases.

Note that in the transistor 200a, it is preferred to use a metal oxide functioning as an oxide semiconductor (hereinafter, also referred to as an oxide semiconductor) for the oxide 230. Since a transistor using an oxide semiconductor has an extremely low leakage current (off-state current) in a non-conduction state, a semiconductor device with low power consumption can be provided. In addition, an oxide semiconductor can be formed by a sputtering method or the like and thus can be used for a transistor consisting in a highly integrated semiconductor device.

On the other hand, the transistor using an oxide semiconductor is likely to have its electrical characteristics changed by impurities and oxygen vacancies in the oxide semiconductor; as a result, the reliability is reduced, in some cases. Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. A transistor using an oxide semiconductor containing oxygen vacancies in a channel formation region is likely to have normally-on characteristics. Thus, it is preferred that oxygen vacancies in the channel formation region be reduced as much as possible.

In particular, when oxygen vacancies exist at the interface between the oxide 230_1c and the insulator 250a functioning as a gate insulating film, it is likely that the electrical characteristics are changed, or the reliability is reduced in some cases.

In view of the above, the insulator 250a which overlaps with the region 234 of the oxide 230 preferably contains oxygen at a higher proportion than oxygen in the stoichiometric composition (also referred to as “excess oxygen”). That is, excess oxygen in the insulator 250a is diffused into the region 234, whereby oxygen vacancies in the region 234 can be reduced.

It is also preferred that the insulator 272a be provided in contact with the side surface of the insulator 250a. For example, the insulator 272a preferably has a function of inhibiting diffusion of at least one of oxygen atoms, oxygen molecules, and the like, or at least one of the oxygen atoms, oxygen molecules, and the like is less likely to penetrate the insulator 272a. When the insulator 272a has a function of inhibiting diffusion of oxygen, oxygen in the insulator 250a is not diffused to the insulator 274a side and supplied to the region 234 efficiently. It is also preferred that the insulator 272a is an insulator in which impurities such as water or hydrogen are reduced. It is also preferred to use an insulator having a barrier property that prevents entry of impurities such as water or hydrogen. Such a function can prevent entry of impurities such as water or hydrogen into the region 234. According to the above, formation of oxygen vacancies at the interface between the oxide 230_1c and the insulator 250a can be inhibited, leading to an improvement in the reliability of the transistor 200a.

Moreover, the transistor 200a is preferably covered with an insulator having a barrier property that prevents entry of impurities such as water or hydrogen. The insulator having a barrier property is an insulator using an insulating material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms, or an insulating material through which the impurities are less likely to pass. The insulator is preferably formed using an insulating material having a function of inhibiting diffusion of at least one of oxygen atoms and oxygen molecules, or an insulating material through which at least one of the oxygen atoms and oxygen molecules is less likely to pass.

The structure of the semiconductor device including the transistor 200a and the transistor 200b of one embodiment of the present invention is described in detail below. Note that also in the following description, the description of the transistor 200a can be referred to for the structure of the transistor 200b.

The conductor 205_1 functioning as a second gate electrode of the transistor 200a is positioned to overlap with the oxide 230 and the conductor 260_1.

Here, the conductor 205_1 is preferably provided such that the length in the channel width direction becomes larger than that of the region 234 in the oxide 230. It is particularly preferred that the conductor 205_1 extend also in a region on an outer side than an end portion of the region 234 in the oxide 230 that intersects with the channel width direction. In other words, the conductor 205_1 and the conductor 260_1 preferably overlap with each other with an insulator provided therebetween at a side surface of the oxide 230 in the channel width direction.

Here, the conductor 260_1 functions as a first gate electrode of the transistor 200a in some cases. Furthermore, the conductor 205_1 functions as the second gate electrode of the transistor 200a in some cases. A potential applied to the conductor 205_1 may be the same potential as a potential applied to the conductor 260_1, or may be a ground potential or a given potential. By changing a potential applied to the conductor 205_1 not in synchronization with but independently of a potential applied to the conductor 260_1, the threshold voltage of the transistor 200a can be controlled. In particular, by applying a negative potential to the conductor 205_1, the threshold voltage of the transistor 200a can be higher than 0 V and the off-state current can be reduced. Accordingly, a drain current when a voltage applied to the conductor 260_1 is 0 V can be low.

As illustrated in FIG. 15(A), the conductor 205_1 is provided to overlap with the oxide 230 and the conductor 260_1. Here, the conductor 205_1 is preferably provided to overlap with the conductor 260_1 also in the region on an outer side than the end portion of the oxide 230 that intersects with the channel width direction (W length direction). In other words, the conductor 205_1 and the conductor 260_1 preferably overlap with each other with an insulator therebetween outside the side surface of the oxide 230 in the channel width direction.

With the above structure, when potentials are applied to the conductor 260_1 and the conductor 205_1 and an electric field generated from the conductor 260_1 and an electric field generated from the conductor 205_1 are connected, a closed circuit is formed and the channel formation region formed in the oxide 230 can be covered.

That is, the channel formation region in the region 234 can be electrically surrounded by the electric field of the conductor 260_1 functioning as the first gate electrode and the electric field of the conductor 205_1 functioning as the second gate electrode. In this specification, a transistor structure in which the channel formation region is electrically surrounded by the electric fields of the first gate electrode and the second gate electrode is referred to as a surrounded channel (S-channel) structure.

The conductor 205_1 is preferably positioned to overlap with the oxide 230 and the conductor 260_1.

As with the conductor 260_1, the conductor 203_1 extends in the channel width direction and functions as a wiring through which a potential is applied to the conductor 205_1, i.e., a back gate. Here, when the conductor 205_1 that is embedded in the insulator 214 and the insulator 216 is provided to be stacked over the conductor 203_1 functioning as the wiring for the back gate, the insulator 214, the insulator 216, and the like are provided between the conductor 203_1 and the conductor 260_1, whereby the parasitic capacitance between the conductor 203_1 and the conductor 260_1 can be reduced and the withstand voltage can be increased. The reduction in the parasitic capacitance between the conductor 203_1 and the conductor 260_1 can improve the switching speed of the transistor, so that the transistor can have high frequency characteristics. Furthermore, the increase in the withstand voltage between the conductor 203_1 and the conductor 260_1 can improve the reliability of the transistor. Thus, the thicknesses of the insulator 214 and the insulator 216 are preferably large. Note that the extending direction of the conductor 203_1 is not limited thereto; for example, the conductor 203_1 may extend in the channel length direction of the transistor.

In the conductor 205_1, the conductor 205_1a is formed in contact with an inner wall of an opening of the insulator 214 and the insulator 216, and the conductor 205_1b is formed further inside. Here, a top surface of the conductor 205_1b can be substantially level with a top surface of the insulator 216. Although a structure in which the conductor 205_1a and the conductor 205_1b are stacked in the transistor 200a is illustrated, the present invention is not limited thereto. For example, a structure in which only one of the conductor 205_1a and the conductor 205_1b is provided may be employed.

Here, it is preferred to use a conductive material that has a function of inhibiting the passage of impurities such as water or hydrogen, or a conductive material through which the impurities are less likely to pass, for the conductor 205_1a. For example, tantalum, tantalum nitride, ruthenium, ruthenium oxide, or the like is preferably used, and a single layer or stacked layers are used. This can inhibit diffusion of impurities such as hydrogen or water from a layer below the insulator 214 into an upper layer through the conductor 205_1. Note that it is preferred that the conductor 205_1a have a function of inhibiting the passage of at least one of oxygen atoms, oxygen molecules, and the like and impurities such as hydrogen atoms, hydrogen molecules, water molecules, oxygen atoms, oxygen molecules, nitrogen atoms, nitrogen molecules, nitrogen oxide molecules (e.g., N₂O, NO, and NO₂), and copper atoms. In the case where a conductive material having a function of inhibiting the passage of impurities is described in the following description, the conductive material preferably has a similar function. The conductor 205_1a with a function of inhibiting the passage of oxygen can prevent the conductor 205_1b from being oxidized and reduced in conductivity.

The conductor 205_1b is preferably formed using a conductive material whose main component is tungsten, copper, or aluminum. Although not illustrated, the conductor 205_1b may have a stacked-layer structure and may be, for example, stacked layers of titanium, titanium nitride, and the above-described conductive material.

The insulator 214 and the insulator 222 can function as barrier insulating films that prevent impurities such as water or hydrogen from entering the transistor from a lower layer. The insulator 214 and the insulator 222 are preferably formed using an insulating material having a function of inhibiting the passage of impurities such as water or hydrogen. For example, it is preferred that silicon nitride or the like be used for the insulator 214 and aluminum oxide, hafnium oxide, an oxide containing silicon and hafnium (hafnium silicate), an oxide containing aluminum and hafnium (hafnium aluminate), or the like be used for the insulator 222. This can inhibit diffusion of impurities such as hydrogen or water to a layer positioned above the insulator 214 and the insulator 222. Note that it is preferred that the insulator 214 and the insulator 222 have a function of inhibiting the passage of at least one of impurities such as hydrogen atoms, hydrogen molecules, water molecules, nitrogen atoms, nitrogen molecules, nitrogen oxide molecules (e.g., N₂O, NO, and NO₂), and copper atoms.

Furthermore, the insulator 214 and the insulator 222 are preferably formed using an insulating material having a function of inhibiting the passage of oxygen (e.g., oxygen atoms or oxygen molecules). This can inhibit downward diffusion of oxygen contained in the insulator 224 or the like.

Moreover, the concentration of impurities such as water, hydrogen, or nitrogen oxide in the insulator 222 is preferably lowered. The amount of hydrogen released from the insulator 222, which is converted into hydrogen molecules per unit area of the insulator 222, is less than or equal to 2×10¹⁵ molecules/cm², preferably less than or equal to 1×10¹⁵ molecules/cm², further preferably less than or equal to 5×10¹⁴ molecules/cm² in thermal desorption spectroscopy (TDS) within the surface temperature range of the insulator 222 of 50° C. to 500° C., for example. The insulator 222 is preferably formed using an insulator from which oxygen is released by heating.

The insulator 250a can function as a first gate insulating film of the transistor 200a, and the insulator 220, the insulator 222, and the insulator 224 can function as second gate insulating films of the transistor 200a. Although a structure in which the insulator 220, the insulator 222, and the insulator 224 are stacked in the transistor 200a is illustrated, the present invention is not limited thereto. For example, a structure in which any two of the insulator 220, the insulator 222, and the insulator 224 are stacked may be employed, or a structure in which any one of them is used may be employed.

It is preferred to use a metal oxide functioning as an oxide semiconductor (hereinafter, also referred to as an oxide semiconductor) for the oxide 230. For the detailed description of the metal oxide functioning as an oxide semiconductor, refer to Embodiment 1.

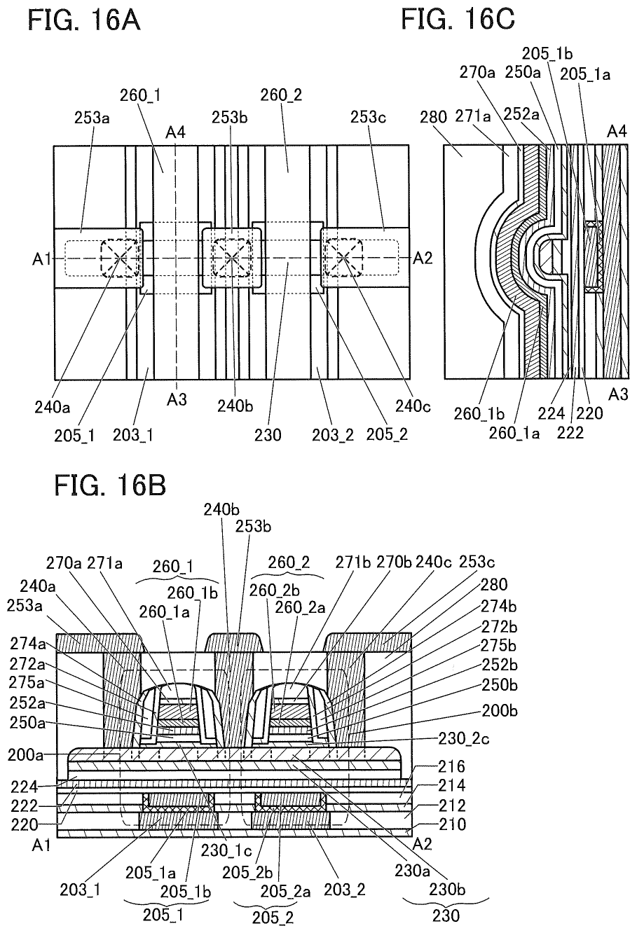

As illustrated in FIG. 15, a side surface of a structure body formed of the insulator 250a, the insulator 252a, the conductor 260_1, the insulator 270a, and the insulator 271a is preferably perpendicular to a top surface of the insulator 222. However, the semiconductor device described in this embodiment is not limited thereto. For example, a structure in which, as illustrated in FIG. 16, an angle formed between the top surface of the insulator 222 and the side surface of the structure body formed of the insulator 250a, the insulator 252a, the conductor 260_1, the insulator 270a, and the insulator 271a is an acute angle may be employed. In that case, the angle formed between the side surface of the structure body and the top surface of the insulator 222 is preferably as large as possible.

The insulator 272a is provided to be in contact with at least the side surfaces of the oxide 230_1c, the insulator 250a, the insulator 252a, the conductor 260_1, and the insulator 270a. The insulator 275a is provided to be in contact with the insulator 272a. An insulator to be the insulator 272a is preferably formed by an ALD method. By using an ALD method, an insulator having excellent coverage and few defects such as pinholes can be formed. Thus, the insulator 272a can be formed to have a thickness of approximately more than or equal to 0.5 nm and less than or equal to 10 nm, preferably more than or equal to 0.5 nm and less than or equal to 3 nm. Note that a precursor used in an ALD method sometimes contains impurities such as carbon. Thus, the insulator 272a may contain impurities such as carbon. In the case where an insulator to be the insulator 252a is formed by a sputtering method and the insulator to be the insulator 272a is formed by an ALD method, for example, the insulator 272a may contain more impurities such as carbon than the insulator 252a even when aluminum oxide is deposited as the insulator to be the insulator 272a and the insulator to be the insulator 252a. Note that impurities can be quantified by X-ray photoelectron spectroscopy (XPS).

The insulator to be the insulator 272a may be formed by a sputtering method. By using a sputtering method, an insulator containing few impurities such as water or hydrogen can be formed. In the case of using a sputtering method, a facing-target sputtering apparatus is preferably used for the film formation, for example. The facing-target sputtering apparatus is preferably used because film formation can be performed without exposing a film formation surface to a high electric field region between facing targets and thus film formation can be performed while the film formation surface is less likely to be damaged due to plasma and film formation damage to the oxide 230 during the formation of the insulator to be the insulator 272a can be small. A film formation method using the facing-target sputtering apparatus can be referred to as VDSP (Vapor Deposition SP) (registered trademark).

The region 231 and the junction region 232 of the oxide 230 are formed by impurity elements that are added when the insulator to be the insulator 274a is formed. Thus, the insulator to be the insulator 274a preferably contains at least one of hydrogen and nitrogen. Moreover, the insulator to be the insulator 274a is preferably formed using an insulating material having a function of inhibiting the passage of oxygen and impurities such as water or hydrogen. For example, the insulator to be the insulator 274a is preferably formed using silicon nitride, silicon nitride oxide, silicon oxynitride, aluminum nitride, or aluminum nitride oxide.

Instead of or in addition to the above-described method, an ion implantation method, an ion doping method by which an ionized source gas is added without mass separation, a plasma immersion ion implantation method, or the like may be used to form the region 231 and the junction region 232 of the oxide 230. The method is preferably performed after the formation of the insulator to be the insulator 272a. When the above method is performed through the insulator to be the insulator 272a, implantation damage to the oxide 230 can be reduced.

In the case where mass separation is performed in an ion doping method, a plasma immersion ion implantation method, or the like, ion species to be added and its concentration can be controlled accurately. Meanwhile, in the case of not performing mass separation, ions can be added at a high concentration in a short time. An ion doping method in which atomic or molecular clusters are generated and ionized may be employed. Note that “dopant” can be replaced with “ion,” “donor,” “acceptor,” “impurity,” “element,” or the like.

As the dopant, an element that forms an oxygen vacancy, an element that is bonded to an oxygen vacancy, or the like is used. Typical examples of such an element include hydrogen, boron, carbon, nitrogen, fluorine, phosphorus, sulfur, chlorine, titanium, and a rare gas element. Typical examples of the rare gas element are helium, neon, argon, krypton, and xenon.

In the case where the transistor is miniaturized to have a channel length of approximately 10 nm to 30 nm, impurity elements contained in the source region or the drain region might be diffused to bring electrical connection between the source region and the drain region. In regard to this, the insulator 272a and the insulator 275a are provided as described in this embodiment to keep the width of the region 234 in the oxide 230; thus, the source region and the drain region can be prevented from being electrically connected to each other.

Here, the insulator 272a is preferably formed using an insulating material that has a function of inhibiting the passage of oxygen and impurities such as water or hydrogen; for example, aluminum oxide or hafnium oxide is preferably used. Since the insulator 272a is positioned between the insulator 275a and the conductor 260_1 and the insulator 250a, diffusion of impurities such as water or hydrogen from the insulator 275a to the insulator 250a can be inhibited. In addition, entry of impurities such as hydrogen or water into the oxide 230 from an end portion of the insulator 250a or the like can be inhibited. Moreover, outward diffusion of oxygen in the insulator 250a through the insulator 275a can be prevented; thus, entry of oxygen into the conductor 260_1 can be inhibited.

The insulator 275a is formed by forming the insulator to be the insulator 275a and then performing anisotropic etching. By the etching, the insulator 275a is formed to be in contact with the insulator 272a.

The insulator 274a is formed by forming the insulator to be the insulator 274a and then performing anisotropic etching. By the etching, the insulator 274a is formed so that a portion in contact with the top surface of the oxide 230 and the side surface of the insulator 275a remains.

Furthermore, the insulator 280 is preferably provided to cover the transistor 200a and the transistor 200b in the semiconductor device. The concentration of impurities such as water or hydrogen in the insulator 280 is preferably lowered.

Openings in the insulator 280 are formed such that inner walls of the openings in the insulator 280 are in contact with side surfaces of the insulator 274a and the insulator 274b. To form such openings, opening conditions are preferably set such that the etching rates of the insulator 274a and the insulator 274b are much lower than the etching rate of the insulator 280 at the time of forming the openings in the insulator 280. When the etching rates of the insulator 274a and the insulator 274b are 1, the etching rate of the insulator 280 is preferably 5 or more, further preferably 10 or more. Formation of the openings in this manner allows the openings to be formed in a self-aligned manner and enables a wide design margin for alignment of the openings and the gate electrodes.

After the openings are formed, the region 236 may be formed in the oxide 230 by treatment using an ion implantation method, an ion doping method by which an ionized source gas is added without mass separation, a plasma immersion ion implantation method, or the like. For the formation of the region 236, a method similar to that for the formation of the region 231 and the junction region 232 can be used.

Here, the conductor 240a, the conductor 240b, and the conductor 240c are formed in contact with the inner walls of the openings in the insulator 280. The region 236 of the oxide 230 is positioned in at least part of bottom portions of the openings, and thus the conductor 240a, the conductor 240b, and the conductor 240c are each in contact with the region 236.

The conductor 240a and the conductor 240b are preferably provide to face each other with the conductor 260_1 positioned therebetween; such a structure can reduce a gap between the conductor 240a and the conductor 240b. Furthermore, the conductor 240b and the conductor 240c are preferably provide to face each other with the conductor 260_2 positioned therebetween; such a structure can reduce a gap between the conductor 240b and the conductor 240c. Such a structure enables a reduction in a gap between the transistor 200a and the transistor 200b adjacent to each other; thus, the transistors can be arranged with high density, leading to size reduction of the semiconductor device.

As illustrated in FIG. 15(B), parasitic capacitance is formed between the conductor 260_1 and the conductor 240a and parasitic capacitance is formed between the conductor 260_1 and the conductor 240b in the transistor 200a. Similarly, parasitic capacitance is formed between the conductor 260_2 and the conductor 240b and parasitic capacitance is formed between the conductor 2602 and the conductor 240c in the transistor 200b.

When the insulator 275a is provided in the transistor 200a and the insulator 275b is provided in the transistor 200b, the parasitic capacitance can be reduced. A material having a low dielectric constant is preferably used for the insulator 275a and the insulator 275b. For example, the dielectric constant of the insulator 275a and the insulator 275b are preferably lower than 4, further preferably lower than 3. For the insulator 275a and the insulator 275b, for example, silicon oxide or silicon oxynitride can be used. A reduction in the parasitic capacitance leads to high-speed operation of the transistor 200a and the transistor 200b.

The conductor 240a, the conductor 240b, and the conductor 240c can be formed using a material similar to that for the conductor 205_1. The conductor 240a, the conductor 240b, and the conductor 240c may be formed after aluminum oxide is formed on side wall portions of the openings. By forming aluminum oxide on the side wall portions of the openings, the passage of oxygen from the outside can be inhibited and oxidation of the conductor 240a, the conductor 240b, and the conductor 240c can be prevented. Furthermore, impurities such as water or hydrogen can be prevented from being diffused from the conductor 240a, the conductor 240b, and the conductor 240c to the outside. The aluminum oxide can be formed by depositing aluminum oxide in the openings by an ALD method or the like and then performing anisotropic etching.

It is preferred that the conductor 253a be positioned in contact with a top surface of the conductor 240a, the conductor 253b be positioned in contact with a top surface of the conductor 240b, and the conductor 253c be positioned in contact with a top surface of the conductor 240c. The conductor 253a, the conductor 253b, and the conductor 253c are preferably formed using a conductive material whose main component is tungsten, copper, or aluminum. Although not illustrated, the conductor 253a, the conductor 253b, and the conductor 253c may have stacked-layer structures and may be, for example, stacked layers of titanium, titanium nitride, and the above-described conductive material.

Note that in this embodiment, the insulator 220, the insulator 222, and the insulator 224 are referred to as a first insulator in some cases. Furthermore, the insulator 250a and the insulator 252a are referred to as a second insulator, and the insulator 250b and the insulator 252b are referred to as a sixth insulator, in some cases. The insulator 270a and the insulator 271a are referred to as a third insulator and the insulator 270b and the insulator 271b are referred to as a seventh insulator, in some cases. The insulator 272a and the insulator 272b are referred to as a fourth insulator and an eighth insulator, respectively, in some cases. The insulator 275a and the insulator 274a are referred to as a fifth insulator and the insulator 275b and the insulator 274b are referred to as a ninth insulator, in some cases.

In this embodiment, the oxide 230 is simply referred to as an oxide in some cases. Furthermore, the conductor 260_1 and the conductor 260_2 are referred to as a first conductor and a second conductor, respectively, in some cases. Furthermore, the conductor 240a, the conductor 240c, and the conductor 240b are referred to as a first wiring, a second wiring, and a third wiring, respectively, in some cases.

### <Structure Example 2 of Semiconductor Device>

An example of a semiconductor device of one embodiment of the present invention including the transistor 200a and the transistor 200b is described below.

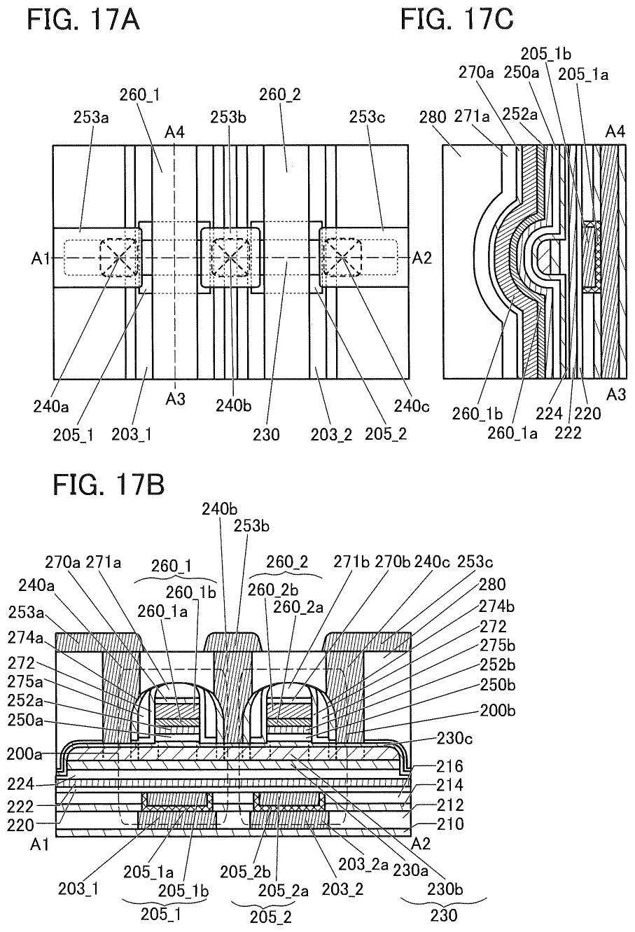

FIG. 17(A) is a top view of the semiconductor device including the transistor 200a and the transistor 200b. FIG. 17(B) is a cross-sectional view of a portion indicated by a dashed-dotted line A1-A2 in FIG. 17(A) and also is a cross-sectional view of the transistor 200a and the transistor 200b in the channel length direction. FIG. 17(C) is a cross-sectional view of a portion indicated by a dashed-dotted line A3-A4 in FIG. 17(A) and also is a cross-sectional view of the transistor 200a in the channel width direction. For simplification of the drawing, some components are not illustrated in the top view in FIG. 17(A).

The transistor 200a and the transistor 200b illustrated in FIG. 17 both have a structure including an oxide 230c and the insulating film 272. The transistor 200a illustrated in FIG. 15 has a structure including the oxide 230_1c and the insulator 272a and the transistor 200b has a structure including the oxide 230_2c and the insulator 272b. The transistor 200a and the transistor 200b illustrated in FIG. 15 have a structure in which the insulating film 272 is formed separated into the insulator 272a and the insulator 272b and the oxide 230c is formed separated into the oxide 230_1c and the oxide 230_2c; meanwhile, the transistor 200a and the transistor 200b illustrated in FIG. 17 have a structure in which neither the oxide 230c nor the insulating film 272 is separated. With such a structure, the oxide 230c and the insulating film 272 cover the oxide 230; thus, impurities such as water or hydrogen from the outside can be prevented from entering the oxide 230 excessively. The description for the semiconductor device illustrated in FIG. 15 is referred to for the other structures and effects.

### <Structure Example 3 of Semiconductor Device>

An example of a semiconductor device of one embodiment of the present invention including a transistor 202a and a transistor 202b is described below.

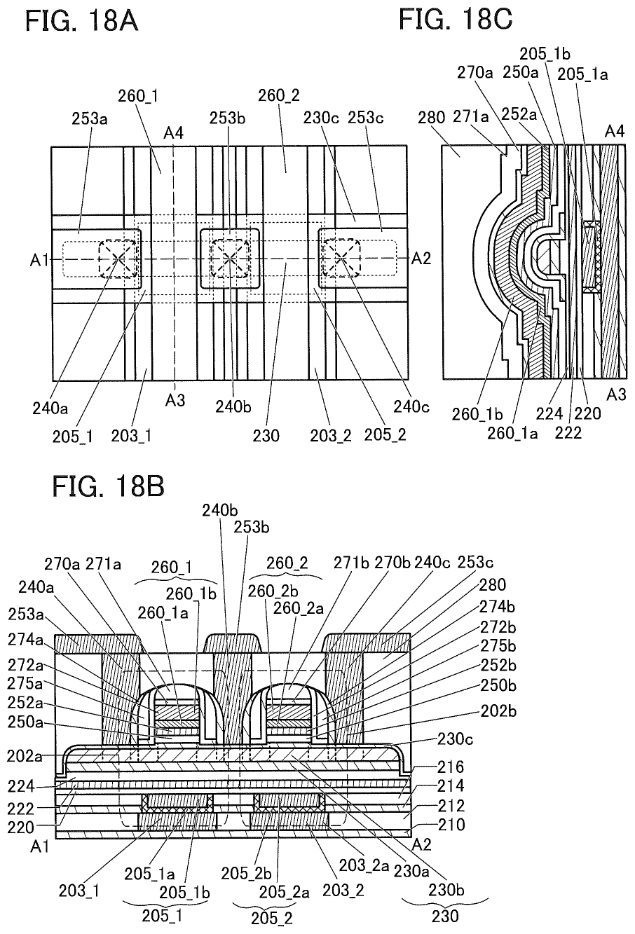

FIG. 18(A) is a top view of the semiconductor device including the transistor 202a and the transistor 202b. FIG. 18(B) is a cross-sectional view of a portion indicated by a dashed-dotted line A1-A2 in FIG. 18(A) and also is a cross-sectional view of the transistor 202a and the transistor 202b in a channel length direction. FIG. 18(C) is a cross-sectional view of a portion indicated by a dashed-dotted line A3-A4 in FIG. 18(A) and also is a cross-sectional view of the transistor 202a in a channel width direction. For simplification of the drawing, some components are not illustrated in the top view in FIG. 18(A).

The transistor 202a and the transistor 202b illustrated in FIG. 18 are different from the transistor 200b and the transistor 200b illustrated in FIG. 15 in the shape of the oxide 230c. The transistor 200a and the transistor 200b illustrated in FIG. 15 has a structure in which the oxide 230c is formed separated into the oxide 230_1c and the oxide 230_2c; as for the transistor 202a and the transistor 202b illustrated in FIG. 18, a formation process of the oxide 230c is different. In other words, the oxide 230c is formed after the formation of the oxide 230 and before the formation of an insulator to be the insulator 250a and the insulator 250b. Such a formation manner has an advantage in that design margin can be wide because the shape and arrangement of the oxide 230c can be freely set. The structure example of the transistor 202a and the transistor 202b illustrated in FIG. 18 shows the structure in which the oxide 230c covers the oxide 230; thus, impurities such as water or hydrogen from the outside can be prevented from entering the oxide 230 excessively. The shape and arrangement of the oxide 230c are not limited to the structure in the transistor 202a and the transistor 202b and can be freely set. The description for the semiconductor device illustrated in FIG. 15 is referred to for the other structures and effects.

Next, component materials of the semiconductor devices illustrated in FIG. 15 to FIG. 18 are described.

The description for the component materials in Embodiment 1 can be referred to for the component materials of the semiconductor devices illustrated in FIG. 15 to FIG. 18.

The conductor 203_1 and the conductor 203_2 can be formed using a material similar to that for the conductor 205_1, the conductor 205_2, the conductor 260_1, the conductor 260_2, the conductor 240, and the conductor 253.

### <Method 1 for Manufacturing Semiconductor Device>

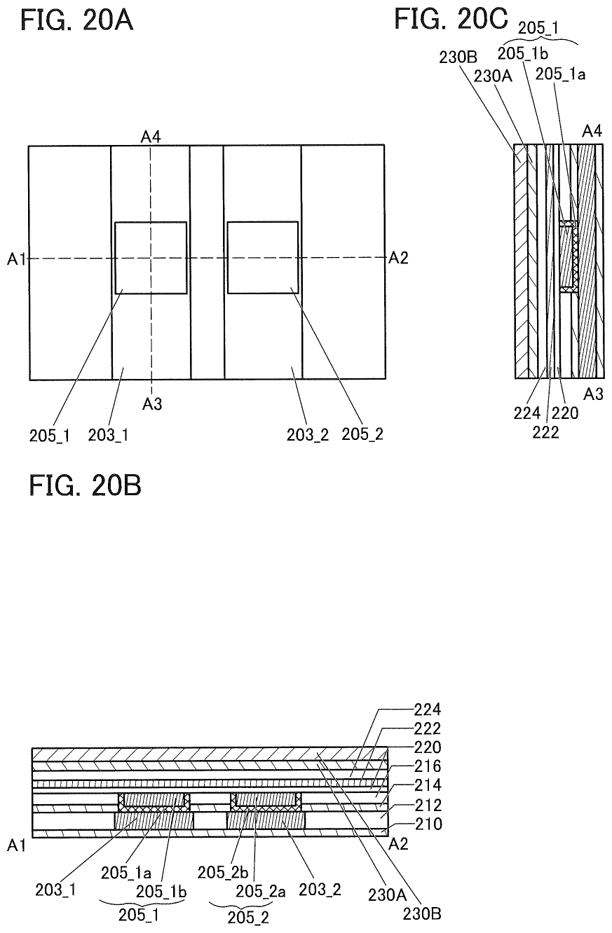

Next, a method for manufacturing the semiconductor device illustrated in FIG. 15 which includes the transistors 200a and 200b of one embodiment of the present invention is described with reference to FIG. 20 to FIG. 31. FIG. 20(A) to FIG. 31(A) are top views. FIG. 20(B) to FIG. 31(B) are cross-sectional views of portions indicated by dashed-dotted lines A1-A2 in FIG. 20(A) to FIG. 31(A). FIG. 20(C) to FIG. 31(C) are cross-sectional views of portions indicated by dashed-dotted lines A3-A4 in FIG. 20(A) to FIG. 31(A).

First, a substrate (not illustrated) is prepared, and the insulator 210 is formed over the substrate. The insulator 210 can be formed by a sputtering method, a chemical vapor deposition (CVD) method, a molecular beam epitaxy (MBE) method, a pulsed laser deposition (PLD) method, an ALD method, or the like.

Note that CVD methods can be classified into a plasma CVD (PECVD: plasma enhanced CVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a film formation method that does not use plasma and thus can cause less plasma damage to an object. For example, a wiring, an electrode, an element (e.g., transistor or capacitor), or the like included in a semiconductor device might be charged up by receiving electric charges from plasma. In that case, accumulated electric charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during film formation, so that a film with few defects can be obtained.

An ALD method is also a film formation method which can cause less plasma damage to an object. An ALD method also does not cause plasma damage during film formation, so that a film with few defects can be obtained.

Unlike in a film formation method in which particles ejected from a target or the like are deposited, a CVD method and an ALD method are film formation methods in which a film is formed by reaction at a surface of an object. Thus, a CVD method and an ALD method are film formation methods that are less likely to be influenced by the shape of an object and thus have favorable step coverage. In particular, an ALD method has excellent step coverage and excellent thickness uniformity, and thus is suitable for the case of covering a surface of an opening portion with a high aspect ratio, for example. Note that an ALD method has a relatively low film formation rate and thus is preferably used in combination with another film formation method with a high film formation rate such as a CVD method, in some cases.

A CVD method and an ALD method enable adjustment of composition of a film to be obtained with a flow rate ratio of the source gases. For example, a CVD method and an ALD method enable formation of a film with any composition depending on a flow rate ratio of source gases. Moreover, a CVD method and an ALD method enable formation of a film whose composition is continuously changed by changing a flow rate ratio of source gases during the film formation, for example. In the case of forming a film while changing a flow rate ratio of source gases, as compared with the case of forming a film with the use of a plurality of film formation chambers, time taken for the film formation can be shortened by the time necessary for transfer and pressure adjustment. Thus, productivity of semiconductor devices can be improved in some cases.

In this embodiment, aluminum oxide is deposited as the insulator 210 by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Next, a conductive film to be the conductor 203_1 and the conductor 203_2 is formed over the insulator 210. The conductive film to be the conductor 203_1 and the conductor 203_2 can be formed by a sputtering method, a CVD method, an MBE method, a PLD method, an ALD method, or the like. The conductive film to be the conductor 203_1 and the conductor 203_2 can be a multilayer film. In this embodiment, tungsten is deposited as the conductive film to be the conductor 203_1 and the conductor 203_2.

Next, the conductive film to be the conductor 203_1 and the conductor 203_2 is processed by a lithography method to form the conductor 203_1 and the conductor 203_2.

Note that in the lithography method, first, a resist is exposed to light through a mask. Next, a region exposed to light is removed or left using a developing solution, so that a resist mask is formed. Then, etching treatment through the resist mask is performed, so that a conductor, a semiconductor, an insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a space between a substrate and a projection lens is filled with liquid (e.g., water) to perform light exposure. Furthermore, an electron beam or an ion beam may be used instead of the above-described light. Note that a mask is not necessary in the case of using an electron beam or an ion beam. Note that for removal of the resist mask, dry etching treatment such as ashing can be performed, wet etching treatment can be performed, wet etching treatment can be performed after dry etching treatment, or dry etching treatment can be performed after wet etching treatment.

A hard mask formed of an insulator or a conductor may be used instead of the resist mask. In the case of using a hard mask, an insulating film or a conductive film that is the material of the hard mask is formed over the conductive film to be the conductor 203_1 and the conductor 203_2, a resist mask is formed thereover, and then the material of the hard mask is etched, so that a hard mask with a desired shape can be formed. The etching of the conductive film to be the conductor 203_1 and the conductor 203_2 may be performed after the resist mask is removed or may be performed while the resist mask remains. In the latter case, the resist mask may disappear during the etching. The hard mask may be removed by etching after the etching of the conductive film to be the conductor 203_1 and the conductor 203_2. Meanwhile, in the case where the material of the hard mask does not affect the following process or can be utilized in the following process, the hard mask does not need to be removed.

As a dry etching apparatus, a capacitively coupled plasma (CCP) etching apparatus including parallel plate electrodes can be used. The capacitively coupled plasma etching apparatus including the parallel plate electrodes may have a structure in which high-frequency power is applied to one of the parallel plate electrodes. Alternatively, a structure may be employed in which different high-frequency powers are applied to one of the parallel plate electrodes. Alternatively, a structure may be employed in which high-frequency powers with the same frequency are applied to the parallel plate electrodes. Alternatively, a structure may be employed in which high-frequency powers with different frequencies are applied to the parallel plate t electrodes. Alternatively, a dry etching apparatus including a high-density plasma source can be used. As the dry etching apparatus including a high-density plasma source, an inductively coupled plasma (ICP) etching apparatus can be used, for example.

Next, an insulating film to be the insulator 212 is formed over the insulator 210, the conductor 203_1, and the conductor 203_2. The insulator to be the insulator 212 can be formed by a sputtering method, a CVD method, an MBE method, a PLD method, an ALD method, or the like. In this embodiment, silicon oxide is deposited as the insulator to be the insulator 212 by a CVD method.

Here, the thickness of the insulating film to be the insulator 212 is preferably larger than or equal to the thickness of the conductor 203_1 and the thickness of the conductor 203_2. For example, when the thickness of the conductor 203_1 and the thickness of the conductor 203_2 are 1, the thickness of the insulating film to be the insulator 212 is greater than or equal to 1 and less than or equal to 3. In this embodiment, the thickness of the conductor 203_1 and the thickness of the conductor 203_2 are 150 nm and the thickness of the insulating film to be the insulator 212 is 350 nm.

Next, CMP (chemical Mechanical Polishing) treatment is performed on the insulating film to be the insulator 212, so that part of the insulating film to be the insulator 212 is removed and a surface of the conductor 203_1 and a surface of the conductor 203_2 are exposed. Accordingly, the conductor 203_1, the conductor 203_2, and the insulator 212 whose top surfaces are flat can be formed (see FIG. 20).

Here, a method for forming the conductor 203_1 and the conductor 203_2 that is different from the above is described below.

The insulator 212 is formed over the insulator 210. The insulator 212 can be formed by a sputtering method, a CVD method, an MBE method, a PLD method, an ALD method, or the like.

Next, openings reaching the insulator 210 are formed in the insulator 212. Examples of the openings include grooves and slits. A region where an opening is formed may be referred to as an opening portion. The openings may be formed by wet etching; however, dry etching is preferably used for microfabrication. It is preferred to select an insulator that functions as an etching stopper film in forming a groove by etching the insulator 212 as the insulator 210. For example, in the case where a silicon oxide film is used as the insulator 212 in which the groove is to be formed, a silicon nitride film, an aluminum oxide film, or a hafnium oxide film is preferably used for the insulator 210.

After the formation of the openings, the conductive film to be the conductor 203_1 and the conductor 203_2 is formed. The conductive film desirably includes a conductor having a function of inhibiting the passage of oxygen. For example, tantalum nitride, tungsten nitride, or titanium nitride can be used. Alternatively, a stacked-layer film of the above conductor and tantalum, tungsten, titanium, molybdenum, aluminum, copper, or a molybdenum-tungsten alloy can be used. The conductive film to be the conductor 203_1 and the conductor 2032 can be formed by a sputtering method, a CVD method, an MBE method, a PLD method, an ALD method, or the like.

In this embodiment, a multilayer structure is used for the conductive film to be the conductor 203_1 and the conductor 203_2. First, tantalum nitride or stacked films of tantalum nitride and titanium nitride thereover are formed by a sputtering method. Even when a metal that is easily diffused, such as copper, is used for a conductive film of an upper layer of the conductive film to be the conductor 203_1 and the conductor 203_2, which is described later, the use of such metal nitride for a conductive film of a lower layer of the conductive film to be the conductor 203_1 and the conductor 203_2 can prevent diffusion of the metal to the outside from the conductor 203_1 and the conductor 203_2.

Next, the conductive film of the upper layer of the conductive film to be the conductor 203_1 and the conductor 203_2 is formed. The conductive film can be formed by a plating method, a sputtering method, a CVD method, an MBE method, a PLD method, an ALD method, or the like. In this embodiment, for the conductive film of the upper layer of the conductive film to be the conductor 203_1 and the conductor 203_2, a film of a low-resistant conductive material such as copper is formed.

Next, by CMP treatment, the conductive film of the upper layer of the conductive film to be the conductor 203_1 and the conductor 203_2 and the conductive film of the lower layer of the conductive film to be the conductor 203_1 and the conductor 203_2 are partly removed to expose the insulator 212. As a result, the conductive film to be the conductor 203_1 and the conductor 203_2 remains only in the opening portions. Thus, the conductor 203_1 and the conductor 203_2 whose top surfaces are flat can be formed. Note that the insulator 212 is partly removed by the CMP treatment in some cases. The above is the different formation method of the conductor 203_1 and the conductor 203_2.

The insulator 214 is formed over the conductor 203_1 and the conductor 2032. The insulator 214 can be formed by a sputtering method, a CVD method, an MBE method, a PLD method, an ALD method, or the like. In this embodiment, silicon nitride is deposited as the insulator 214 by a CVD method. As described here, an insulator through which copper is less likely to pass, such as silicon nitride, is used as the insulator 214; accordingly, even when a metal that is easy to diffuse, such as copper, is used for the conductor 203_1 and the conductor 203_2, the metal can be prevented from diffusing into a layer above the insulator 214.

Next, the insulator 216 is formed over the insulator 214. The insulator 216 can be formed by a sputtering method, a CVD method, an MBE method, a PLD method, an ALD method, or the like. In this embodiment, silicon oxide is deposited as the insulator 216 by a CVD method.

Next, depression portions are formed in the insulator 214 and the insulator 216. Examples of the depression portions include holes and opening portions. The depression portions may be formed by wet etching; however, dry etching is preferably used for micro fabrication.

After the formation of the depression portions, a conductive film to be the conductor 205_1a and a conductor 205_2a is formed. The conductive film to be the conductor 205_1a and the conductor 205_2a desirably includes a conductor having a function of inhibiting the passage of oxygen. For example, tantalum nitride, tungsten nitride, or titanium nitride can be used. Alternatively, a stacked-layer film of the above conductor and tantalum, tungsten, titanium, molybdenum, aluminum, copper, or a molybdenum-tungsten alloy can be used. The conductive film to be the conductor 205_1a and the conductor 205_2a can be formed by a sputtering method, a CVD method, an MBE method, a PLD method, an ALD method, or the like.

In this embodiment, tantalum nitride is deposited as the conductive film to be the conductor 205_1a and the conductor 205_2a by a sputtering method.

Next, a conductive film to be the conductor 205_1b and the conductor 205_213 is formed over the conductive film to be the conductor 205_1a and the conductor 2052a. The conductive film to be the conductor 205_1b and the conductor 205_2b can be formed by a sputtering method, a CVD method, an MBE method, a PLD method, an ALD method, or the like.

In this embodiment, for the conductive film to be the conductor 205_1b and the conductor 205_2b, titanium nitride is deposited by a CVD method and tungsten is deposited over the titanium nitride by a CVD method.

Next, CMP treatment is performed to remove the conductive film to be the conductor 205_1a and the conductor 205_2a and the conductive film to be the conductor 205_1b and the conductor 205_2b that are over the insulator 216. Consequently, the conductive film to be the conductor 205_1a and the conductor 205_2a and the conductive film to be the conductor 205_1b and the conductor 205_2b are left only in the depression portion, whereby the conductor 205_1 and the conductor 205_2 with flat top surfaces can be formed (see FIG. 20).

Next, the insulator 220 is formed over the insulator 216, the conductor 205_1, and the conductor 205_2. The insulator 220 can be formed by a sputtering method, a CVD method, an MBE method, a PLD method, an ALD method, or the like.

Next, the insulator 222 is formed over the insulator 220. The insulator 222 can be formed by a sputtering method, a CVD method, an MBE method, a PLD method, an ALD method, or the like.

Next, the insulator 224 is formed over the insulator 222. The insulator 224 can be formed by a sputtering method, a CVD method, an MBE method, a PLD method, an ALD method, or the like.

Next, first heat treatment is preferably performed. The first heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. The first heat treatment is performed in a nitrogen atmosphere, an inert gas atmosphere, or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen. Through the first heat treatment, impurities such as hydrogen and water contained in the insulator 224 can be removed, for example. Alternatively, in the first heat treatment, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be generated, and application of the RF to the substrate side allows the oxygen radicals generated by the high-density plasma to be efficiently introduced into the insulator 224. Alternatively, after plasma treatment containing an inert gas is performed with this apparatus, plasma treatment containing oxygen may be performed to compensate for released oxygen. Note that the first heat treatment is not necessarily performed in some cases.

The heat treatment can be performed after the formation of the insulator 220, after the formation of the insulator 222, and after the formation of the insulator 224. Although the above conditions can be used for the heat treatment, the heat treatment after the formation of the insulator 220 is preferably performed in an atmosphere containing nitrogen.

In this embodiment, as the first heat treatment, treatment is performed at 400° C. in a nitrogen atmosphere for one hour after the formation of the insulator 224.

Next, the oxide film 230A and the oxide film 230B are formed in this order over the insulator 224 (see FIG. 20). Note that it is preferred that the oxide film 230A and the oxide film 230B be successively formed without being exposed to the air. When film formation is performed in such a manner, impurities or moisture from the air can be prevented from being attached to the oxide film 230A, and an interface between the oxide film 230A and the oxide film 230B and the vicinity thereof can be kept clean.

The oxide film 230A and the oxide film 230B can be formed by a sputtering method, a CVD method, an MBE method, a PLD method, an ALD method, or the like.

For example, in the case where the oxide film 230A and the oxide film 230B are formed by a sputtering method, oxygen or a mixed gas of oxygen and a rare gas is used as a sputtering gas. Increasing the proportion of oxygen contained in the sputtering gas can increase the amount of excess oxygen in the oxide film to be formed. In addition, in the case where the oxide film 230A and the oxide film 230B are formed by a sputtering method, the above-described In-M-Zn oxide target can be used.

In particular, at the time of the formation of the oxide film 230A, part of oxygen contained in the sputtering gas is supplied to the insulator 224 in some cases.

Note that the proportion of oxygen contained in the sputtering gas at the time of the formation of the oxide film 230A is higher than or equal to 70%, preferably higher than or equal to 80%, further preferably 100%.

When the proportion of oxygen contained in the sputtering gas at the time of the formation of the oxide film 230B is higher than or equal to 1% and lower than or equal to 30% and preferably higher than or equal to 5% and lower than or equal to 20%, an oxygen-deficient oxide semiconductor is formed. In a transistor using an oxygen-deficient oxide semiconductor, relatively high field-effect mobility can be obtained.

In the case where an oxygen-deficient oxide semiconductor is used for the oxide film 230B, an oxide film containing excess oxygen is preferably used as the oxide film 230A. Oxygen doping treatment may be performed after the formation of the oxide film 230A.

In this embodiment, the oxide film 230A is formed by a sputtering method using a target with In:Ga:Zn=1:3:4 [atomic ratio], and the oxide film 230B is formed by a sputtering method using a target with In:Ga:Zn=4:2:4.1 [atomic ratio].

The, second heat treatment may be performed. For the second heat treatment, the conditions for the first heat treatment can be used. Through the second heat treatment, impurities such as hydrogen and water contained in the oxide film 230A and the oxide film 230B can be removed, for example. In this embodiment, treatment is performed at 400° C. in a nitrogen atmosphere for one hour, and then another treatment is successively performed at 400° C. in an oxygen atmosphere for one hour.

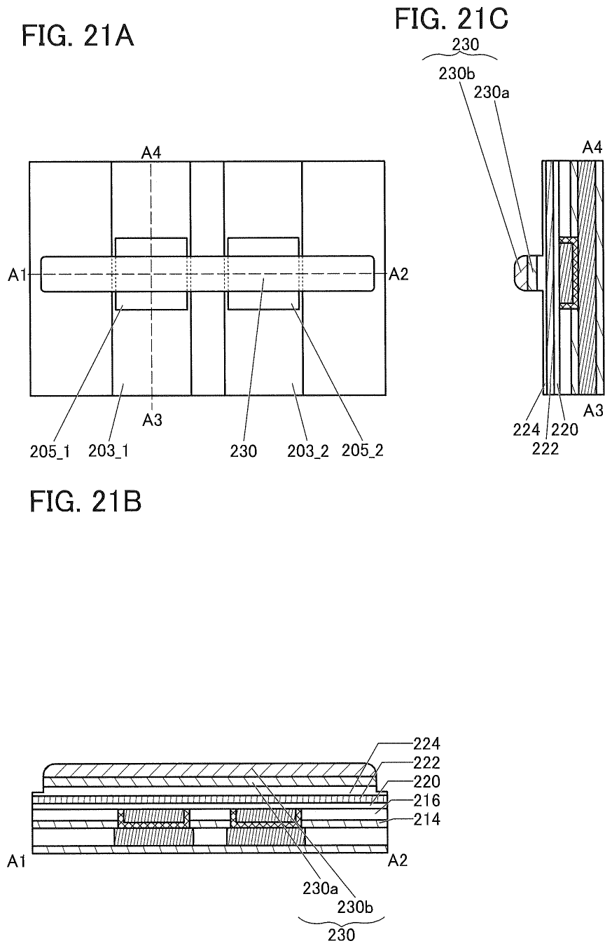

Next, the oxide film 230A and the oxide film 230B are processed into island shapes to form the oxide 230a and the oxide 230b (see FIG. 21).

Here, the oxide 230 is formed to at least partly overlap with the conductors 205. A side surface of the oxide 230 is preferably substantially perpendicular to a top surface of the insulator 222. When the side surface of the oxide 230 is substantially perpendicular to the top surface of the insulator 222, a plurality of transistors 200 can be provided in a small area with high density. Note that a structure in which an angle formed between the side surface of the oxide 230 and the top surface of the insulator 222 is an acute angle may be employed. In that case, it is preferred that the angle formed between the side surface of the oxide 230 and the top surface of the insulator 222 be as large as possible.

There is a curved surface between the side surface of the oxide 230 and the top surface of the oxide 230. That is, an end portion of the side surface and an end portion of the top surface are preferably curved (such a shape is also referred to as a rounded shape). It is preferred that the radius of curvature of the curved surface at an end portion of the oxide 230b be greater than or equal to 3 nm and less than or equal to 10 nm, preferably greater than or equal to 5 nm and less than or equal to 6 nm.

Note that when the end portions are not angular, the coverage of films formed later in the film formation process can be improved.

Note that the oxide films may be processed by a lithography method. The processing can be performed by a dry etching method or a wet etching method. A dry etching method is suitable for microfabrication.

A hard mask formed of an insulator or a conductor may be used as an etching mask instead of the resist mask. In the case of using a hard mask, an insulating film or a conductive film that is the material of the hard mask is formed over the oxide film 230B, a resist mask is formed thereover, and then the material of the hard mask is etched, so that a hard mask with a desired shape can be formed. The etching of the oxide film 230A and the oxide film 230B may be performed after the resist mask is removed or may be performed while the resist mask remains. In the latter case, the resist mask may disappear during the etching. The hard mask may be removed by etching after the etching of the oxide film 230A and the oxide film 230B. Meanwhile, in the case where the material of the hard mask does not affect the following process or can be utilized in the following process, the hard mask does not need to be removed.

In some cases, treatment such as dry etching performed in the above process causes the attachment or diffusion of impurities due to an etching gas or the like to a surface or an inside of the oxide 230a, the oxide 230b, and the like. Examples of the impurities include fluorine and chlorine.

In order to remove the above impurities and the like, cleaning is performed. Examples of a cleaning method include wet cleaning using a cleaning solution or the like, plasma treatment using plasma, and cleaning by heat treatment; the cleaning methods may be performed in appropriate combination.

As the wet cleaning, cleaning treatment may be performed using an aqueous solution obtained by diluting an oxalic acid, a phosphoric acid, a hydrofluoric acid, or the like with carbonated water or pure water. Alternatively, ultrasonic cleaning using pure water or carbonated water may be performed. In this embodiment, ultrasonic cleaning using pure water or carbonated water is performed.

Next, third heat treatment may be performed. As heat treatment conditions, the conditions for the first heat treatment can be used. Note that the third heat treatment is not necessarily performed in some cases. In this embodiment, the third heat treatment is not performed.

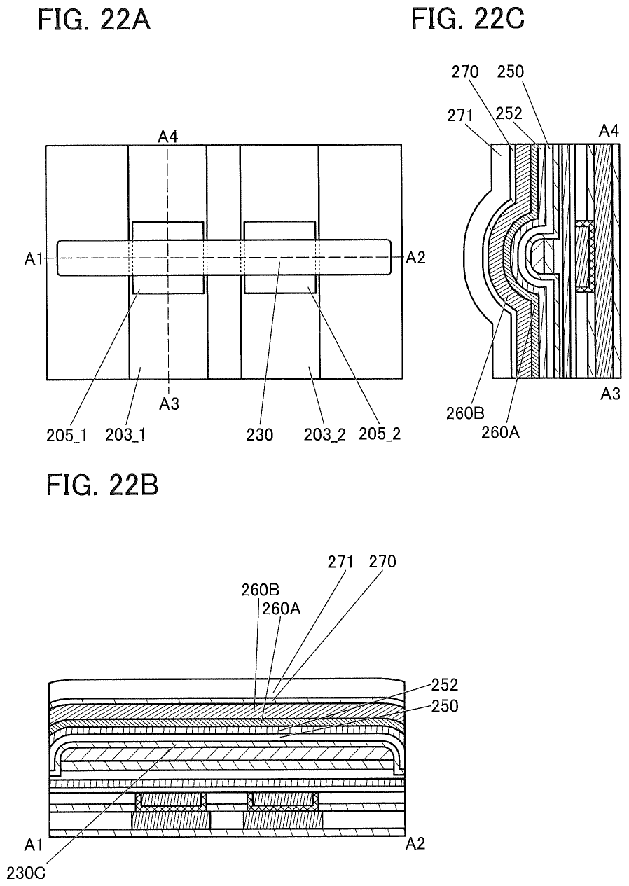

Next, the oxide film 230C, the insulating film 250, the insulating film 252, the conductive film 260A, the conductive film 260B, the insulating film 270, and the insulating film 271 are formed in this order over the insulator 224, the oxide 230a, and the oxide 230b (see FIG. 22).

The insulating film 250 and the insulating film 252 can be formed by a sputtering method, a CVD method, an MBE method, a PLD method, an ALD method, or the like. Here, when the insulating film 252 is formed in an atmosphere containing oxygen by a sputtering method, oxygen can be added to the insulating film 250.

Here, fourth heat treatment can be performed. For the fourth heat treatment, the conditions for the first heat treatment can be used. Through the heat treatment, the moisture concentration and the hydrogen concentration in the insulating film 250 can be reduced. Note that the fourth heat treatment is not necessarily performed in some cases.

The conductive film 260A and the conductive film 260B can be formed by a sputtering method, a CVD method, an MBE method, a PLD method, an ALD method, or the like.

The insulating film 270 and the insulating film 271 can be formed by a sputtering method, a CVD method, an MBE method, a PLD method, an ALD method, or the like; in particular, the insulating film 270 is preferably formed by an ALD method. When the insulating film 270 is formed by an ALD method, the thickness can be approximately 0.5 nm to 10 nm inclusive, preferably approximately 0.5 nm to 3 nm inclusive. Note that the formation of the insulating film 270 can be omitted.

The insulating film 271 can be used as a hard mask in processing the conductive film 260A and the conductive film 260B.

Here, fifth heat treatment can be performed. For the heat treatment, the conditions for the first heat treatment can be used. Note that the fifth heat treatment is not necessarily performed in some cases.

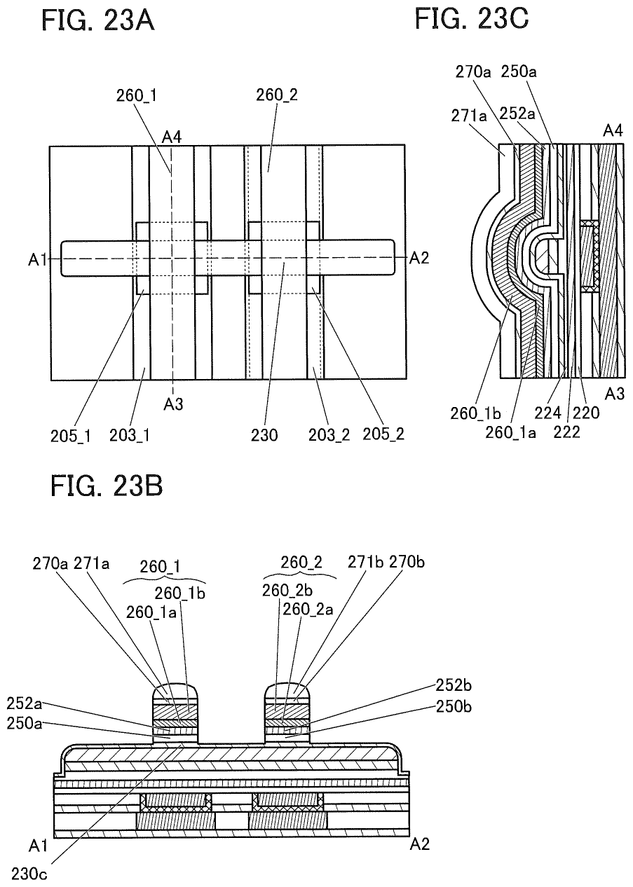

Next, the insulating film 250, the insulating film 252, the conductive film 260A, the conductive film 260B, the insulating film 270, and the insulating film 271 are etched to form the insulator 250a, the insulator 252a, the conductor 260_1a, the conductor 260_1b, the insulator 270a, the insulator 271a, the insulator 250b, the insulator 252b, the conductor 260_2a, the conductor 260_2b, the insulator 270b, and the insulator 271b (see FIG. 23). This processing is performed by a lithography method.

Here, it is preferred that the cross-sectional shapes of the insulator 250a, the insulator 252a, the conductor 260_1a, the conductor 260_1b, and the insulator 270a be tapered as little as possible. Similarly, it is preferred that the cross-sectional shapes of the insulator 250b, the insulator 252b, the conductor 260_2a, the conductor 260_2b, and the insulator 270b be tapered as little as possible. An angle formed between a bottom surface of the oxide 230 and the side surfaces of the insulator 250a, the insulator 252a, the conductor 260_1a, the conductor 260_1b, and the insulator 270a is preferably greater than or equal to 80° and less than or equal to 100°. Similarly, an angle formed between the bottom surface of the oxide 230 and the side surfaces of the insulator 250b, the insulator 252b, the conductor 260_2a, the conductor 260_2b, and the insulator 270b is preferably greater than or equal to 80° and less than or equal to 100°. Accordingly, the insulator 275a and the insulator 274a are likely to remain when the insulator 275a and the insulator 274a are formed in a later step. Similarly, the insulator 275b and the insulator 274b are likely to remain when the insulator 275b and the insulator 274b are formed.

Upper portions of the oxide film 230C in regions not overlapping with the insulator 250a and the insulator 250b are etched by the above etching in some cases. In that case, the thickness of the oxide film 230C in regions overlapping with the insulator 250a and the insulator 250b is larger than the thickness in the regions not overlapping with the insulator 250a and the insulator 250b.

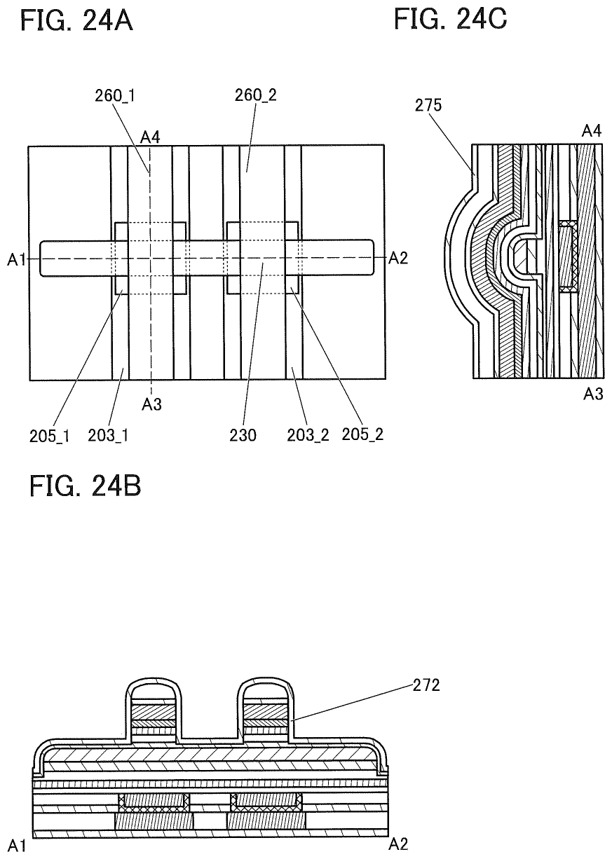

Next, the insulating film 272 is formed to cover the oxide film 230C, the insulator 250a, the insulator 252a, the conductor 260_1, the insulator 270a, the insulator 271a, the insulator 250b, the insulator 252b, the conductor 260_2, the insulator 270b, and the insulator 271b. The insulating film 272 can be formed by a sputtering method, a CVD method, an MBE method, a PLD method, an ALD method, or the like. In this embodiment, aluminum oxide is deposited as the insulating film 272 by an ALD method (see FIG. 24).

The region 231 and the junction region 232 may be formed by an ion implantation method, an ion doping method by which an ionized source gas is added without mass separation, a plasma immersion ion implantation method, or the like. The ions cannot reach regions where the oxide 230 overlaps with the insulator 250a and the insulator 250b, whereas the ions reach regions not overlapping with the insulator 250a and the insulator 250b; thus, the region 231 and the junction region 232 can be formed in a self-aligned manner. When the above method is performed through the insulating film 272, implantation damage to the oxide 230 can be reduced.

In the case where mass separation is performed in an ion doping method, a plasma immersion ion implantation method, or the like, ion species to be added and its concentration can be controlled accurately. Meanwhile, in the case of not performing mass separation, ions can be added at a high concentration in a short time. An ion doping method in which atomic or molecular clusters are generated and ionized may be employed. Note that “dopant” can be replaced with “ion,” “donor,” “acceptor,” “impurity,” “element,” or the like.

As the dopant, an element that forms an oxygen vacancy, an element that is bonded to an oxygen vacancy, or the like is used. Typical examples of such an element include hydrogen, boron, carbon, nitrogen, fluorine, phosphorus, sulfur, chlorine, titanium, and a rare gas element. Typical examples of the rare gas element are helium, neon, argon, krypton, and xenon.

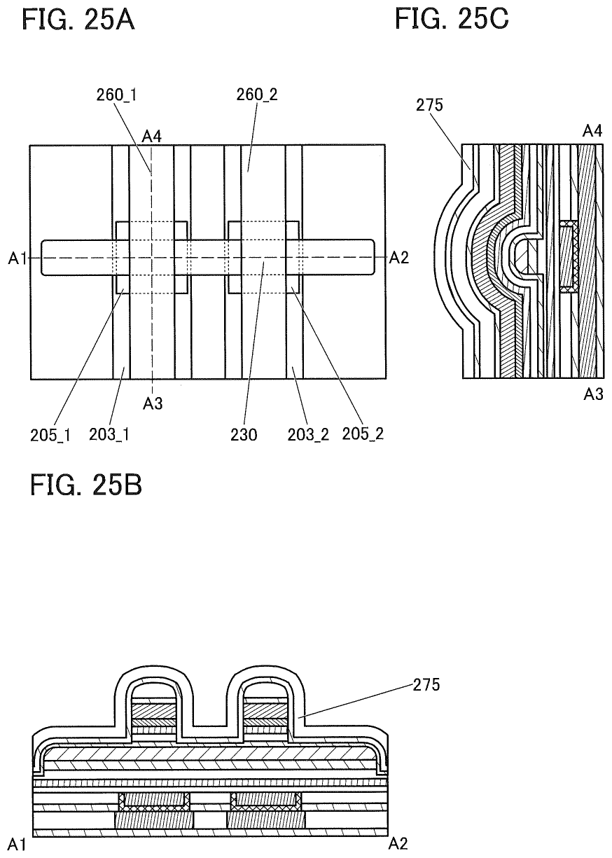

Next, the insulating film 275 is formed. The insulating film 275 can be formed by a sputtering method, a CVD method, an MBE method, a PLD method, an ALD method, or the like. In this embodiment, silicon oxide is deposited as the insulating film 275 by a CVD method (see FIG. 25).

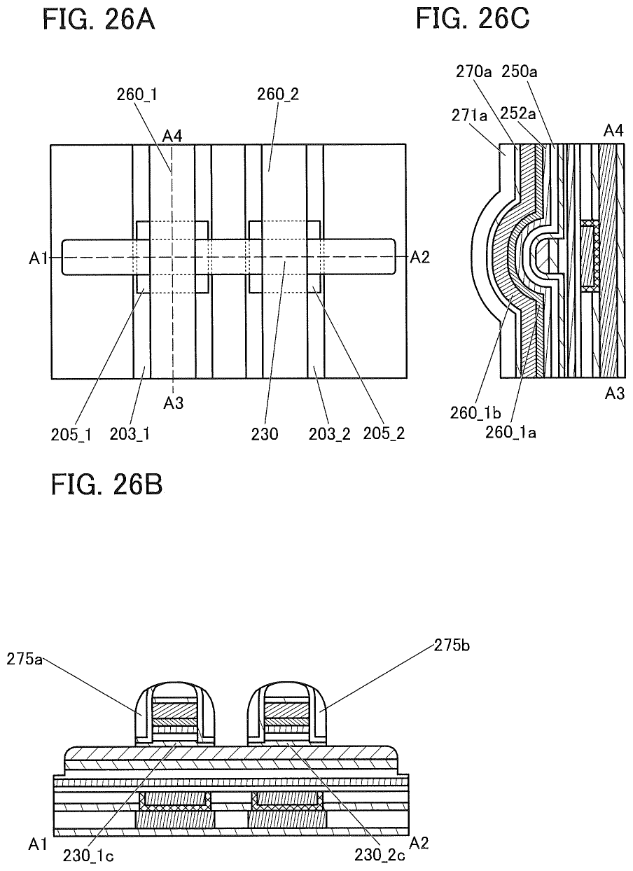

Next, the insulating film 275 is subjected to anisotropic etching treatment, whereby the oxide film 230C, the insulating film 272, and the insulating film 275 are processed to form the oxide 230_1c, the insulator 272a, the insulator 275a, the oxide 230_2c, the insulator 272b, and the insulator 275b. The insulator 275a is formed to be in contact with the insulator 272a, and the insulator 275b is formed to be in contact with the insulator 272b. Dry etching treatment is preferably performed as the anisotropic etching treatment. Consequently, the oxide film 230C, the insulating film 272, and the insulating film 275 formed on a plane substantially parallel to a substrate surface are removed and the oxide 230_1c, the oxide 230_2c, the insulator 275a, and the insulator 275b can be formed in a self-aligned manner (see FIG. 26).

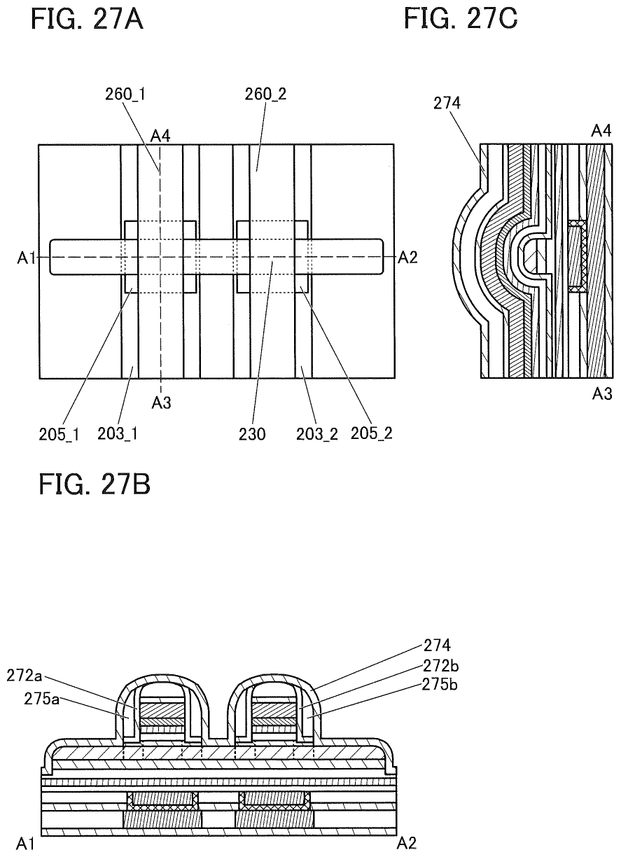

Next, the insulating film 274 is formed. The formation of the insulating film 274 is preferably performed in an atmosphere containing at least one of nitrogen and hydrogen. When the formation is performed in such an atmosphere, oxygen vacancies can be formed mainly in the regions of the oxide 230b not overlapping with the insulator 250a and the insulator 250b and the oxygen vacancies and impurity elements such as nitrogen or hydrogen can be bonded to each other, leading to an increase in carrier density. In this manner, the region 231 and the junction region 232 with reduced resistance can be formed. In particular, oxygen vacancies can be formed in the region 231 by, in addition to the above ion implantation, the formation of the insulating film 274; thus, the carrier density can be increased. For the insulating film 274, for example, silicon nitride or silicon nitride oxide formed by a CVD method can be used. In this embodiment, silicon nitride oxide is used for the insulating film 274. Here, the insulating film 274 and the oxide 230b are not in contact with each other in regions of the oxide 230b that overlap with the insulator 275a and the insulator 275b; thus, excessive bonds between oxygen vacancies in the oxide 230b that are generated by the formation of the insulating film 274 and impurity elements such as nitrogen or hydrogen can be inhibited (see FIG. 27).

As described above, in the method for manufacturing a semiconductor device described in this embodiment, a source region and a drain region can be formed in a self-aligned manner owing to the formation of the insulating film 274, even in a minute transistor whose channel length is approximately 10 nm to 30 nm. Thus, miniaturized or highly integrated semiconductor devices can be manufactured with high yield.

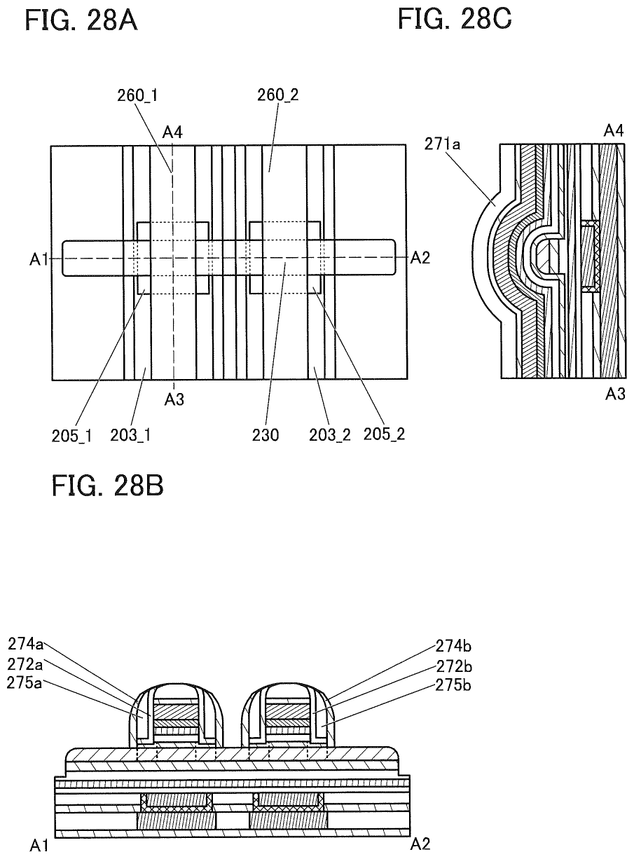

Next, anisotropic etching treatment is performed on the insulating film 274 to form the insulator 274a and the insulator 274b. Dry etching treatment is preferably performed as the anisotropic etching treatment. Consequently, the insulating film 274 formed on a plane substantially parallel to a substrate surface is removed and each of the insulator 274a and the insulator 274b can be formed in a self-aligned manner (see FIG. 28).

Next, the insulator 280 is formed. The insulator 280 can be formed by a sputtering method, a CVD method, an MBE method, a PLD method, an ALD method, or the like.

Alternatively, a spin coating method, a dipping method, a droplet discharging method (e.g., an ink-jet method), a printing method (e.g., screen printing or offset printing), a doctor knife method, a roll coater method, a curtain coater method, or the like can be used. In this embodiment, silicon oxynitride is used for the insulator 280.

The insulator 280 is preferably formed to have a flat top surface. For example, the top surface of the insulator 280 may have flatness immediately after the formation. Alternatively, for example, the insulator 280 may have flatness by removing an insulator and the like from the top surface after the formation so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not need to have flatness.

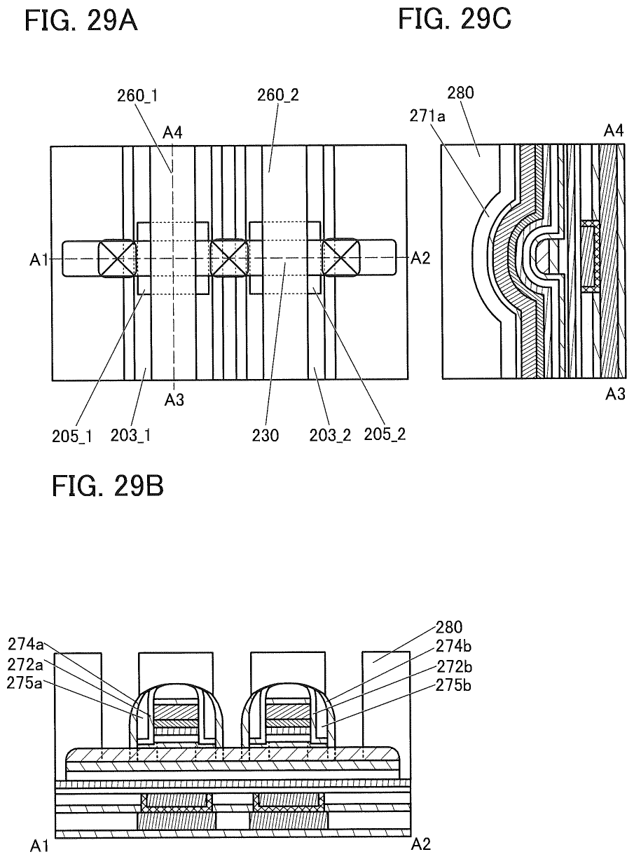

Next, openings reaching the oxide 230 are formed in the insulator 280 (see FIG. 29). A lithography method is used for the formation of the openings. Here, the openings are formed such that the conductor 240a, the conductor 240b, and the conductor 240c are provided in contact with the side surface of the insulator 274a, the side surfaces of the insulator 274a and the insulator 274b, and the side surface of the insulator 274b, respectively. The opening conditions are preferably conditions where the insulator 274a and the insulator 274b are hardly etched, i.e., conditions where the etching rate of the insulator 280 is higher than the etching rates of the insulator 274a and the insulator 274b. When the etching rates of the insulator 274a and the insulator 274b are 1, the etching rate of the insulator 280 is preferably 5 or more, further preferably 10 or more. With such opening conditions, the opening portions can be positioned on the oxide 230 in a self-aligned manner; thus, a miniaturized transistor can be manufactured. In addition, tolerance of misalignment of each opening and the conductor 260_1 and the conductor 260_2 in a lithography process is high; thus, the yield should be improved.

Here, the region 236 may be formed in the opening portions by an ion implantation method, an ion doping method by which an ionized source gas is added without mass separation, a plasma immersion ion implantation method, or the like. The ions cannot reach regions except the opening portions because of the insulator 280. In other words, the region 236 can be formed in a self-aligned manner. This ion implantation can increase the carrier density of the region 236, and thus the contact resistance of the conductor 240a, the conductor 240b, and the conductor 240c with the region 236 can be reduced.

In the case where mass separation is performed in an ion doping method, a plasma immersion ion implantation method, or the like, ion species to be added and its concentration can be controlled accurately. Meanwhile, in the case of not performing mass separation, ions can be added at a high concentration in a short time. An ion doping method in which atomic or molecular clusters are generated and ionized may be employed. Note that “dopant” can be replaced with “ion,” “donor,” “acceptor,” “impurity,” “element,” or the like.

As the dopant, an element that forms an oxygen vacancy, an element that is bonded to an oxygen vacancy, or the like is used. Typical examples of such an element include hydrogen, boron, carbon, nitrogen, fluorine, phosphorus, sulfur, chlorine, titanium, and a rare gas element. Typical examples of the rare gas element are helium, neon, argon, krypton, and xenon.

Next, a conductive film to be the conductor 240a, the conductor 240b, and the conductor 240c is formed. The conductive film to be the conductor 240a, the conductor 240b, and the conductor 240c desirably has a stacked-layer structure which includes a conductor having a function of inhibiting the passage of impurities such as water or hydrogen. For example, stacked layers of tantalum nitride, titanium nitride, or the like and tungsten, molybdenum, copper, or the like can be employed. The conductive film to be the conductor 240a, the conductor 240b, and the conductor 240c can be formed by a sputtering method, a CVD method, an MBE method, a PLD method, an ALD method, or the like.

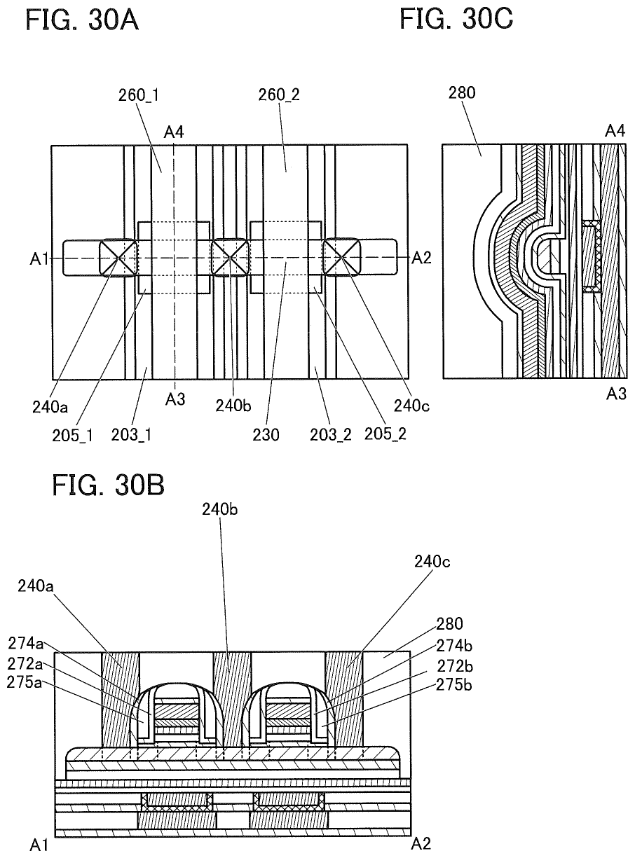

Next, CMP treatment is performed to remove the conductive film to be the conductor 240a, the conductor 240b, and the conductor 240c over the insulator 280. As a result, the conductive film remains only in the above-described openings, whereby the conductor 240a, the conductor 240b, and the conductor 240c having flat top surfaces can be formed (see FIG. 30).

The conductor 240a, the conductor 240b, and the conductor 240c may be formed after aluminum oxide is formed on side wall portions of the openings. By forming aluminum oxide on the side wall portions of the openings, the passage of oxygen from the outside can be inhibited and oxidation of the conductor 240a, the conductor 240b, and the conductor 240c can be prevented. Furthermore, impurities such as water or hydrogen can be prevented from being diffused from the conductor 240a, the conductor 240b, and the conductor 240c to the outside. The aluminum oxide can be formed by depositing aluminum oxide in the openings by an ALD method or the like and then performing anisotropic etching.

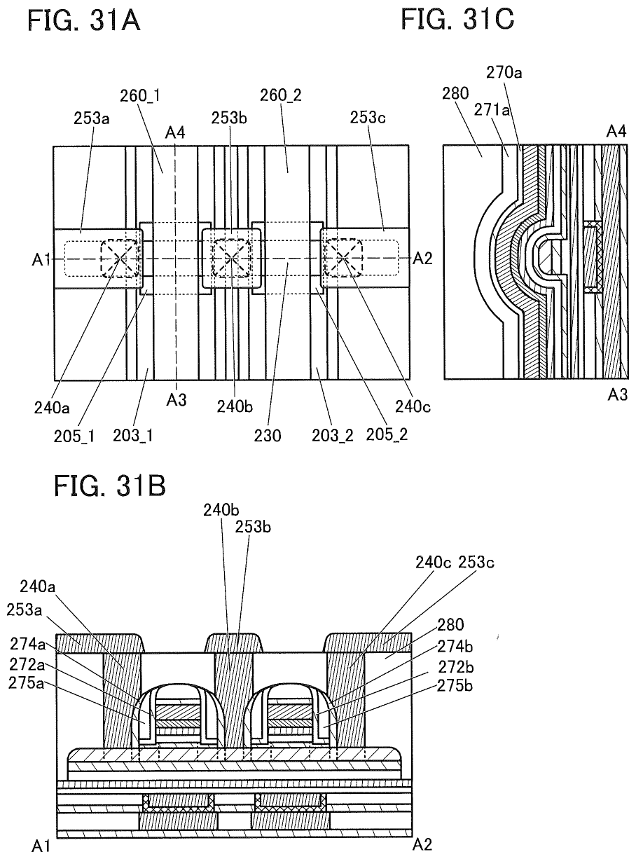

Next, a conductive film to be the conductor 253a, the conductor 253b, and the conductor 253c is formed and the conductive film is processed by a lithography method, so that the conductor 253a, the conductor 253b, and the conductor 253c are formed (see FIG. 31). The conductive film to be the conductor 253a, the conductor 253b, and the conductor 253c can be formed by a sputtering method, a CVD method, an MBE method, a PLD method, an ALD method, or the like. The conductive film to be the conductor 253a, the conductor 253b, and the conductor 253c may be formed to be embedded in an insulator.

Accordingly, the semiconductor device including the transistor 200a and the transistor 200b illustrated in FIG. 15 can be manufactured.

### <Method 2 for Manufacturing Semiconductor Device>

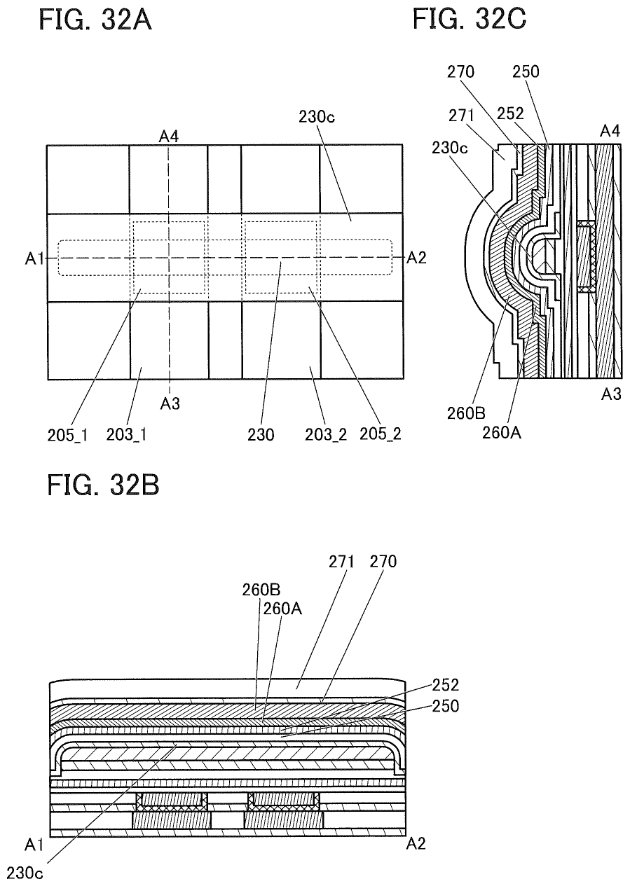

Next, a method for manufacturing the semiconductor device illustrated in FIG. 18 which includes the transistors 202a and 202b of one embodiment of the present invention is described with reference to FIG. 32 to FIG. 41. FIG. 32(A) to FIG. 41(A) are top views. FIG. 32(B) to FIG. 41(B) are cross-sectional views of portions indicated by dashed-dotted lines A1-A2 in FIG. 32(A) to FIG. 41(A). FIG. 32(C) to FIG. 41(C) are cross-sectional views of portions indicated by dashed-dotted lines A3-A4 in FIG. 32(A) to FIG. 41(A).

The method for manufacturing the semiconductor device which includes the transistors 202a and 202b is manufactured in a manner similar to the method for manufacturing the semiconductor device illustrated in FIG. 15 which includes the transistors 200a and 200b up to the formation of the oxide 230 (the oxide 230a and the oxide 230b) (see FIG. 21).

Next, an oxide film to be the oxide 230c is formed and the oxide 230c is formed by lithography. Owing to the formation of the oxide 230c, there is an advantage in that design margin can be wide because the shape and arrangement of the oxide 230c can be freely set.

Next, the insulating film 250, the insulating film 252, the conductive film 260A, the conductive film 260B, the insulating film 270, and the insulating film 271 are formed in this order over the oxide 230c (see FIG. 32).

The insulating film 250 and the insulating film 252 can be formed by a sputtering method, a CVD method, an MBE method, a PLD method, an ALD method, or the like. Here, when the insulating film 252 is formed in an atmosphere containing oxygen by a sputtering method, oxygen can be added to the insulating film 250.

Here, fourth heat treatment can be performed. For the fourth heat treatment, the conditions for the first heat treatment can be used. Through the heat treatment, the moisture concentration and the hydrogen concentration in the insulating film 250 can be reduced. Note that the fourth heat treatment is not necessarily performed in some cases.

The conductive film 260A and the conductive film 260B can be formed by a sputtering method, a CVD method, an MBE method, a PLD method, an ALD method, or the like.

The insulating film 270 and the insulating film 271 can be formed by a sputtering method, a CVD method, an MBE method, a PLD method, an ALD method, or the like; in particular, the insulating film 270 is preferably formed by an ALD method. When the insulating film 270 is formed by an ALD method, the thickness can be approximately 0.5 nm to 10 nm inclusive, preferably approximately 0.5 nm to 3 nm inclusive. Note that the formation of the insulating film 270 can be omitted.

The insulating film 271 can be used as a hard mask in processing the conductive film 260A and the conductive film 260B.

Here, fifth heat treatment can be performed. For the heat treatment, the conditions for the first heat treatment can be used. Note that the fifth heat treatment is not necessarily performed in some cases.

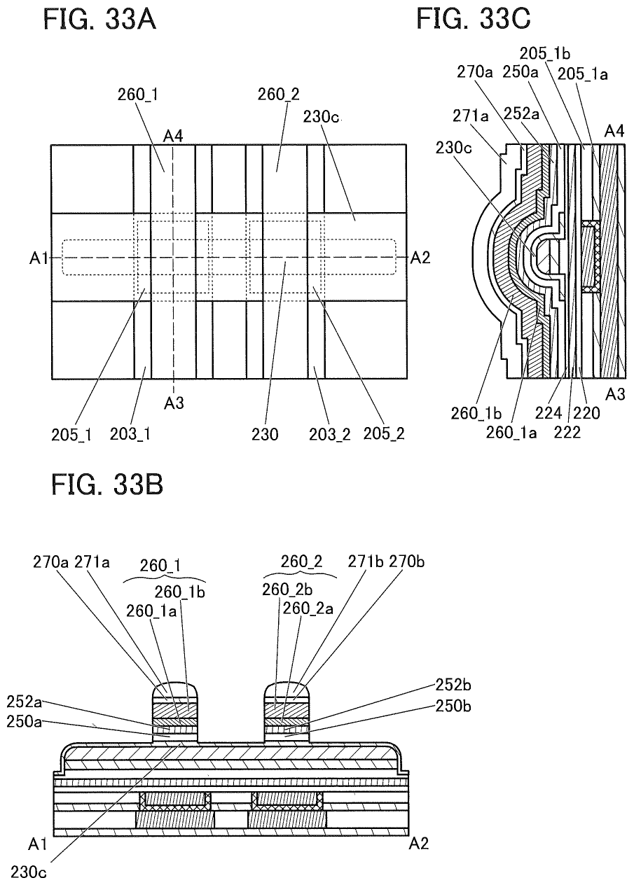

Next, the insulating film 250, the insulating film 252, the conductive film 260A, the conductive film 260B, the insulating film 270, and the insulating film 271 are etched to form the insulator 250a, the insulator 252a, the conductor 260_1a, the conductor 260_1b, the insulator 270a, the insulator 271a, the insulator 250b, the insulator 252b, the conductor 260_2a, the conductor 260_2b, the insulator 270b, and the insulator 271b (see FIG. 33). This processing is performed by a lithography method.

Here, it is preferred that the cross-sectional shapes of the insulator 250a, the insulator 252a, the conductor 260_1a, the conductor 260_1b, and the insulator 270a be tapered as little as possible. Similarly, it is preferred that the cross-sectional shapes of the insulator 250b, the insulator 252b, the conductor 260_2a, the conductor 260_2b, and the insulator 270b be tapered as little as possible. An angle formed between a bottom surface of the oxide 230 and the side surfaces of the insulator 250a, the insulator 252a, the conductor 260_1a, the conductor 260_1b, and the insulator 270a is preferably greater than or equal to 80° and less than or equal to 100°. Similarly, an angle formed between the bottom surface of the oxide 230 and the side surfaces of the insulator 250b, the insulator 252b, the conductor 260_2a, the conductor 260_2b, and the insulator 270b is preferably greater than or equal to 80° and less than or equal to 100°. Accordingly, the insulator 275a and the insulator 274a are likely to remain when the insulator 275a and the insulator 274a are formed in a later step. Similarly, the insulator 275b and the insulator 274b are likely to remain when the insulator 275b and the insulator 274b are formed.

Upper portions of the oxide 230c in regions not overlapping with the insulator 250a and the insulator 250b are etched by the above etching in some cases. In that case, the thickness of the oxide 230c in regions overlapping with the insulator 250a and the insulator 250b is larger than the thickness in the regions not overlapping with the insulator 250a and the insulator 250b.

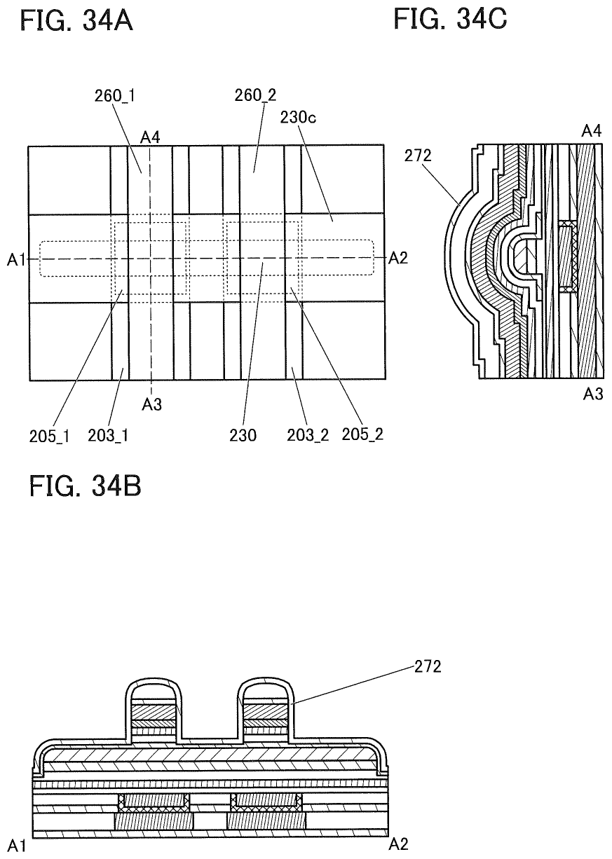

Next, the insulating film 272 is formed to cover the oxide 230c, the insulator 250a, the insulator 252a, the conductor 260_1, the insulator 270a, the insulator 271a, the insulator 250b, the insulator 252b, the conductor 260_2, the insulator 270b, and the insulator 271b. The insulating film 272 can be formed by a sputtering method, a CVD method, an MBE method, a PLD method, an ALD method, or the like. In this embodiment, aluminum oxide is deposited as the insulating film 272 by an ALD method (see FIG. 34).

The region 231 and the junction region 232 may be formed by an ion implantation method, an ion doping method by which an ionized source gas is added without mass separation, a plasma immersion ion implantation method, or the like. The ions cannot reach regions where the oxide 230 overlaps with the insulator 250a and the insulator 250b, whereas the ions reach regions not overlapping with the insulator 250a and the insulator 250b; thus, the region 231 and the junction region 232 can be formed in a self-aligned manner. When the above method is performed through the insulating film 272, implantation damage to the oxide 230 can be reduced.

In the case where mass separation is performed in an ion doping method, a plasma immersion ion implantation method, or the like, ion species to be added and its concentration can be controlled accurately. Meanwhile, in the case of not performing mass separation, ions can be added at a high concentration in a short time. An ion doping method in which atomic or molecular clusters are generated and ionized may be employed. Note that “dopant” can be replaced with “ion,” “donor,” “acceptor,” “impurity,” “element,” or the like.

As the dopant, an element that forms an oxygen vacancy, an element that is bonded to an oxygen vacancy, or the like is used. Typical examples of such an element include hydrogen, boron, carbon, nitrogen, fluorine, phosphorus, sulfur, chlorine, titanium, and a rare gas element. Typical examples of the rare gas element are helium, neon, argon, krypton, and xenon.

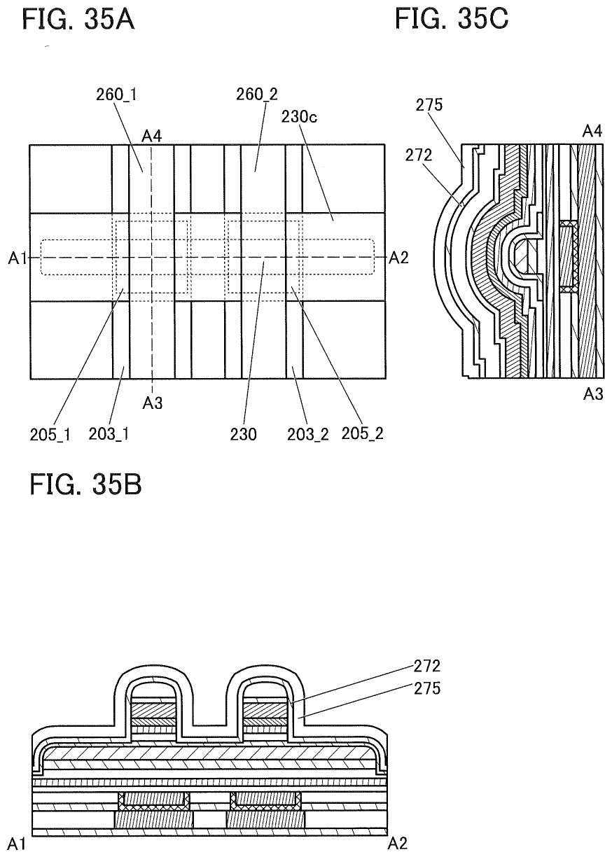

Next, the insulating film 275 is formed. The insulating film 275 can be formed by a sputtering method, a CVD method, an MBE method, a PLD method, an ALD method, or the like. In this embodiment, silicon oxide is deposited as the insulating film 275 by a CVD method (see FIG. 35).

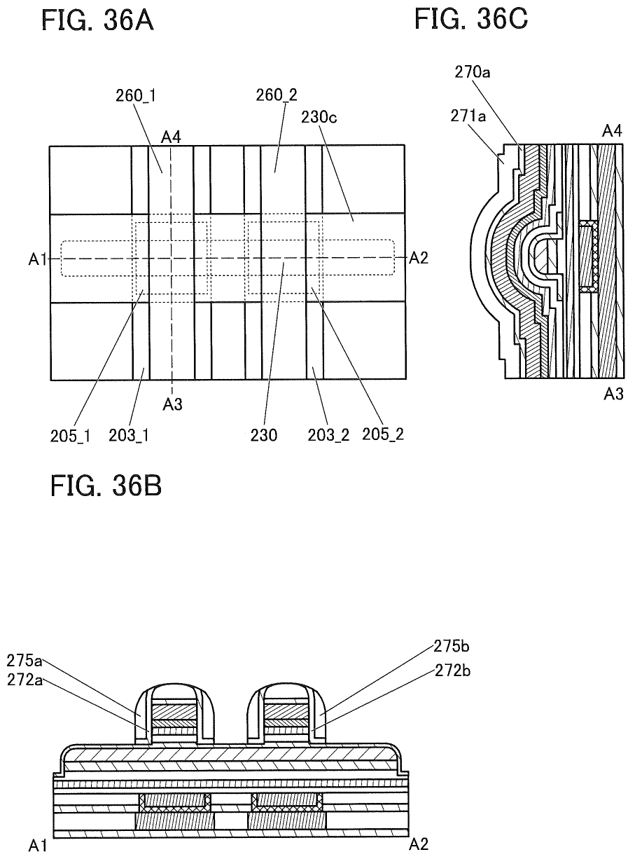

Next, the insulating film 275 is subjected to anisotropic etching treatment, whereby the insulating film 272 and the insulating film 275 are processed to form the insulator 272a, the insulator 275a, the insulator 272b, and the insulator 275b. The insulator 275a is formed to be in contact with the insulator 272a, and the insulator 275b is formed to be in contact with the insulator 272b. Dry etching treatment is preferably performed as the anisotropic etching treatment. Consequently, the insulating film 272 and the insulating film 275 formed on a plane substantially parallel to a substrate surface are removed and the insulator 275a and the insulator 275b can be formed in a self-aligned manner (see FIG. 36).

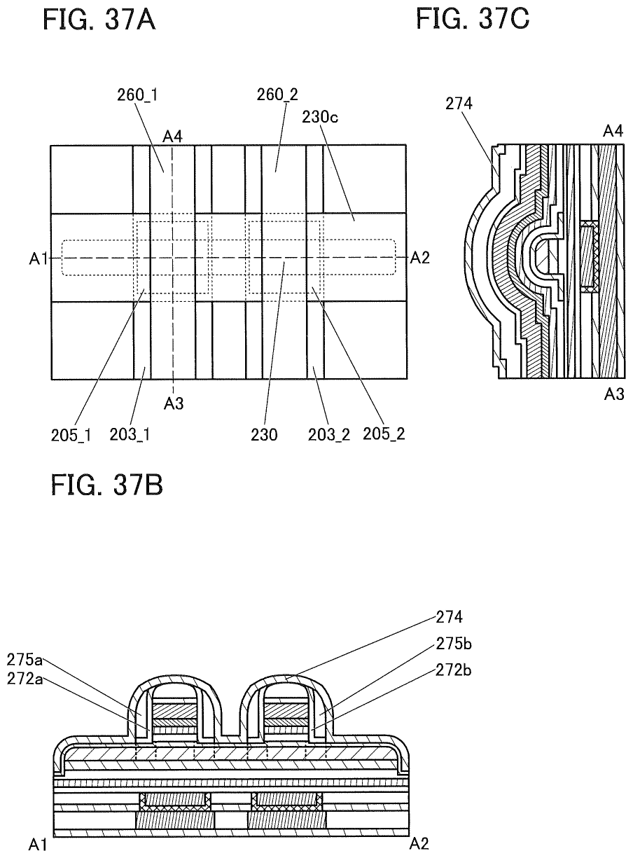

Next, the insulating film 274 is formed. The formation of the insulating film 274 is preferably performed in an atmosphere containing at least one of nitrogen and hydrogen. When the formation is performed in such an atmosphere, oxygen vacancies can be formed mainly in the regions of the oxide 230b not overlapping with the insulator 250a and the insulator 250b and the oxygen vacancies and impurity elements such as nitrogen or hydrogen can be bonded to each other, leading to an increase in carrier density. In this manner, the region 231 and the junction region 232 with reduced resistance can be formed. In particular, oxygen vacancies can be formed in the region 231 by, in addition to the above ion implantation, the formation of the insulating film 274; thus, the carrier density can be increased. For the insulating film 274, for example, silicon nitride or silicon nitride oxide formed by a CVD method can be used. In this embodiment, silicon nitride oxide is used for the insulating film 274. Here, the insulating film 274 and the oxide 230b are not in contact with each other in regions of the oxide 230b that overlap with the insulator 275a and the insulator 275b. In addition, since the oxide 230c is positioned between the insulating film 274 and the oxide 230b, excessive bonds between oxygen vacancies in the oxide 230b that are generated by the formation of the insulating film 274 and impurity elements such as nitrogen or hydrogen can be inhibited (see FIG. 37).

As described above, in the method for manufacturing a semiconductor device described in this embodiment, a source region and a drain region can be formed in a self-aligned manner owing to the formation of the insulating film 274, even in a minute transistor whose channel length is approximately 10 nm to 30 nm. Thus, miniaturized or highly integrated semiconductor devices can be manufactured with high yield.

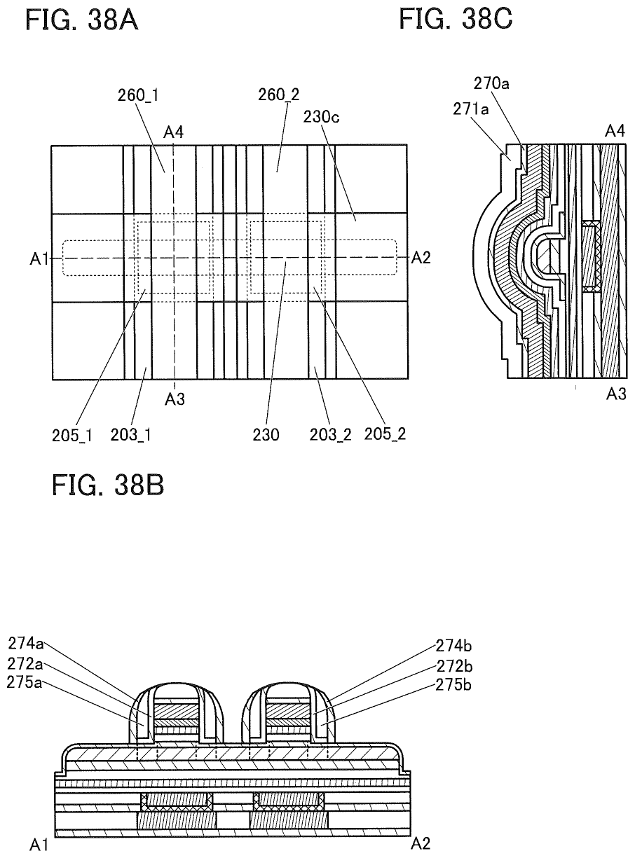

Next, anisotropic etching treatment is performed on the insulating film 274 to form the insulator 274a and the insulator 274b. Dry etching treatment is preferably performed as the anisotropic etching treatment. Consequently, the insulating film 274 formed on a plane substantially parallel to a substrate surface is removed and each of the insulator 274a and the insulator 274b can be formed in a self-aligned manner (see FIG. 38).

Next, the insulator 280 is formed. The insulator 280 can be formed by a sputtering method, a CVD method, an MBE method, a PLD method, an ALD method, or the like. Alternatively, a spin coating method, a dipping method, a droplet discharging method (e.g., an ink-jet method), a printing method (e.g., screen printing or offset printing), a doctor knife method, a roll coater method, a curtain coater method, or the like can be used. In this embodiment, silicon oxynitride is used for the insulator 280.

The insulator 280 is preferably formed to have a flat top surface. For example, the top surface of the insulator 280 may have flatness immediately after the formation. Alternatively, for example, the insulator 280 may have flatness by removing an insulator and the like from the top surface after the formation so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not need to have flatness.

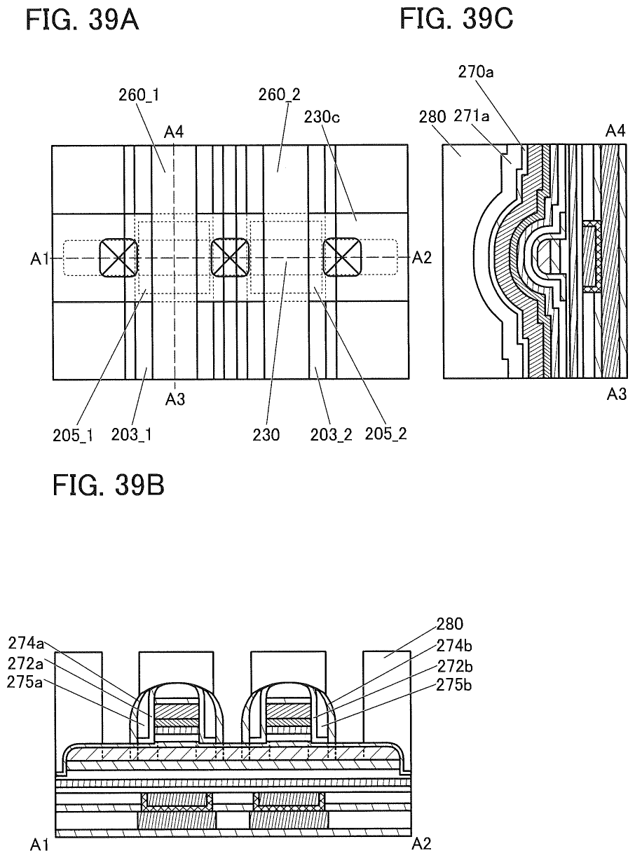

Next, openings reaching the oxide 230 are formed in the insulator 280 (see FIG. 39). A lithography method is used for the formation of the openings. Here, the openings are formed such that the conductor 240a, the conductor 240b, and the conductor 240c are provided in contact with the side surface of the insulator 274a, the side surfaces of the insulator 274a and the insulator 274b, and the side surface of the insulator 274b, respectively. The opening conditions are preferably conditions where the insulator 274a and the insulator 274b are hardly etched, i.e., conditions where the etching rate of the insulator 280 is higher than the etching rates of the insulator 274a and the insulator 274b. When the etching rates of the insulator 274a and the insulator 274b are 1, the etching rate of the insulator 280 is preferably 5 or more, further preferably 10 or more. With such opening conditions, the opening portions can be positioned on the oxide 230 in a self-aligned manner; thus, a miniaturized transistor can be manufactured. In addition, tolerance of misalignment of each opening and the conductor 260_1 and the conductor 260_2 in a lithography process is high; thus, the yield should be improved.

Here, the region 236 may be formed in the opening portions by an ion implantation method, an ion doping method by which an ionized source gas is added without mass separation, a plasma immersion ion implantation method, or the like. The ions cannot reach regions except the opening portions because of the insulator 280. In other words, the region 236 can be formed in a self-aligned manner. This ion implantation can increase the carrier density of the region 236, and thus the contact resistance of the conductor 240a, the conductor 240b, and the conductor 240c with the region 236 can be reduced.

In the case where mass separation is performed in an ion doping method, a plasma immersion ion implantation method, or the like, ion species to be added and its concentration can be controlled accurately. Meanwhile, in the case of not performing mass separation, ions can be added at a high concentration in a short time. An ion doping method in which atomic or molecular clusters are generated and ionized may be employed. Note that “dopant” can be replaced with “ion,” “donor,” “acceptor,” “impurity,” “element,” or the like.

As the dopant, an element that forms an oxygen vacancy, an element that is bonded to an oxygen vacancy, or the like is used. Typical examples of such an element include hydrogen, boron, carbon, nitrogen, fluorine, phosphorus, sulfur, chlorine, titanium, and a rare gas element. Typical examples of the rare gas element are helium, neon, argon, krypton, and xenon.

Next, a conductive film to be the conductor 240a, the conductor 240b, and the conductor 240c is formed. The conductive film to be the conductor 240a, the conductor 240b, and the conductor 240c desirably has a stacked-layer structure which includes a conductor having a function of inhibiting the passage of impurities such as water or hydrogen. For example, stacked layers of tantalum nitride, titanium nitride, or the like and tungsten, molybdenum, copper, or the like can be employed. The conductive film to be the conductor 240a, the conductor 240b, and the conductor 240c can be formed by a sputtering method, a CVD method, an MBE method, a PLD method, an ALD method, or the like.

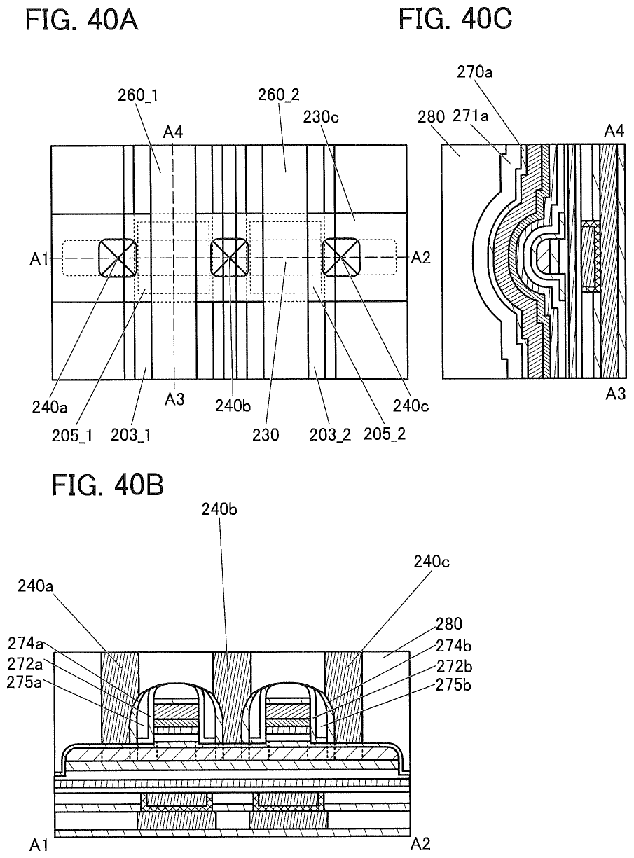

Next, CMP treatment is performed to remove the conductive film to be the conductor 240a, the conductor 240b, and the conductor 240c over the insulator 280. As a result, the conductive film remains only in the above-described openings, whereby the conductor 240a, the conductor 240b, and the conductor 240c having flat top surfaces can be formed (see FIG. 40).

The conductor 240a, the conductor 240b, and the conductor 240c may be formed after aluminum oxide is formed on side wall portions of the openings. By forming aluminum oxide on the side wall portions of the openings, the passage of oxygen from the outside can be inhibited and oxidation of the conductor 240a, the conductor 240b, and the conductor 240c can be prevented. Furthermore, impurities such as water or hydrogen can be prevented from being diffused from the conductor 240a, the conductor 240b, and the conductor 240c to the outside. The aluminum oxide can be formed by depositing aluminum oxide in the openings by an ALD method or the like and then performing anisotropic etching.

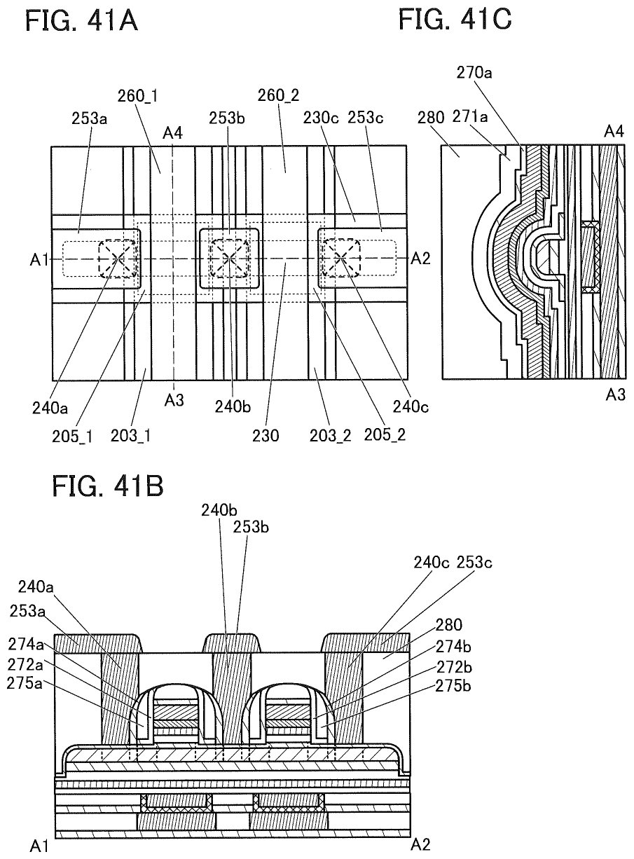

Next, a conductive film to be the conductor 253a, the conductor 253b, and the conductor 253c is formed and the conductive film is processed by a lithography method, so that the conductor 253a, the conductor 253b, and the conductor 253c are formed (see FIG. 41). The conductive film to be the conductor 253a, the conductor 253b, and the conductor 253c can be formed by a sputtering method, a CVD method, an MBE method, a PLD method, an ALD method, or the like. The conductive film to be the conductor 253a, the conductor 253b, and the conductor 253c may be formed to be embedded in an insulator.

Accordingly, the semiconductor device including the transistor 202a and the transistor 202b illustrated in FIG. 18 can be manufactured.

The structures, methods, and the like described above in this embodiment can be used in an appropriate combination with the structures, methods, and the like described in the other embodiments.

### Embodiment 3

In this embodiment, a semiconductor device including the transistor 200a, the transistor 200b, a capacitor 100a, and a capacitor 100b is described.

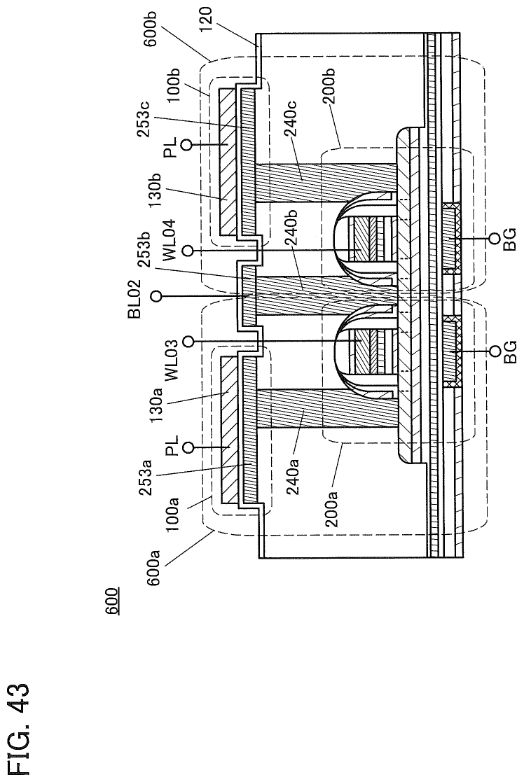

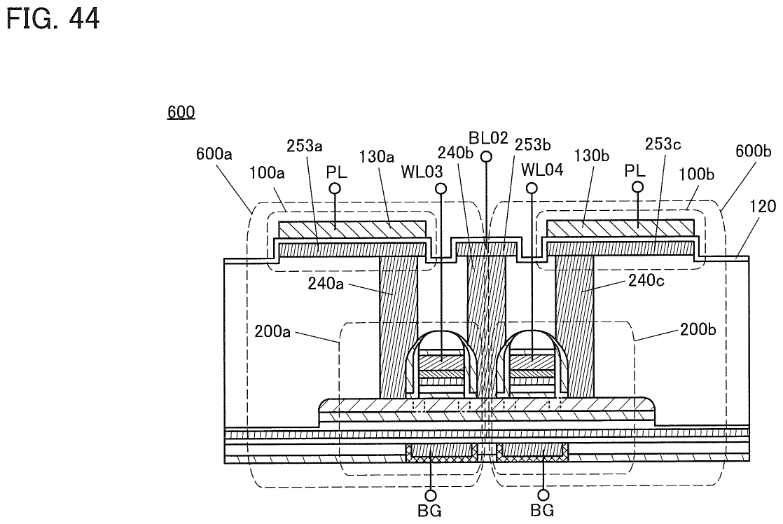

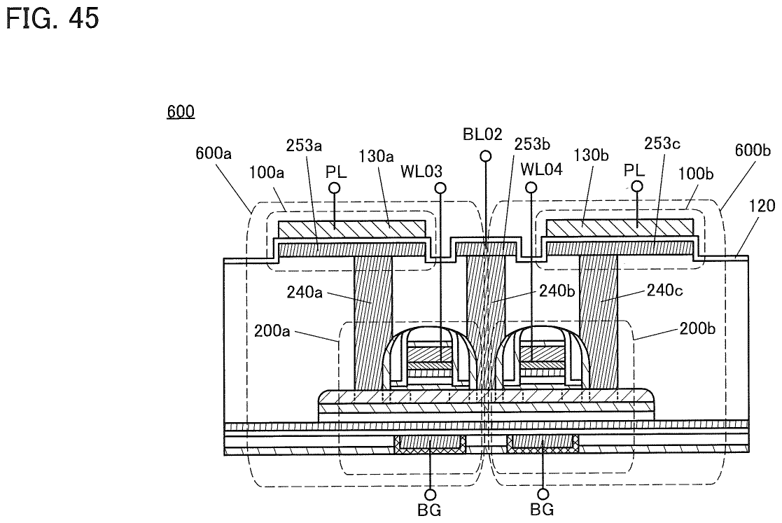

FIG. 43, FIG. 44, and FIG. 45 illustrate semiconductor devices including the transistor 200a, the transistor 200b, the capacitor 100a, and the capacitor 100b. FIG. 43 illustrates the structure of the transistor illustrated in FIG. 1, FIG. 44 illustrates the structure of the transistor illustrated in FIG. 2, and FIG. 45 illustrates the structure of the transistor illustrated in FIG. 15. Note that in this specification, a semiconductor device including one capacitor and at least one transistor is referred to as a cell.

FIG. 43, FIG. 44, and FIG. 45 are cross-sectional views of a cell 600 including the transistor 200a, the transistor 200b, the capacitor 100a, and the capacitor 100b. The cell 600 includes a cell 600a including the transistor 200a and the capacitor 100a, and a cell 600b including the transistor 200b and the capacitor 100b. Note that the above descriptions for the transistor 200a and the transistor 200b can be referred to for the structures of the transistor 200a and the transistor 200b.

As illustrated in FIG. 43, FIG. 44, and FIG. 45, the capacitor 100a is provided over the transistor 200a to overlap with each other, and the capacitor 100b is provided over the transistor 200b to overlap with each other. Here, the capacitor 100a is electrically connected to one of the source and the drain of the transistor 200a through the conductor 240a. In addition, the capacitor 100b is electrically connected to one of the source and the drain of the transistor 200b through the conductor 240c. The others of the sources and the drains of the transistor 200a and the transistor 200b can be electrically connected to a wiring or the like through the conductor 240b and the conductor 253b.

In the cell 600a, part of or the entire capacitor 100a overlaps with the transistor 200a, so that the total area of the projected area of the transistor 200a and the projected area of the capacitor 100a can be reduced. The same applies to the cell 600b. Such a structure can reduce the projected area of the cell 600.

### [Capacitor]

The capacitor 100a includes the conductor 253a, an insulator 120 provided over the conductor 253a, and a conductor 130a provided over the insulator 120 so as to overlap with the conductor 253a. The capacitor 100b includes the conductor 253c, the insulator 120 provided over the conductor 253c, and a conductor 130b provided over the insulator 120 so as to overlap with the conductor 253a.

In the capacitor 100a, the conductor 253a functions as one electrode of the capacitor 100a and the conductor 130a functions as the other electrode of the capacitor 100a. In the capacitor 100b, the conductor 253c functions as one electrode of the capacitor 100b and the conductor 130b functions as the other electrode of the capacitor 100b. The insulator 120 functions as dielectrics of the capacitor 100a and the capacitor 100b.

The insulator 120 may be, for example, a single layer or a stacked layer of aluminum oxide or silicon oxynitride.

The conductor 130a and the conductor 130b are preferably formed using a conductive material whose main component is tungsten, copper, or aluminum. Although not illustrated, the conductor 130a and the conductor 130b may have stacked-layer structures and may be, for example, stacked layers of titanium, titanium nitride, and the above-described conductive material.

The insulator 120, the conductor 130a, and the conductor 130b can be formed by a sputtering method, a CVD method, an MBE method, a PLD method, an ALD method, or the like, and are processed by a lithography method or the like.

As described above, when the transistor 200a and the transistor 200b are formed to have the structure described in this embodiment, the areas of the transistor 200a and the transistor 200b can be reduced and the semiconductor device can be miniaturized or highly integrated. Moreover, when the capacitor 100a and the capacitor 100b are provided to overlap with the transistor 200a and the transistor 200b as illustrated in FIG. 43, FIG. 44, and FIG. 45, the cell 600 can be formed while an increase in the area is suppressed.

Note that the capacitor 100a and the capacitor 100b in the cell 600 illustrated in FIG. 43, FIG. 44, and FIG. 45 have, without being limited thereto, planar shapes. The capacitor 100a and the capacitor 100b may have cylindrical shapes.

### [Structure of Cell Array]

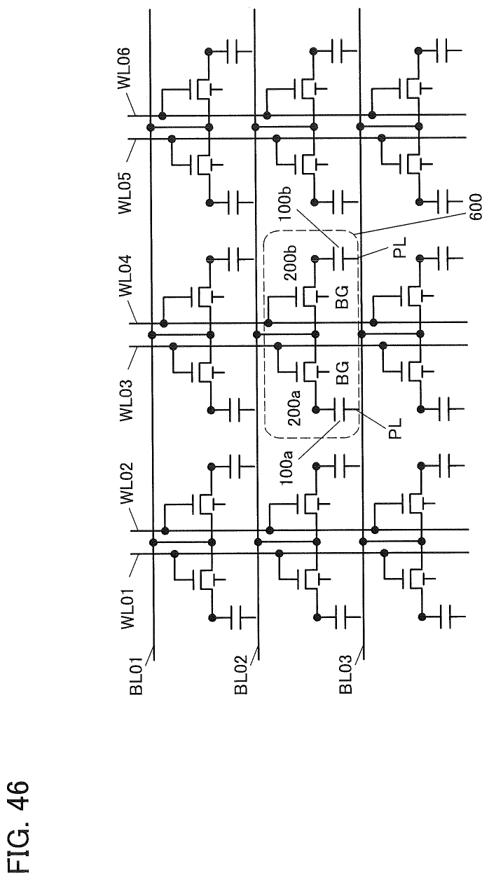

FIG. 46 illustrates an example of a cell array of this embodiment. For example, the cell array can be formed by arranging the cells 600 each including the transistor 200a, the transistor 200b, the capacitor 100a, and the capacitor 100b illustrated in FIG. 43, FIG. 44, and FIG. 45 in a matrix.

FIG. 46 is a circuit diagram showing an embodiment in which the cells 600 illustrated in FIG. 43, FIG. 44, and FIG. 45 are arranged in a matrix. Wirings BL extend in a row direction and wirings WL extend in a column direction in the cell array illustrated in FIG. 46.

In FIG. 46, ones of the sources and the drains of the transistor 200a and the transistor 200b which are included in the cell 600 are electrically connected to a common wiring BL (BL01, BL02, or BL03), as illustrated in FIG. 43, FIG. 44, and FIG. 45. The wiring BL is also electrically connected to ones of the sources and the drains of the transistor 200a and the transistor 200b included in the cells 600 arranged in the row direction. Meanwhile, the first gate of the transistor 200a and the first gate of the transistor 200b which are included in the cell 600 are electrically connected to different wirings WL (WL01 to WL06). Furthermore, these wirings WL are electrically connected to the first gates of the transistors 200a and the first gates of the transistors 200b which are included in the cells 600 arranged in the column direction.

For example, in the cell 600 connected to the BL02, the WL03, and the WL04 in FIG. 46, the conductor 253b is electrically connected to the BL02, the conductor 260_1 is electrically connected to the WL03, and the conductor 260_2 is electrically connected to the WL04, as illustrated in FIG. 43, FIG. 44, and FIG. 45.

The transistor 200a and the transistor 200b which are included in each of the cells 600 may be provided with second gates BG. The threshold voltage of the transistor can be controlled by a potential applied to the BG. Furthermore, the conductor 130a of the capacitor 100a and the conductor 130b of the capacitor 100b which are included in the cell 600 are electrically connected to different wirings PL.

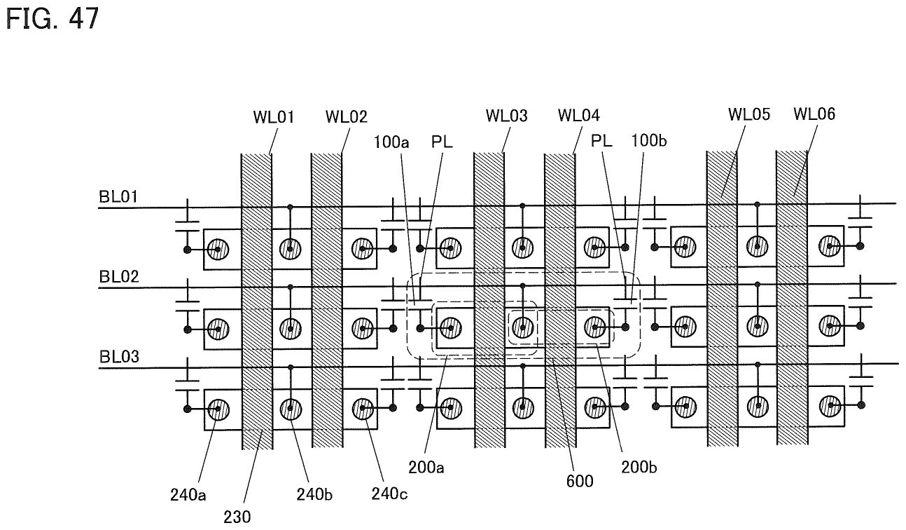

FIG. 47 illustrates a schematic view showing a layout of the wirings WL and the oxides 230 of the circuit diagram illustrated in FIG. 46. As illustrated in FIG. 47, the oxides 230 and the wirings WL are arranged in a matrix, whereby the semiconductor device of the circuit diagram illustrated in FIG. 46 can be formed. It is preferred that the wirings BL, the capacitors 100a, and the capacitors 100b be provided in a layer different from that for the wirings WL and the oxides 230 with the conductor 240a, the conductor 240b, and the conductor 240c provided therebetween.

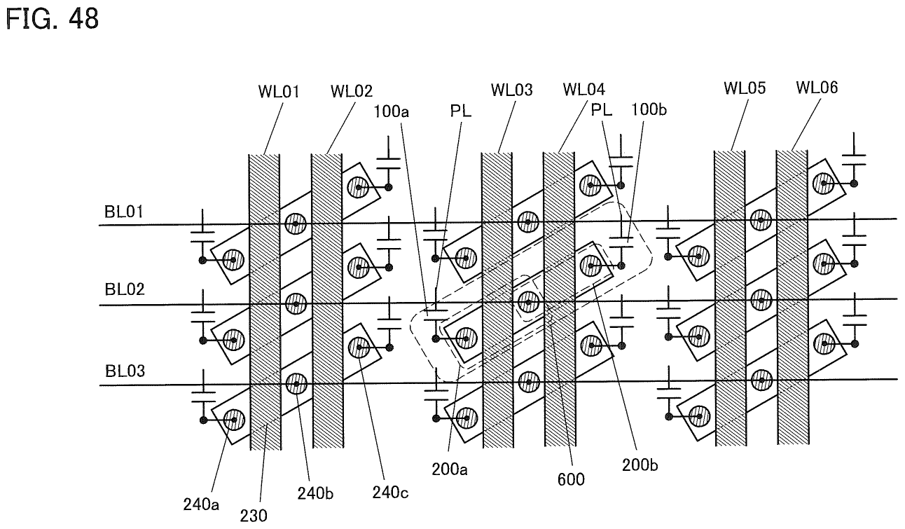

The oxides 230 and the wirings WL are provided such that, without being limited thereto, the long sides of the oxides 230 are substantially perpendicular to the extending direction of the wirings WL in FIG. 47. For example, a layout may be employed in which the long sides of the oxides 230 are not perpendicular to the extending direction of the wirings WL and the long sides of the oxides 230 are inclined with respect to the extending direction of the wirings WL as illustrated in FIG. 48. For example, the oxides 230 and the wirings WL are provided such that an angle formed between the long side of the oxide 230 and the wiring WL is greater than or equal to 20° and less than or equal to 70°, preferably greater than or equal to 30° and less than or equal to 60°.

When the oxide 230 is provided to be inclined as described above, the capacitor 100a is positioned below and the capacitor 100b is positioned above with the wiring BL positioned therebetween in the cell 600. In other words, the capacitor 100a and the capacitor 100b can be positioned so as not to overlap with the wiring BL. Accordingly, the cell 600 can be provided in a narrow area without interference with the wiring BL even when the capacitor 100a and the capacitor 100b have cylindrical shapes.

As described above, one embodiment of the present invention can provide a semiconductor device that can be miniaturized or highly integrated. Alternatively, one embodiment of the present invention can provide a semiconductor device having favorable electrical characteristics. Alternatively, one embodiment of the present invention can provide a semiconductor device with low off-state current. Alternatively, one embodiment of the present invention can provide a transistor with high on-state current. Alternatively, one embodiment of the present invention can provide a highly reliable semiconductor device. Alternatively, one embodiment of the present invention can provide a semiconductor device with reduced power consumption. Alternatively, one embodiment of the present invention can provide a semiconductor device with high productivity.

The structures, methods, and the like described above in this embodiment can be used in an appropriate combination with the structures, methods, and the like described in the other embodiments.

### Embodiment 4

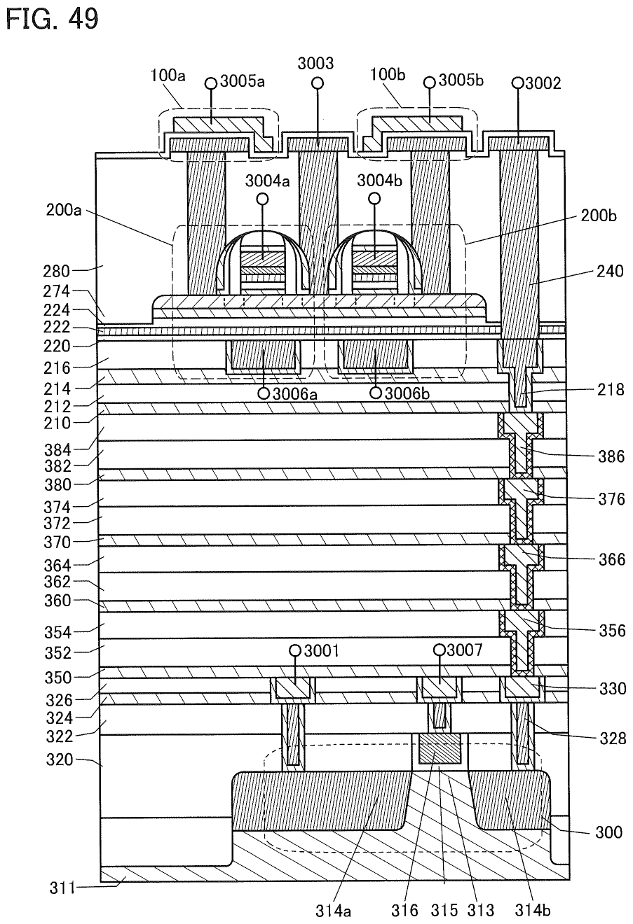

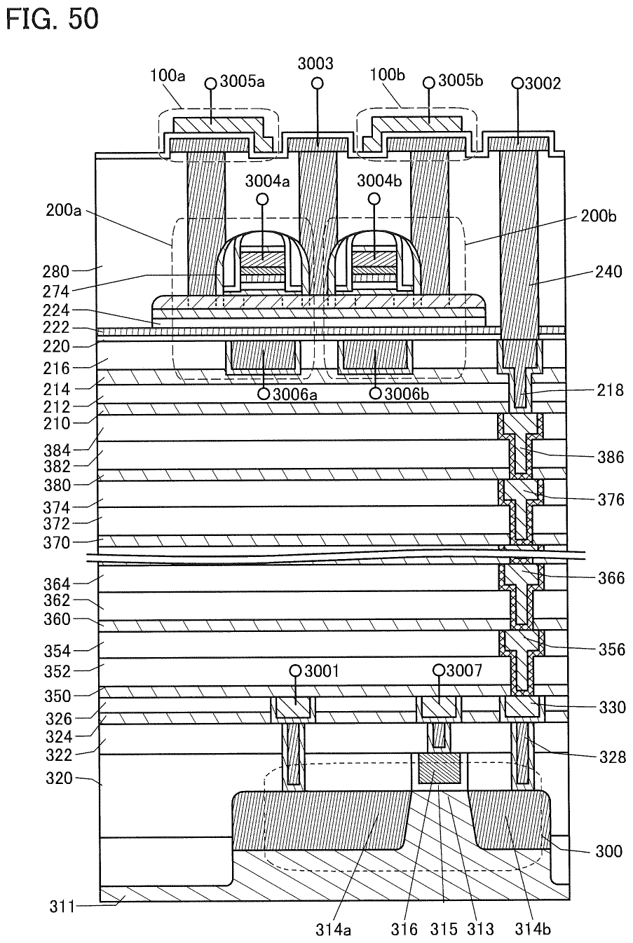

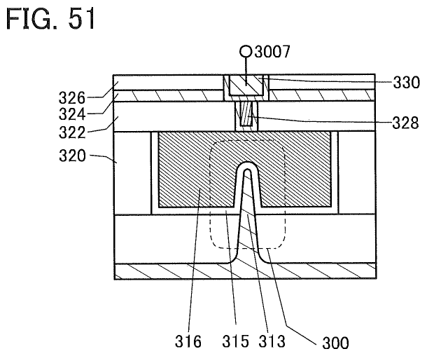

In this embodiment, one embodiment of a semiconductor device is described with reference to FIG. 49, FIG. 50, and FIG. 51. FIG. 49 illustrates the structure of the transistor illustrated in FIG. 1, and FIG. 50 illustrates the structure of the transistor illustrated in FIG. 15.

### [Memory Device 1]

Memory devices illustrated in FIG. 49 and FIG. 50 include the transistor 200a, the capacitor 100a connected to the transistor 200a, the transistor 200b, the capacitor 100b connected to the transistor 200b, and a transistor 300. FIG. 49 and FIG. 50 are cross-sectional views of the transistor 200a, the transistor 200b, and the transistor 300 in the channel length direction. FIG. 51 illustrates a cross-sectional view of the vicinity of the transistor 300 in the channel width direction of the transistor 300.

The transistor 200a and the transistor 200b are transistors in which channels are formed in semiconductor layers including oxide semiconductors. Since the off-state currents of the transistor 200a and the transistor 200b are low, memory devices using such transistors can retain stored data for a long time. In other words, since refresh operation is not required or the frequency of refresh operation is extremely low, the power consumption of the memory devices can be sufficiently reduced.

In the memory devices illustrated in FIG. 49 and FIG. 50, a wiring 3001 is electrically connected to one of a source and a drain of the transistor 300, a wiring 3002 is electrically connected to the other of the source and the drain of the transistor 300, and a wiring 3007 is electrically connected to a gate of the transistor 300. A wiring 3003 is electrically connected to one of the source and the drain of the transistor 200a and one of the source and the drain of the transistor 200b, a wiring 3004a is electrically connected to the first gate of the transistor 200a, a wiring 3004b is electrically connected to the first gate of the transistor 200b, a wiring 3006a is electrically connected to the second gate of the transistor 200a, and a wiring 3006b is electrically connected to the second gate of the transistor 200b. A wiring 3005a is electrically connected to one electrode of the capacitor 100a, and a wiring 3005b is electrically connected to one electrode of the capacitor 100b.

The semiconductor devices illustrated in FIG. 49 and FIG. 50 can be used for a memory device provided with an oxide transistor, such as a DOSRAM described later. Owing to the characteristics that the off-state currents of the transistor 200a and the transistor 200b are low and the potential of the other of the source and the drain (also referred to the other electrode of the capacitor 100a and the capacitor 100b) can be retained, data can be written, retained, and read.

### <Structure of Memory Device 1>

The semiconductor device of one embodiment of the present invention includes the transistor 300, the transistor 200a, the transistor 200b, the capacitor 100a, and the capacitor 100b as illustrated in FIG. 49 and FIG. 50. The transistor 200a and the transistor 200b are provided above the transistor 300, and the capacitor 100a and the capacitor 100b are provided above the transistor 300, the transistor 200a, and the transistor 200b.

The transistor 300 is provided in a substrate 311 and includes a conductor 316, an insulator 315, a semiconductor region 313 that is part of the substrate 311, and a low-resistance region 314a and a low-resistance region 314b functioning as a source region and a drain region.

As illustrated in FIG. 51, a top surface and a side surface in the channel width direction of the semiconductor region 313 of the transistor 300 are covered with the conductor 316 with the insulator 315 provided therebetween. When the transistor 300 is such a Fin-type transistor, the effective channel width is increased, whereby the on-state characteristics of the transistor 300 can be improved. In addition, since contribution of the electric field of the gate electrode can be increased, the off-state characteristics of the transistor 300 can be improved.

The transistor 300 is of either a p-channel type or an n-channel type.

A region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, further preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 300 may be an HEMT (High Electron Mobility Transistor) by using GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

For the conductor 316 functioning as a gate electrode, a semiconductor material such as silicon containing the element which imparts n-type conductivity, such as arsenic or phosphorus, or the element which imparts p-type conductivity, such as boron, or a conductive material such as a metal material, an alloy material, or a metal oxide material can be used.

Note that since a material of a conductor determines the work function, a threshold voltage can be adjusted by changing the material of the conductor. Specifically, it is preferred to use a material such as titanium nitride or tantalum nitride for the conductor. Furthermore, in order to ensure both conductivity and embeddability, it is preferred to use a stacked layer of metal materials such as tungsten and aluminum for the conductor, and it is particularly preferred to use tungsten in terms of heat resistance.

Note that the transistor 300 illustrated in FIG. 49 and FIG. 50 is an example and the structure is not limited thereto; a transistor appropriate for a circuit configuration or a driving method is used.

An insulator 320, an insulator 322, an insulator 324, and an insulator 326 are provided to be stacked in this order to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

The insulator 322 may function as a planarization film for eliminating a level difference caused by the transistor 300 or the like provided below the insulator 322. For example, a top surface of the insulator 322 may be planarized by planarization treatment using a chemical mechanical polishing (CMP) method or the like to improve planarity.

For the insulator 324, it is preferred to use a film having a barrier property that prevents diffusion of hydrogen and impurities from the substrate 311, the transistor 300, or the like into a region where the transistor 200a and the transistor 200b are provided.

As an example of the film having a barrier property against hydrogen, silicon nitride formed by a CVD method can be used. Here, the diffusion of hydrogen into a semiconductor element including an oxide semiconductor, such as the transistor 200a or the transistor 200b, degrades the characteristics of the semiconductor element in some cases. Therefore, a film that inhibits diffusion of hydrogen is preferably used between the transistor 300 and the transistor 200a and the transistor 200b. The film that inhibits diffusion of hydrogen is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm² in the TDS analysis in a film-surface temperature ranging from 50° C. to 500° C., for example.

Note that the insulator 326 preferably has a lower dielectric constant than the insulator 324. For example, the dielectric constant of the insulator 326 is preferably lower than 4, further preferably lower than 3. For example, the dielectric constant of the insulator 326 is preferably 0.7 times or less, further preferably 0.6 times or less the dielectric constant of the insulator 324. When a material with a low dielectric constant is used for an interlayer film, the parasitic capacitance generated between wirings can be reduced.

Moreover, a conductor 328, a conductor 330, and the like that are electrically connected to the transistor 300 are embedded in the insulator 320, the insulator 322, the insulator 324, and the insulator 326. Note that the conductor 328 and the conductor 330 function as plugs or wirings. In addition, a plurality of conductors functioning as plugs or wirings are collectively denoted by the same reference numeral in some cases. Furthermore, in this specification and the like, a wiring and a plug electrically connected to the wiring may be a single component. That is, there are a case where part of a conductor functions as a wiring and a case where part of a conductor functions as a plug.

As a material for each of the plugs and wirings (the conductor 328, the conductor 330, and the like), a single layer or a stacked layer of a conductive material such as a metal material, an alloy material, a metal nitride material, or a metal oxide material can be used. It is preferred to use a high-melting-point material that has both heat resistance and conductivity, such as tungsten or molybdenum; it is further preferred to use tungsten. Alternatively, it is preferred to use a low-resistance conductive material such as aluminum or copper. The use of a low-resistance conductive material can reduce wiring resistance.

A wiring layer may be provided over the insulator 326 and the conductor 330. For example, in FIG. 49 and FIG. 50, an insulator 350, an insulator 352, and an insulator 354 are provided to be stacked in this order. Furthermore, a conductor 356 is formed in the insulator 350, the insulator 352, and the insulator 354. The conductor 356 functions as a plug or a wiring. Note that the conductor 356 can be provided using a material similar to those for the conductor 328 and the conductor 330.

Note that for example, an insulator having a barrier property against hydrogen is preferably used for the insulator 350, as with the insulator 324. Furthermore, the conductor 356 preferably includes a conductor having a barrier property against hydrogen. The conductor having a barrier property against hydrogen is formed in an opening portion included in the insulator 350 having a barrier property against hydrogen. In such a structure, the transistor 300 can be separated from the transistor 200a and the transistor 200b by a barrier layer, so that diffusion of hydrogen from the transistor 300 into the transistor 200a and the transistor 200b can be inhibited.

Note that for the conductor having a barrier property against hydrogen, tantalum nitride is preferably used, for example. In addition, by stacking tantalum nitride and tungsten, which has high conductivity, the diffusion of hydrogen from the transistor 300 can be inhibited while the conductivity as a wiring is kept. In that case, it is preferred to have a structure in which a tantalum nitride layer having a barrier property against hydrogen is in contact with the insulator 350 having a barrier property against hydrogen.

A wiring layer may be provided over the insulator 350 and the conductor 356. For example, in FIG. 49 and FIG. 50, an insulator 360, an insulator 362, and an insulator 364 are provided to be stacked in this order. Furthermore, a conductor 366 is formed in the insulator 360, the insulator 362, and the insulator 364. The conductor 366 functions as a plug or a wiring. Note that the conductor 366 can be provided using a material similar to those for the conductor 328 and the conductor 330.

Note that for example, an insulator having a barrier property against hydrogen is preferably used for the insulator 360, as with the insulator 324. Furthermore, the conductor 366 preferably includes a conductor having a barrier property against hydrogen. The conductor having a barrier property against hydrogen is formed in an opening portion included in the insulator 360 having a barrier property against hydrogen. In such a structure, the transistor 300 can be separated from the transistor 200a and the transistor 200b by a barrier layer, so that diffusion of hydrogen from the transistor 300 into the transistor 200a and the transistor 200b can be inhibited.

A wiring layer may be provided over the insulator 364 and the conductor 366. For example, in FIG. 49 and FIG. 50, an insulator 370, an insulator 372, and an insulator 374 are provided to be stacked in this order. Furthermore, a conductor 376 is formed in the insulator 370, the insulator 372, and the insulator 374. The conductor 376 functions as a plug or a wiring. Note that the conductor 376 can be provided using a material similar to those for the conductor 328 and the conductor 330.

Note that for example, an insulator having a barrier property against hydrogen is preferably used for the insulator 370, as with the insulator 324. Furthermore, the conductor 376 preferably includes a conductor having a barrier property against hydrogen. The conductor having a barrier property against hydrogen is formed in an opening portion included in the insulator 370 having a barrier property against hydrogen. In such a structure, the transistor 300 can be separated from the transistor 200a and the transistor 200b by a barrier layer, so that diffusion of hydrogen from the transistor 300 into the transistor 200a and the transistor 200b can be inhibited.

A wiring layer may be provided over the insulator 374 and the conductor 376. For example, in FIG. 49 and FIG. 50, an insulator 380, an insulator 382, and an insulator 384 are provided to be stacked in this order. Furthermore, a conductor 386 is formed in the insulator 380, the insulator 382, and the insulator 384. The conductor 386 functions as a plug or a wiring. Note that the conductor 386 can be provided using a material similar to those for the conductor 328 and the conductor 330.

Note that for example, an insulator having a barrier property against hydrogen is preferably used for the insulator 380, as with the insulator 324. Furthermore, the conductor 386 preferably includes a conductor having a barrier property against hydrogen. The conductor having a barrier property against hydrogen is formed in an opening portion included in the insulator 380 having a barrier property against hydrogen. In such a structure, the transistor 300 can be separated from the transistor 200a and the transistor 200b by a barrier layer, so that diffusion of hydrogen from the transistor 300 into the transistor 200a and the transistor 200b can be inhibited.

Although the wiring layer including the conductor 356, the wiring layer including the conductor 366, the wiring layer including the conductor 376, and the wiring layer including the conductor 386 are described above, the memory device of this embodiment is not limited thereto. The number of wiring layers similar to the wiring layer including the conductor 356 may be three or less, or the number of wiring layers similar to the wiring layer including the conductor 356 may be five or more.

The insulator 210 and the insulator 212 are provided to be stacked in this order over the insulator 384. A material having a barrier property against oxygen and hydrogen is preferably used for either the insulator 210 or the insulator 212.

For the insulator 210, for example, it is preferred to use a film having a barrier property that prevents diffusion of hydrogen and impurities from the substrate 311, a region where the transistor 300 is provided, or the like into a region where the transistor 200a and the transistor 200b are provided. Therefore, a material similar to that for the insulator 324 can be used.

As an example of the film having a barrier property against hydrogen, silicon nitride formed by a CVD method can be used. Here, the diffusion of hydrogen into a semiconductor element including an oxide semiconductor, such as the transistor 200a or the transistor 200b, degrades the characteristics of the semiconductor element in some cases. Therefore, a film that inhibits diffusion of hydrogen is preferably used between the transistor 300 and the transistor 200a and the transistor 200b. The film that inhibits diffusion of hydrogen is specifically a film from which a small amount of hydrogen is released.

As the film having a barrier property against hydrogen in the insulator 210, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of a change in electrical characteristics of the transistor. Accordingly, aluminum oxide can prevent entry of impurities such as hydrogen and moisture into the transistor 200a and the transistor 200b in a manufacturing process of the transistor and after the manufacturing process. In addition, release of oxygen from the oxide included in the transistor 200a and the transistor 200b can be inhibited. Therefore, aluminum oxide is suitably used for a protective film for the transistor 200a and the transistor 200b.

For the insulator 212, for example, a material similar to that for the insulator 320 can be used. When a material with a relatively low dielectric constant is used for an interlayer film, the parasitic capacitance between wirings can be reduced. For example, a silicon oxide film, a silicon oxynitride film, or the like can be used for the insulator 212.

Moreover, a conductor 218, and conductors (the conductors 205) and the like included in the transistor 200a and the transistor 200b are embedded in the insulator 210, the insulator 212, the insulator 214, and the insulator 216. Note that the conductor 218 functions as a plug or a wiring that is electrically connected to the transistor 300 or the transistor 200a and the transistor 200b. The conductor 218 can be provided using a material similar to those for the conductor 328 and the conductor 330.

In particular, the conductor 218 in a region in contact with the insulator 210 and the insulator 214 is preferably a conductor having a barrier property against oxygen, hydrogen, and water. In such a structure, the transistor 300 can be separated from the transistor 200a and the transistor 200b by a layer having a barrier property against oxygen, hydrogen, and water; thus, the diffusion of hydrogen from the transistor 300 into the transistor 200a and the transistor 200b can be inhibited.

The transistor 200a and the transistor 200b are provided above the insulator 212. Note that the transistor 200a and the transistor 200b have the structures of the transistor 200a and the transistor 200b described in the above embodiment. The transistor 200a and the transistor 200b illustrated in FIG. 49 and FIG. 50 are examples and the structures are not limited thereto; transistors appropriate for a circuit configuration or a driving method are used.

Furthermore, the conductor 240 is provided in contact with the conductor 218, so that the conductor 253 which is connected to the transistor 300 can be extracted above the transistor 200a and the transistor 200b. The wiring 3002 is extracted above the transistor 200a and the transistor 200b in FIG. 49 and FIG. 50 without being limited thereto; a structure may be employed in which the wiring 3001, the wiring 3007, and the like are extracted above the transistor 200a and the transistor 200b.

The above is the description of the structure example. With the use of the structure, a change in electrical characteristics can be reduced and reliability can be improved in a semiconductor device using a transistor including an oxide semiconductor. Alternatively, a transistor including an oxide semiconductor with a high on-state current can be provided. Alternatively, a transistor including an oxide semiconductor with a low off-state current can be provided. Alternatively, a semiconductor device with low power consumption can be provided.

The structures, methods, and the like described above in this embodiment can be used in an appropriate combination with the structures, methods, and the like described in the other embodiments.

### Embodiment 5

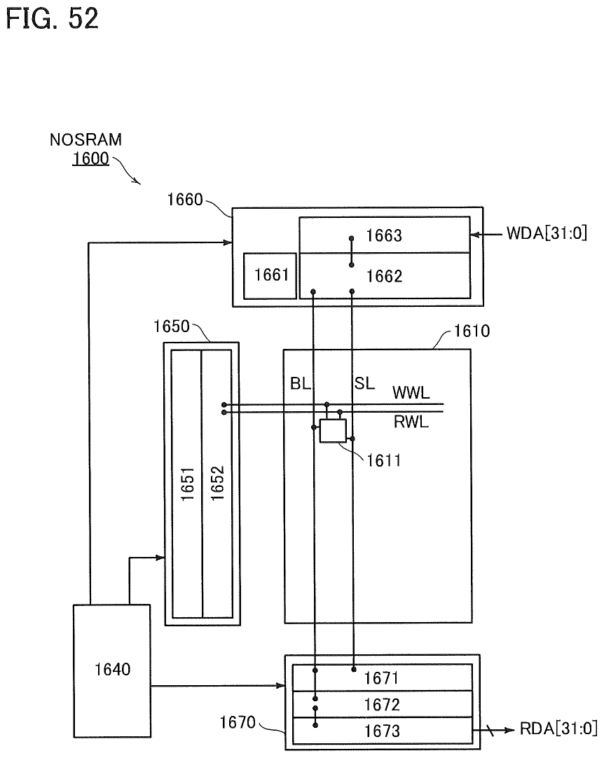

In this embodiment, a NOSRAM (registered trademark) is described with reference to FIG. 52 to FIG. 55 as an example of a memory device of one embodiment of the present invention in which a transistor using an oxide for a semiconductor (hereinafter referred to as an OS transistor) and a capacitor are applied. A NOSRAM is an abbreviation of “Nonvolatile Oxide Semiconductor RAM,” indicating a RAM including a gain cell (2T or 3T) memory cell.

A memory device in which OS transistors are used in memory cells (hereinafter referred to as an “OS memory”) is used in a NOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

### <<NOSRAM>>

FIG. 52 illustrates a structure example of a NOSRAM. A NOSRAM 1600 illustrated in FIG. 52 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL and RWL, bit lines BL, and source lines SL. The word lines WWL are write word lines and the word lines RWL are read word lines. In the NOSRAM 1600, one memory cell 1611 stores 3-bit (8-level) data.

The controller 1640 controls the entire NOSRAM 1600 as a whole, and writes data WDA[31:0] and reads out data RDA[31:0]. The controller 1640 processes command signals from the outside (e.g., a chip enable signal and a write enable signal) to generate control signals for the row driver 1650, the column driver 1660, and the output driver 1670.

The row driver 1650 has a function of selecting a row to be accessed. The row driver 1650 includes a row decoder 1651 and a word line driver 1652.

The column driver 1660 drives the source lines SL and the bit lines BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source lines SL, a function of bringing the source lines SL into an electrically floating state, a function of selecting a source line SL, a function of inputting a writing voltage generated by the DAC 1663 to the selected source line SL, a function of precharging the bit line BL, a function of bringing the bit lines BL into an electrically floating state, and the like.

The output driver 1670 includes a selector 1671, an ADC (analog-digital converter circuit) 1672, and an output buffer 1673. The selector 1671 selects a source line SL to be accessed and transmits the voltage of the selected source line SL to the ADC 1672. The ADC 1672 has a function of converting an analog voltage into 3-bit digital data. The voltage of the source line SL is converted into 3-bit data in the ADC 1672, and the output buffer 1673 retains data output from the ADC 1672.

Note that the configuration of the row driver 1650, the column driver 1660, and the output driver 1670 described in this embodiment is not limited to the above. The arrangement of those drivers and wirings connected to the drivers may be changed or the functions of the drivers and the wirings connected to the drivers may be changed or added, depending on the configuration, driving method, or the like of the memory cell array 1610. For example, a configuration may be employed in which the bit lines BL have part of the function of the source lines SL.

Although the amount of data retained in each of the memory cells 1611 is 3 bits in the above description, the structure of the memory device of this embodiment is not limited thereto. The amount of data retained in each of the memory cells 1611 may be 2 bits or less or 4 bits or more. In the case where the amount of data retained in each of the memory cells 1611 is one bit, for example, a structure may be employed in which the DAC 1663 and the ADC 1672 are not provided.

### <Memory Cell>

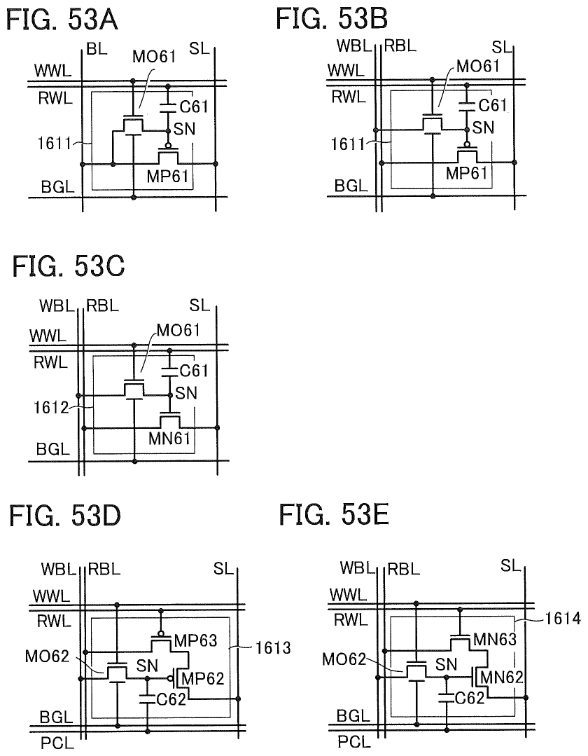

FIG. 53(A) is a circuit diagram showing a structure example of the memory cell 1611. The memory cell 1611 is a 2T gain cell, and the memory cell 1611 is electrically connected to the word lines WWL and RWL, the bit line BL, the source line SL, and a wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the voltage of the node SN. The node SN is a data storage node and corresponds to a gate of the transistor MP61 here.

The write transistor of the memory cell 1611 is formed using the OS transistor MO61; thus, the NOSRAM 1600 can retain data for a long time.

As for the bit line, a common bit line is used for writing and reading in the example of FIG. 53(A); however, as illustrated in FIG. 53(B), a bit line WBL functioning as a write bit line and a bit line RBL functioning as a read bit line may be provided.

FIG. 53(C) to FIG. 53(E) illustrate other structure examples of the memory cell. FIG. 53(C) to FIG. 53(E) illustrate examples where the bit line WBL for writing and the bit line RBL for reading are provided; however, as in FIG. 53(A), a bit line shared in writing and reading may be provided.

A memory cell 1612 illustrated in FIG. 53(C) is a modification example of the memory cell 1611 where the read transistor is changed into an n-channel transistor (MN61). The transistor MN61 may be an OS transistor or a Si transistor.

In the memory cells 1611 and 1612, the OS transistor MO61 may be an OS transistor with no back gate.

A memory cell 1613 illustrated in FIG. 53(D) is a 3T gain cell and is electrically connected to the word lines WWL and RWL, the bit lines WBL and RBL, the source line SL, and wirings BGL and PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

A memory cell 1614 illustrated in FIG. 53(E) is a modification example of the memory cell 1613 where the read transistor and the selection transistor are changed into n-channel transistors (MN62 and MN63). The transistors MN62 and MN63 may be OS transistors or Si transistors.

The OS transistors provided in the memory cells 1611 to 1614 may be transistors with no back gates or transistors with back gates.

What is called a NOR memory device in which the memory cells 1611 or the like are connected in parallel is described above, but the memory device of this embodiment is not limited thereto. For example, what is called a NAND memory device in which memory cells 1615 described below are connected in series may be provided.

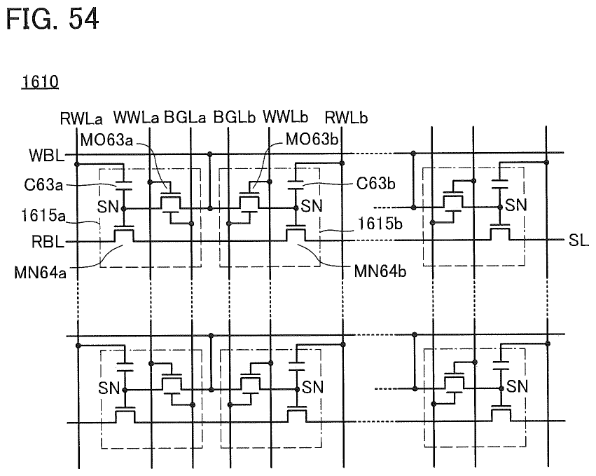

FIG. 54 is a circuit diagram showing a structure example of the NAND memory cell array 1610. The memory cell array 1610 illustrated in FIG. 54 includes the source line SL, the bit line RBL, the bit line WBL, the word line WWL, the word line RWL, the wiring BGL, and the memory cell 1615. The memory cell 1615 includes the node SN, an OS transistor MO63, a transistor MN64, and a capacitor C63. Here, the transistor MN64 is formed of an n-channel Si transistor, for example. The transistor MN64 is not limited thereto and may be a p-channel Si transistor or an OS transistor.

A memory cell 1615a and a memory cell 1615b illustrated in FIG. 54 are described below as examples. Here, the character “a” or “b” is added to the reference numerals of wirings and circuit elements connected to either the memory cell 1615a or the memory cell 1615b.

In the memory cell 1615a, a gate of a transistor MN64a, one of a source and a drain of a transistor MO63a, and one electrode of a capacitor C63a are electrically connected to one another. The bit line WBL and the other of the source and the drain of the transistor MO63a are electrically connected to each other. A word line WWLa and a gate of the transistor MO63a are electrically connected to each other. A wiring BGLa and a back gate of the transistor MO63a are electrically connected to each other. A word line RWLa and the other electrode of the capacitor C63a are electrically connected to each other.

The memory cell 1615b can be provided symmetric to the memory cell 1615a with a contact portion with the bit line WBL as a symmetric axis. Therefore, circuit elements included in the memory cell 1615b are connected to wirings as in the memory cell 1615a.

A source of the transistor MN64a included in the memory cell 1615a is electrically connected to a drain of a transistor MN64b of the memory cell 1615b. A drain of the transistor MN64a included in the memory cell 1615a is electrically connected to the bit line RBL. A source of the transistor MN64b included in the memory cell 1615b is electrically connected to the source line SL through the transistors MN64 included in the plurality of memory cells 1615. As described here, the plurality of transistors MN64 are connected in series between the bit line RBL and the source line SL in the NAND memory cell array 1610.

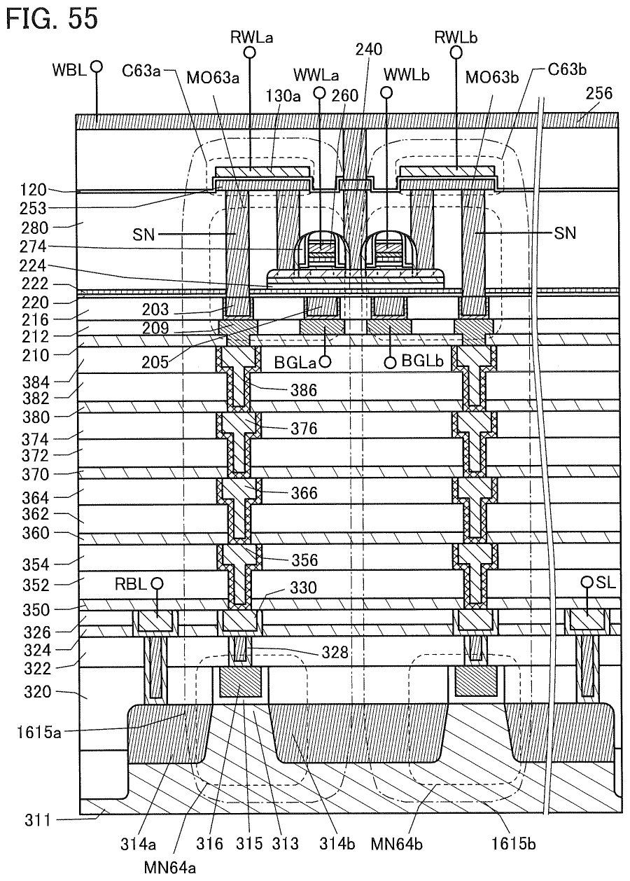

FIG. 55 illustrates a cross-sectional view of the memory cell 1615a and the memory cell 1615b. The memory cell 1615a and the memory cell 1615b have a structure similar to that of the memory device illustrated in FIG. 50. That is, the capacitor C63a and a capacitor C63b have structures similar to those of the capacitors 100, the OS transistor MO63a and an OS transistor MO63b have structures similar to those of the transistors 200, and the transistor MN64a and the transistor MN64b have structures similar to those of the transistors 300. Note that for components illustrated in FIG. 55 that are denoted by the same reference numerals as the components illustrated in FIG. 49 and FIG. 50, refer to the corresponding description.

In the memory cell 1615a, the conductor 130a is provided to extend and functions as the word line RWLa, the conductor 260 is provided to extend and functions as the word line WWLa, and a conductor 209 in contact with a bottom surface of the conductor 205 is provided to extend and functions as the wiring BGLa. A word line RWLb, a word line WWLb, and a wiring BGLb are provided similarly in the memory cell 1615b.

The low-resistance region 314b illustrated in FIG. 55 functions as the source of the transistor MN64a and the drain of the transistor MN64b. The low-resistance region 314a functioning as the drain of the transistor MN64a is electrically connected to the bit line RBL through the conductor 328 and the conductor 330. The source of the transistor MN64b is electrically connected to the source line SL through the transistors MN64 included in the plurality of memory cells 1615, the conductor 328, and the conductor 330.

A conductor 256 is provided to extend and functions as the bit line WBL. The conductor 240 functions as the contact portion with the word line WBL and is shared by the transistor MO63a and the transistor MO63b. When the contact portion with the bit line WBL is shared by the memory cell 1615a and the memory cell 1615b as described above, the number of contact portions with the bit line WBL can be reduced and the area occupied by the memory cell 1615 when seen from the top can be reduced. Accordingly, the memory device of this embodiment can be further highly integrated and the storage capacity per unit area can be increased.

In a memory device including the memory cell array 1610 illustrated in FIG. 54, writing operation and reading operation are performed for each group of memory cells (hereinafter referred to as a memory cell column) connected to the same word line WWL (or the word line RWL). For example, the writing operation can be performed as follows. A potential at which the transistor MO63 is brought into an on state is applied to the word line WWL connected to a memory cell column on which writing is performed so that the transistors MO63 in the memory cell column on which writing is performed are brought into an on state. Accordingly, the potential of the bit line WBL is applied to the gates of the transistors MN64 and one electrodes of the capacitors C63 in the specified memory cell column, whereby a predetermined charge is applied to the gates. Thus, data can be written to the memory cells 1615 in the specified memory cell column.

For example, the reading operation can be performed as follows. First, a potential at which the transistor MN64 is brought into an on state is applied to the word lines RWL not connected to a memory cell column on which reading is performed regardless of a charge applied to the gates of the transistors MN64, so that the transistors MN64 not in the memory cell column on which reading is performed are brought into an on state. Then, a potential (reading potential) at which an on state or an off state of the transistor MN64 is selected is applied to the word line RWL connected to the memory cell column on which reading is performed in accordance with a charge of the gates of the transistors MN64. Then, a fixed potential is applied to the source line SL and a reading circuit connected to the bit line RBL is brought into an operation state. Here, the plurality of transistors MN64 between the source line SL and the bit line RBL are in an on state except the transistor in the memory cell column on which reading is performed; therefore, the conductance between the source line SL and the bit line RBL depends on the state (an on state or an off state) of the transistor MN64 in the memory cell column on which reading is performed. Since the conductance of the transistor varies depending on the charge of the gate of the transistor MN64 in the memory cell column on which reading is performed, the potential of the bit line RBL varies accordingly. By reading the potential of the bit line RBL with the reading circuit, data can be read from the memory cell 1615 in the specified memory cell column.

There is no limitation on the number of rewriting operations of the NOSRAM 1600 in principle because data is rewritten by charging and discharging of the capacitor C61, the capacitor C62, or the capacitor C63, and data can be written and read with low energy. Furthermore, since data can be retained for a long time, the refresh rate can be reduced.

In the case where the semiconductor device described in the above embodiment is used for the memory cells 1611, 1612, 1613, 1614, and 1615, the transistors 200 can be used as the OS transistors MO61, MO62, and MO63, the capacitors 100 can be used as the capacitors C61, C62, and C63, and the transistors 300 can be used as the transistors MP61, MP62, MP63, MN61, MN62, MN63, and MN64. Accordingly, the area occupied by one set consisting of a transistor and a capacitor when seen from the above can be reduced, so that the memory device of this embodiment can be further highly integrated. Thus, storage capacity per unit area of the memory device of this embodiment can be increased.

The structures described in this embodiment can be used in an appropriate combination with the structures described in the other embodiments.

### Embodiment 6

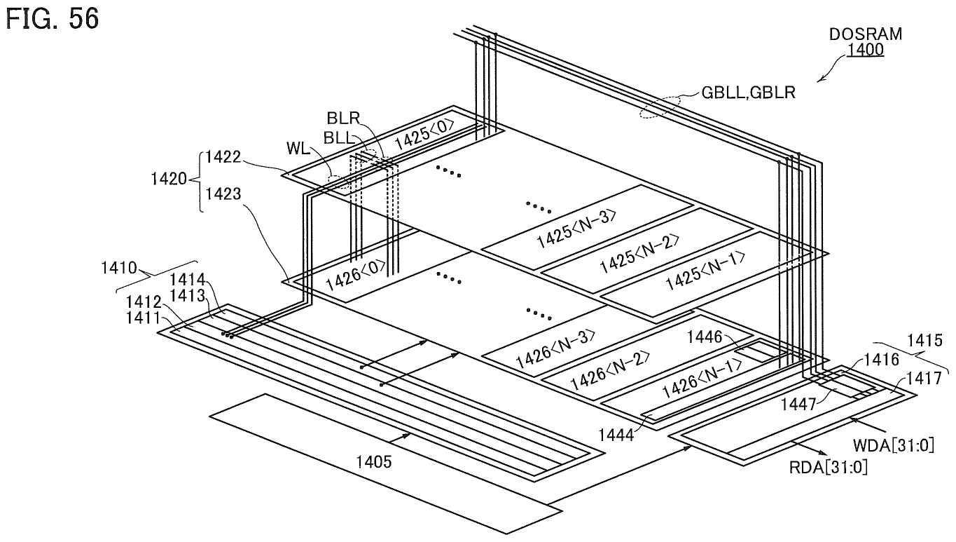

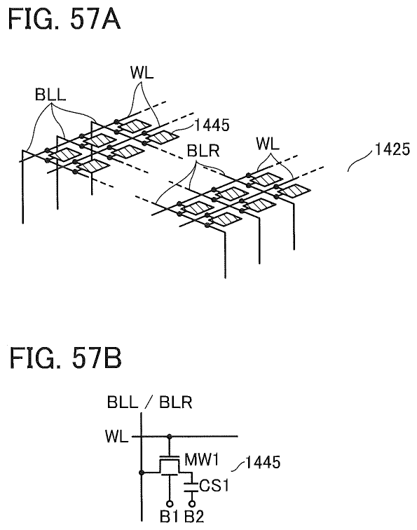

In this embodiment, a DOSRAM (registered trademark) is described with reference to FIG. 56 and FIG. 57 as an example of a memory device of one embodiment of the present invention in which a transistor using an oxide for a semiconductor (hereinafter referred to as an OS transistor) and a capacitor are applied. A DOSRAM is an abbreviation of “Dynamic Oxide Semiconductor RAM,” indicating a RAM including a 1T (transistor) 1C (capacitor) memory cell.

A memory device in which OS transistors are used in memory cells (hereinafter referred to as an “OS memory”) is used in a DOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

### <<DOSRAM 1400>>

FIG. 56 illustrates a structure example of a DOSRAM. As illustrated in FIG. 56, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as a bit-line structure, a hierarchical bit line structure hierarchized with local bit lines and global bit lines.

The memory cell array 1422 includes N local memory cell arrays 1425<0> to 1425<N−1> (N is an integer greater than or equal to 2). FIG. 57(A) illustrates a structure example of the local memory cell array 1425. The local memory cell array 1425 includes a plurality of memory cells 1445, a plurality of word lines WL, and a plurality of bit lines BLL and BLR. The local memory cell array 1425 has an open bit-line architecture in the example of FIG. 57(A) but may have a folded bit-line architecture.

FIG. 57(B) illustrates a circuit configuration example of the memory cell 1445. The memory cell 1445 includes a transistor MW1, a capacitor CS1, and terminals B1 and B2. The transistor MW1 has a function of controlling charging and discharging of the capacitor CS1. A gate of the transistor MW1 is electrically connected to the word line, a first terminal is electrically connected to the bit line, and a second terminal is electrically connected to a first terminal of the capacitor CS1. A second terminal of the capacitor CS1 is electrically connected to the terminal B2. A constant voltage (e.g., a low power supply voltage) is input to the terminal B2.

In the case where the semiconductor device described in the above embodiment is used for the memory cell 1445, the transistor 200a and the transistor 200b can be used as the transistor MW1, and the capacitors 100 can be used as the capacitor CS1. Thus, the area occupied by each set consisting of one transistor and one capacitor in the top view can be reduced, so that the memory device of this embodiment can be highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with the voltage of the terminal B1. For example, the voltage of the terminal B1 may be a fixed voltage (e.g., a negative constant voltage), or the voltage of the terminal B1 may be changed in response to the operation of the DOSRAM 1400.

The back gate of the transistor MW1 may be electrically connected to the gate, the first terminal, or the second terminal of the transistor MW1. Alternatively, the back gate is not necessarily provided for the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference between the bit line pair, and a function of retaining the voltage difference. The switch array 1444 has a function of selecting a bit line pair and bringing the selected bit line pair and a global bit line pair into a conduction state.

Here, the bit line pair refers to two bit lines which are compared by the sense amplifier at the same time. The global bit line pair refers to two global bit lines which are compared by the global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a target row that is to be accessed.

The column selector 1413 and the sense amplifier driver circuit 1414 are circuits for driving the sense amplifier array 1423. The column selector 1413 has a function of generating a selection signal for selecting the bit line of a target column that is to be accessed. With the selection signal from the column selector 1413, the switch array 1444 of each local sense amplifier array 1426 is controlled. With the control signal from the sense amplifier driver circuit 1414, the plurality of local sense amplifier arrays 1426 are independently driven.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference between the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data and retains the data. In the specified local memory cell array 1425, the word line WL of a target row is selected by the row circuit 1410, and the data retained at the local sense amplifier array 1426 is written to the memory cell 1445 of the selected row.

The read operation of the DOSRAM 1400 is briefly described. One row of the local memory cell arrays 1425 is specified by an address signal. In the specified local memory cell array 1425, the word line WL of a target row is in a selected state, and data of the memory cell 1445 is written to the bit line. The local sense amplifier array 1426 detects a voltage difference between the bit line pair of each column as data, and retains the data. Among the data retained at the local sense amplifier array 1426, the data of a column specified by the address signal is written to the global bit line pair by the switch array 1444. The global sense amplifier array 1416 detects and retains the data of the global bit line pair. The data retained at the global sense amplifier array 1416 is output to the input/output circuit 1417. Thus, the read operation is completed.

There is no limitation on the number of rewriting operations of the DOSRAM 1400 in principle because data is rewritten by charging and discharging of the capacitor CS1, and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM. This allows less frequent refresh, which can reduce power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, enabling a reduction in power consumption.

The structures described in this embodiment can be used in an appropriate combination with the structures described in the other embodiments.

### Embodiment 7

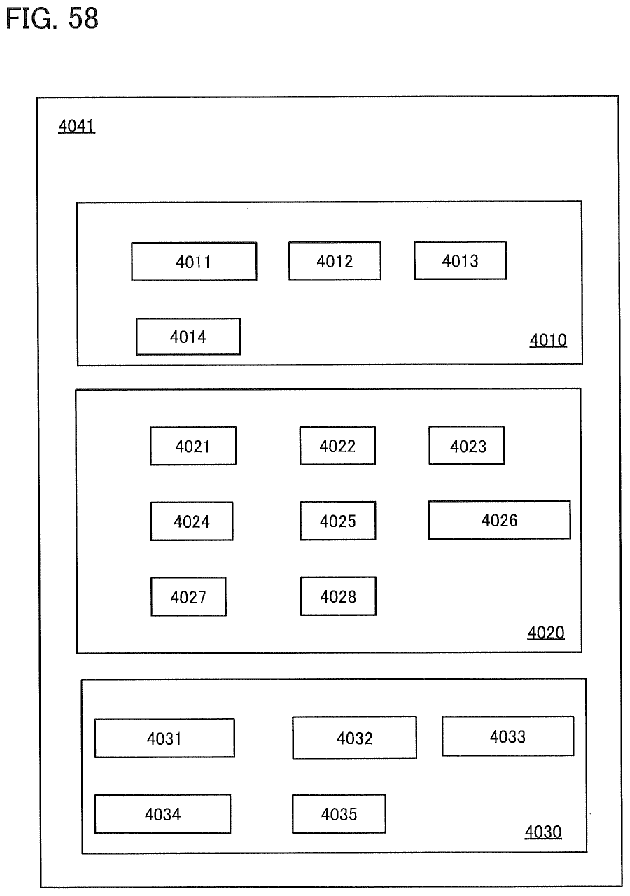

In this embodiment, an AI system in which the semiconductor device of the above embodiment is used is described with reference to FIG. 58.

FIG. 58 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400 described in the above embodiment can be used as the DOSRAM 4012.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for learning or inference with low power consumption.

The DOSRAM 4012 is a DRAM formed using an OS transistor, and the DOSRAM 4012 is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in the SRAM 4024, the input data have to be subdivided and stored because of the circuit area limitation and small storage capacity of the SRAM 4024. The DOSRAM 4012 has a larger storage capacity than the SRAM 4024 because the memory cells can be arranged to be highly integrated even in a limited circuit area. Therefore, the DOSRAM 4012 can efficiently store the input data.

The NOSRAM 4013 is a nonvolatile memory using an OS transistor. As in the DOSRAM, an OS memory can be used in the NOSRAM of this embodiment.

The NOSRAM 4013 consumes less power in data writing than the other nonvolatile memories such as a flash memory, a ReRAM (Resistive Random Access Memory), and an MRAM (Magnetoresistive Random Access Memory). Furthermore, unlike in a flash memory and a ReRAM, elements do not deteriorate by data writing and there is no limitation on the number of times of data writing.

Furthermore, the NOSRAM 4013 can store multilevel data of two or more bits as well as one-bit binary data. Storage of the multilevel data in the NOSRAM 4013 leads to a reduction in the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. In this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 can have a longer bit line than the DOSRAM 4012 and thus can have an increased storage capacity.

The FPGA 4014 is an FPGA using an OS transistor. In the FPGA of this embodiment, an OS memory can be used for a configuration memory and a register. Here, such an FPGA is referred to as an “OS-FPGA.” With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with a hardware. Establishing the connection of the neural network with a hardware enables higher speed performance.

The FPGA 4014 is an OS-FPGA. An OS-FPGA can have a smaller memory area than an FPGA including an SRAM. Thus, adding a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute calculation of the neural network quickly with low power consumption. In addition, the analog arithmetic circuit 4011, the DOSRAM 4012, the NOSRAM 4013, and the FPGA 4014 can be fabricated through the same manufacturing process. Therefore, the AI system 4041 can be fabricated at low cost.

Note that the arithmetic portion 4010 does not need to include all of the following: the DOSRAM 4012, the NOSRAM 4013, and the FPGA 4014. One or more selected from the DOSRAM 4012, the NOSRAM 4013, and the FPGA 4014 are provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Furthermore, part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and can execute the other product-sum operations in the GPU 4022. In this manner, the learning and inference can be executed at high speed.

The power supply circuit 4027 generates not only a low power supply potential for a logic circuit but also a potential for an analog operation. An OS memory may be used for the power supply circuit 4027. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation frequency is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute the neural network calculation at high speed with low power consumption.

Data used for the neural network calculation is stored in an external storage device (an HDD (Hard Disk Drive), an SSD (Solid State Drive), or the like) in many cases. Therefore, the A1 system 4041 preferably includes the external memory control circuit 4031 functioning as an interface with the external storage device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus), an I2C (Inter-Integrated Circuit), or the like, for example.

The AI system 4041 can perform learning or inference using data obtained via the Internet. For this reason, the AI system 4041 preferably includes the communication module 4035.

The analog arithmetic circuit 4011 may use a multi-level flash memory as an analog memory. However, the flash memory has a limitation on the number of rewriting times. In addition, the multi-level flash memory is extremely difficult to embed (to form the arithmetic circuit and the memory on the same die).

Alternatively, the analog arithmetic circuit 4011 may use a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

The structures described in this embodiment can be used in an appropriate combination with the structures described in the other embodiments.

### Embodiment 8

### <Application Example of AI System>

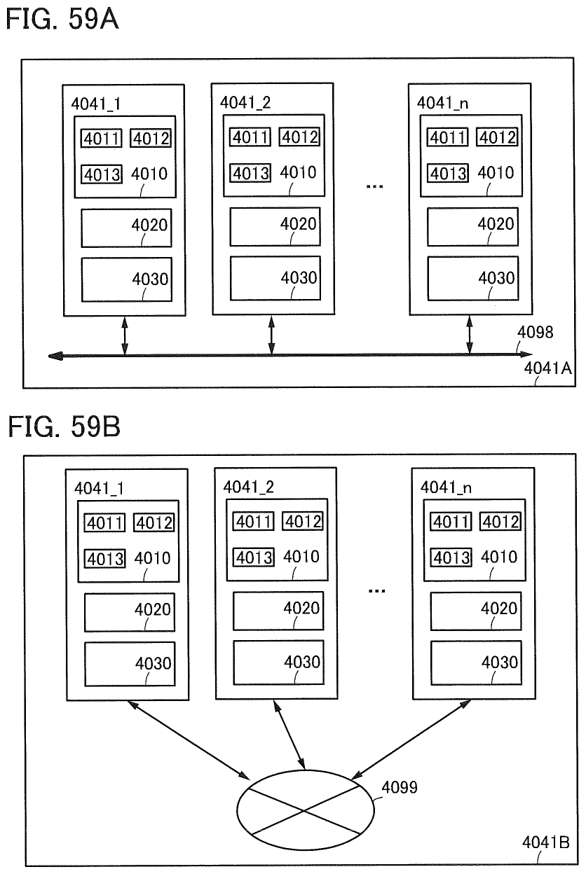

In this embodiment, application examples of the AI system described in the above embodiment are described with reference to FIG. 59.

FIG. 59(A) is an AI system 4041A in which the AI systems 4041 described with FIG. 58 are arranged in parallel and a signal can be transmitted between the systems via a bus line.

The AI system 4041A illustrated in FIG. 59(A) includes an AI system 4041_1 to an AI system 4041_n (n is a natural number). The AI system 4041_1 to the AI system 4041_n are connected to each other via a bus line 4098.

FIG. 59(B) is an AI system 4041B in which the AI systems 4041 described with FIG. 58 are arranged in parallel as in FIG. 59(A) and a signal can be transmitted between the systems via a network.

The AI system 4041B illustrated in FIG. 59(B) includes the AI system 4041_1 to the AI system 4041_n. The AI system 4041_1 to the AI system 4041_n are connected to each other via a network 4099.

A structure may be employed in which a communication module is provided for each of the AI system 4041_1 to the AI system 4041_n to perform wireless or wired communication via the network 4099. The communication module can perform communication via an antenna. For example, the communication can be performed in such a manner that each electronic device is connected to a computer network such as the Internet that is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a specification that is communication standardized by IEEE such as Wi-Fi (registered trademark), Bluetooth (registered trademark), or ZigBee (registered trademark).

With the structure in FIG. 59(A) or 59(B), analog signals obtained with external sensors or the like can be processed by different AI systems. For example, biological information such as brain waves, a pulse, blood pressure, and body temperature can be obtained with a variety of sensors such as a brain wave sensor, a pulse wave sensor, a blood pressure sensor, and a temperature sensor, and analog signals can be processed by different AI systems. When the signal processing or learning is performed by different AI systems, the amount of information processed by each AI system can be reduced. Accordingly, the signal processing or learning can be performed with a smaller amount of arithmetic processing. As a result, recognition accuracy can be increased. The information obtained with each AI system is expected to enable instant understanding of collective biological information that irregularly changes.

The structures described in this embodiment can be used in an appropriate combination with the structures described in the other embodiments.

### Embodiment 9

In this embodiment, an example of an IC incorporating the AI system described in the above embodiment is described.

In the AI system described in the above embodiment, a digital processing circuit including a Si transistor such as a CPU, an analog arithmetic circuit including an OS transistor, an OS-FPGA, and an OS memory such as a DOSRAM or a NOSRAM can be integrated into one die.

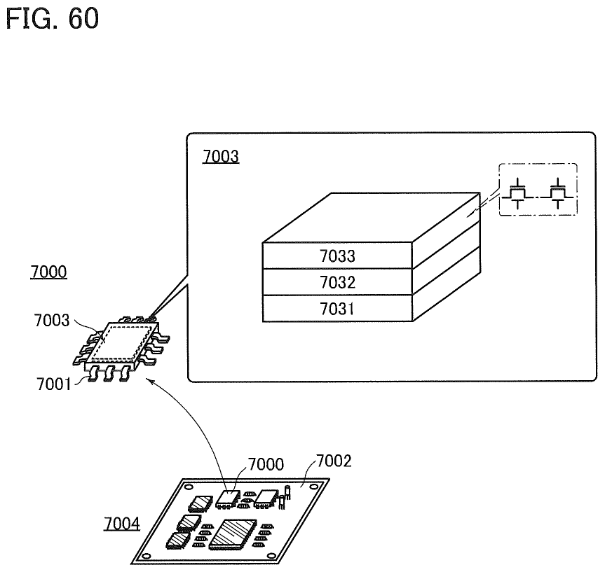

FIG. 60 illustrates the example of the IC incorporating the AI system. An AI system IC 7000 illustrated in FIG. 60 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a mounted board 7004) is completed. In the circuit portion 7003, the various circuits described in the above embodiment are provided on one die. The circuit portion 7003 has a stacked-layer structure, which is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 60, the embodiment of the package is not limited thereto.

The digital processing circuit such as a CPU, the analog arithmetic circuit including an OS transistor, the OS-FPGA, and the OS memory such as a DOSRAM or a NOSRAM can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated at low cost.

The structures described in this embodiment can be used in an appropriate combination with the structures described in the other embodiments.

### Embodiment 10

### <Electronic Device>

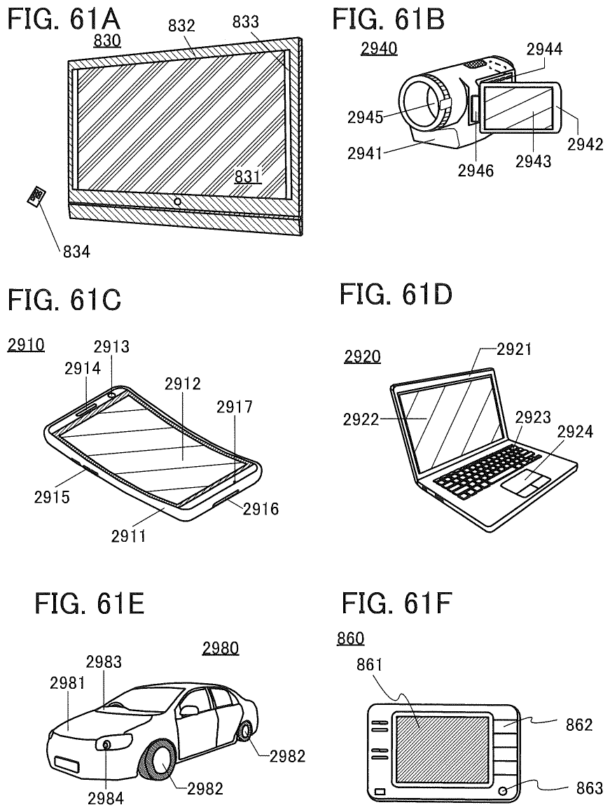

A semiconductor device of one embodiment of the present invention can be used for a variety of electronic devices. FIG. 61 illustrates specific examples of the electronic devices using the semiconductor device of one embodiment of the present invention.

FIG. 61(A) illustrates a monitor 830. The monitor 830 includes a display portion 831, a housing 832, a speaker 833, and the like. In addition, an LED lamp, operation keys (including a power switch or an operation switch), a connection terminal, a variety of sensors, a microphone, and the like can be included. The monitor 830 can be controlled with a remote controller 834.

The monitor 830 can function as a television device by receiving airwaves.

Examples of the airwaves the monitor 830 can receive include ground waves and waves transmitted from a satellite. Examples of the airwaves also include analog airwaves, digital airwaves, waves for image-and-sound broadcasting, and waves for sound-only broadcasting. For example, airwaves transmitted in a certain frequency band in a UHF band (higher than or equal to 300 MHz and lower than or equal to 3 GHz) or a VHF band (higher than or equal to 30 MHz and lower than or equal to 300 MHz) can be received. With the use of a plurality of pieces of data received in a plurality of frequency bands, for example, the transfer rate can be increased and more information can thus be obtained. Accordingly, the display portion 831 can display an image with a resolution higher than the full high definition. For example, an image with a resolution of 4K2K, 8K4K, 16K8K, or higher can be displayed.

A structure may be employed in which an image to be displayed on the display portion 831 is generated using broadcasting data transmitted with a technology for transmitting data via a computer network such as the Internet, a LAN (Local Area Network), or Wi-Fi (registered trademark). In that case, the monitor 830 does not need to include a tuner.

The monitor 830 can be used as a computer monitor when connected to a computer. Several people can see the monitor 830 connected to a computer at the same time; thus, the monitor 830 can be used for a conference system. The monitor 830 can also be used for a videoconference system by display of data in a computer via a network or connection of the monitor 830 itself to a network.

The monitor 830 can also be used as a digital signage.

The semiconductor device of one embodiment of the present invention can be used for, for example, a driver circuit or an image processing portion of the display portion. When the semiconductor device of one embodiment of the present invention is used for the driver circuit or the image processing portion of the display portion, high-speed operation or signal processing can be achieved with low power consumption.

When an AI system including the semiconductor device of one embodiment of the present invention is used for the image processing portion of the monitor 830, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, the number of grayscale levels of an image can be changed, and interpolation of the gray value in the case of increasing the number of grayscale levels can be performed. In addition, high-dynamic range (HDR) processing for increasing a dynamic range is also included in the grayscale conversion processing.

A video camera 2940 illustrated in FIG. 61(B) includes a housing 2941, a housing 2942, a display portion 2943, an operation switch 2944, a lens 2945, a connection portion 2946, and the like. The operation switch 2944 and the lens 2945 are provided on the housing 2941, and the display portion 2943 is provided on the housing 2942. The video camera 2940 also includes an antenna, a battery, and the like inside the housing 2941. A structure is employed in which the housing 2941 and the housing 2942 are connected to each other with the connection portion 2946 and the angle between the housing 2941 and the housing 2942 can be changed with the connection portion 2946. The orientation of an image displayed on the display portion 2943 may be changed and display and non-display of an image can be switched depending on the angle between the housing 2941 and the housing 2942.

The semiconductor device of one embodiment of the present invention can be used for, for example, a driver circuit or an image processing portion of the display portion. When the semiconductor device of one embodiment of the present invention is used for the driver circuit or the image processing portion of the display portion, high-speed operation or signal processing can be achieved with low power consumption.

When an AI system including the semiconductor device of one embodiment of the present invention is used for the image processing portion of the video camera 2940, imaging appropriate for the surroundings of the video camera 2940 can be performed. Specifically, imaging can be performed with optimal exposure for the surrounding brightness. In the case of performing imaging against the light or in the case of imaging landscapes with different brightness such as indoors and outdoors at the same time, high-dynamic-range (HDR) imaging can be performed.

Furthermore, the AI system can learn the user's habit and assist in performing imaging. Specifically, the AI system can learn the user's camera shaking habit and cancel the camera shaking during imaging, so that blurring of the obtained image associated with camera shaking can be reduced as much as possible. In the case of using a zoom function during imaging, the orientation of the lens or the like can be controlled such that a subject is positioned at the center of an image all the time.

An information terminal 2910 illustrated in FIG. 61(C) includes a housing 2911, a display portion 2912, a microphone 2917, a speaker portion 2914, a camera 2913, an external connection portion 2916, an operation switch 2915, and the like. A display panel and a touch screen formed using flexible substrates are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, or an e-book reader.

For example, a memory device using the semiconductor device of one embodiment of the present invention can retain control data, a control program, or the like of the information terminal 2910 for a long time.

When an AI system including the semiconductor device of one embodiment of the present invention is used for an image processing portion of the information terminal 2910, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, the number of grayscale levels of an image can be changed, and interpolation of the gray value in the case of increasing the number of grayscale levels can be performed. In addition, high-dynamic range (HDR) processing for increasing a dynamic range is also included in the grayscale conversion processing.

Furthermore, the AI system can learn the user's habit and assist in operating the information terminal 2910. The information terminal 2910 incorporating the AI system can predict touch input from the motion of the user's fingers, eyes, or the like.

A laptop personal computer 2920 illustrated in FIG. 61(D) includes a housing 2921, a display portion 2922, a keyboard 2923, a pointing device 2924, and the like. In addition, the laptop personal computer 2920 includes an antenna, a battery, and the like inside the housing 2921.

For example, a memory device using the semiconductor device of one embodiment of the present invention can retain control data, a control program, or the like of the laptop personal computer 2920 for a long time.

When an AI system including the semiconductor device of one embodiment of the present invention is used for an image processing portion of the laptop personal computer 2920, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, the number of grayscale levels of an image can be changed, and interpolation of the gray value in the case of increasing the number of grayscale levels can be performed. In addition, high-dynamic range (HDR) processing for increasing a dynamic range is also included in the grayscale conversion processing.

Furthermore, the AI system can learn the user's habit and assist in operating the laptop personal computer 2920. The laptop personal computer 2920 incorporating the AI system can predict touch input to the display portion 2922, from the motion of the user's fingers, eyes, or the like. In text inputting, the AI system predicts input from the past text inputting data or a text or a diagram such as a photograph around the text to be input, to assist conversion. Accordingly, input mistakes and conversion mistakes can be reduced as much as possible.

FIG. 61(E) is an external view illustrating an example of an automobile, and FIG. 61(F) illustrates a navigation device 860. An automobile 2980 includes a car body 2981, wheels 2982, a dashboard 2983, lights 2984, and the like. The automobile 2980 also includes an antenna, a battery, and the like. The navigation device 860 includes a display portion 861, an operation button 862, and an external input terminal 863. The automobile 2980 and the navigation device 860 can be independent of each other; however, it is preferred that a structure in which the navigation device 860 is incorporated into and linked to the automobile 2980 be employed.

A memory device using the semiconductor device of one embodiment of the present invention can retain control data, a control program, or the like of the automobile 2980 or the navigation device 860 for a long time, for example. When an AI system using the semiconductor device of one embodiment of the present invention is used for a control device or the like of the automobile 2980, the AI system can learn driver's driving skill and habit and assist in safe driving or driving involving efficient use of fuel such as gasoline or a battery. To assist in safe driving, the AI system learns not only driver's driving skill and habit, but also learns the behavior of the automobile such as the speed and movement of the automobile 2980, road information saved in the navigation device 860, and the like complexly; thus, driving lane departure can be prevented and collision with other automobiles, pedestrians, objects, and the like can be prevented. Specifically, when there is a sharp curve ahead, the navigation device 860 transmits the road information to the automobile 2980 so that the speed of the automobile 2980 can be controlled and steering can be assisted.

This embodiment can be implemented in appropriate combination with the structures described in the other embodiments and the like.

### REFERENCE NUMERALS

100 capacitor
100a capacitor
100b capacitor
120 insulator
130a conductor
130b conductor
200 transistor
200a transistor
200b transistor
201a transistor
201_b transistor
202a transistor
202b transistor
203_1 conductor
203_2 conductor
205 conductor
205_1 conductor
205_1a conductor
205_1b conductor
205_2 conductor
205_2a conductor
205_2b conductor
209 conductor
210 insulator
212 insulator
214 insulator
216 insulator
218 conductor
220 insulator
222 insulator
224 insulator
230 oxide
230_1c oxide
2302c oxide
230a oxide
230A oxide film
230b oxide
230B oxide film
230c oxide
230c_1 oxide
230_c2 oxide
230C oxide film
231 region
231a region
231b region
232 junction region
232a junction region
232b junction region
234 region
236 region
236a region
236b region
240 conductor
240a conductor
240b conductor
240c conductor
250 insulating film
250a insulator
250b insulator
252 insulating film
252a insulator
252b insulator
253 conductor
253a conductor
253b conductor
253c conductor
256 conductor
260 conductor
260_1 conductor
260_1a conductor
260_1b conductor
260_2 conductor
260_2a conductor
260_2b conductor
260A conductive film
260B conductive film
270 insulating film
270a insulator
270b insulator
271 insulating film
271a insulator
271b insulator
272 insulating film
272a insulator
272b insulator
274 insulating film
274a insulator
274b insulator
275 insulating film
275a insulator
275b insulator
280 insulator
300 transistor
311 substrate
313 semiconductor region
314a low-resistance region
314b low-resistance region
315 insulator
316 conductor
320 insulator
322 insulator
324 insulator
326 insulator
328 conductor
330 conductor
350 insulator
352 insulator
354 insulator
356 conductor
360 insulator
362 insulator
364 insulator
366 conductor
370 insulator
372 insulator
374 insulator
376 conductor
380 insulator
382 insulator
384 insulator
386 conductor
600 cell
600a cell
600b cell
830 monitor
831 display portion
832 housing
833 speaker
834 remote controller
860 navigation device
861 display portion
862 operation button
863 external input terminal
1400 DOSRAM
1405 controller
1410 row circuit
1411 decoder
1412 word line driver circuit
1413 column selector
1414 sense amplifier driver circuit
1415 column circuit
1416 global sense amplifier array
1417 input/output circuit
1420 sense amplifier array
1422 memory cell array
1423 sense amplifier array
1425 local memory cell array
1426 local sense amplifier array
1444 switch array
1445 memory cell
1446 sense amplifier
1447 global sense amplifier
1600 NOSRAM
1610 memory cell array
1611 memory cell
1612 memory cell
1613 memory cell
1614 memory cell
1615 memory cell
1615a memory cell
1615b memory cell
1640 controller
1650 row driver
1651 row decoder
1652 word line driver
1660 column driver
1661 column decoder
1662 driver
1663 DAC
1670 output driver
1671 selector
1672 ADC
1673 output buffer
2910 information terminal
2911 housing
2912 display portion
2913 camera
2914 speaker portion
2915 operation switch
2916 external connection portion
2917 microphone
2920 laptop personal computer
2921 housing
2922 display portion
2923 keyboard
2924 pointing device
2940 video camera
2941 housing
2942 housing
2943 display portion
2944 operation switch
2945 lens
2946 connection portion
2980 automobile
2981 car body
2982 wheel
2983 dashboard
2984 light
3001 wiring
3002 wiring
3003 wiring
3004a wiring
3004b wiring
3005a wiring
3005b wiring
3006a wiring
3006b wiring
3007 wiring
4010 arithmetic portion
4011 analog arithmetic circuit
4012 DOSRAM
4013 NOSRAM
4014 FPGA
4020 control portion
4021 CPU
4022 GPU
4023 PLL
4025 PROM
4026 memory controller
4027 power supply circuit
4028 PMU
4030 input/output portion
4031 external memory control circuit
4032 audio codec
4033 video codec
4034 general-purpose input/output module
4035 communication module
4041 AI system
4041_n AI system
4041_1 AI system
4041A AI system
4041B AI system
4098 bus line
4099 network
7000 AI system IC
7001 lead
7003 circuit portion
7031 Si transistor layer
7032 wiring layer
7033 OS transistor layer

What is claimed is:

1. A semiconductor device comprising an oxide in a channel formation region, comprising:
a first transistor;
a second transistor;
a first wiring;
a second wiring; and
a third wiring,
wherein the first transistor comprises:
the oxide over a first insulator;
a second insulator over the oxide;
a first conductor over the second insulator;
a third insulator over the first conductor; and
a fourth insulator in contact with the second insulator, the first conductor, and the third insulator,
wherein the second transistor comprises:
the oxide over the first insulator;
a fifth insulator over the oxide;
a second conductor over the fifth insulator;
a sixth insulator over the second conductor; and
a seventh insulator in contact with the fifth insulator, the second conductor, and the sixth insulator,
wherein the oxide comprises:
first regions overlapping with the second insulator and the fifth insulator;
second regions overlapping with the fourth insulator and the seventh insulator;
third regions in contact with the second regions; and
a fourth region in contact with the second regions and between the first conductor and the second conductor,
wherein the first wiring is electrically connected to the third region of the first transistor,
wherein the second wiring is electrically connected to the third region of the second transistor, and
wherein the third wiring is in contact with the fourth insulator and the seventh insulator and is electrically connected to the fourth region.

2. The semiconductor device according to claim 1,
wherein the oxide comprises In, an element M, and Zn, and
wherein the element M is Al, Ga, Y, or Sn.

3. The semiconductor device according to claim 1,
wherein the third regions and the fourth region have higher carrier density than the second regions, and
wherein the second regions have higher carrier density than the first regions.

4. The semiconductor device according to claim 1,
wherein the fourth insulator and the seventh insulator are each one or more selected from aluminum oxide, silicon oxynitride, and silicon nitride.

5. The semiconductor device according to claim 1,
wherein silicon oxynitride, aluminum oxide, and silicon nitride are stacked in this order in each of the fourth insulator and the seventh insulator.

6. A memory device wherein the semiconductor device according to claim 1 and a semiconductor device comprising silicon in a channel formation region are electrically connected to each other.

7. A semiconductor device comprising an oxide in a channel formation region, comprising:
a first transistor;
a second transistor;
a first wiring;
a second wiring; and
a third wiring,
wherein the first transistor comprises:
the oxide over a first insulator;
a second insulator over the oxide;
a first conductor over the second insulator;
a third insulator over the first conductor;
a fourth insulator in contact with the second insulator, the first conductor, and the third insulator; and
a fifth insulator in contact with the fourth insulator,
wherein the second transistor comprises:
the oxide over the first insulator;
a sixth insulator over the oxide;
a second conductor over the sixth insulator;
a seventh insulator over the second conductor;
an eighth insulator in contact with the sixth insulator, the second conductor, and the seventh insulator; and
a ninth insulator in contact with the eighth insulator,
wherein the oxide comprises:
first regions overlapping with the second insulator and the sixth insulator;
second regions overlapping with the fourth insulator and the eighth insulator;
third regions in contact with the second regions; and
fourth regions in contact with the third regions,
wherein the first wiring is electrically connected to the fourth region of the first transistor,
wherein the second wiring is electrically connected to the fourth region of the second transistor,
wherein the third wiring is in contact with the fifth insulator and the ninth insulator and is electrically connected to the fourth region.

8. The semiconductor device according to claim 7,
wherein the oxide comprises In, an element M, and Zn, and
wherein the element M is Al, Ga, Y, or Sn.

9. The semiconductor device according to claim 7,
wherein the fourth regions have higher carrier density than the third regions,
wherein the third regions have higher carrier density than the second regions, and
wherein the second regions have higher carrier density than the first regions.

10. The semiconductor device according to claim 7,
wherein the fourth insulator and the eighth insulator each comprise a metal oxide.

11. The semiconductor device according to claim 7,
wherein the fifth insulator and the ninth insulator are each one or more selected from aluminum oxide, silicon oxide, silicon oxynitride, silicon nitride oxide, and silicon nitride.

12. The semiconductor device according to claim 7,
wherein silicon oxynitride and silicon nitride are stacked in this order in each of the fifth insulator and the ninth insulator.

13. A memory device wherein the semiconductor device according to claim 7 and a semiconductor device comprising silicon in a channel formation region are electrically connected to each other.

14. A method for manufacturing a semiconductor device, comprising the steps of:
forming a first insulator over a substrate;
forming an oxide layer over the first insulator;
forming a first insulating film, a first conductive film, and a second insulating film in this order over the oxide layer;
processing the first insulating film, the first conductive film, and the second insulating film to form a second insulator, a third insulator, a first conductor, a second conductor, a fourth insulator, and a fifth insulator;
forming a third insulating film and a fourth insulating film in this order so as to cover the first insulator, the oxide layer, the second insulator, the third insulator, the first conductor, the second conductor, the fourth insulator, and the fifth insulator;
processing the third insulating film and the fourth insulating film to form a sixth insulator, a seventh insulator, an eighth insulator in contact with the sixth insulator, and a ninth insulator in contact with the seventh insulator;
forming a fifth insulating film so as to cover the first insulator, the oxide layer, the eighth insulator, and the ninth insulator;
processing the fifth insulating film to form a tenth insulator in contact with a side surface of the eighth insulator and an eleventh insulator in contact with a side surface of the ninth insulator;
forming a twelfth insulator over the first insulator, the oxide layer, the tenth insulator, and the eleventh insulator;
forming a first opening, a second opening, and a third opening in the twelfth insulator;
forming a third conductor so as to fill the first opening;
forming a fourth conductor so as to fill the second opening; and
forming a fifth conductor is formed so as to fill the third opening.

15. The method for manufacturing a semiconductor device, according to claim 14,
wherein the first opening is formed so as to expose part of the tenth insulator, a top surface of the oxide layer, and at least part of a side surface of the oxide layer,
wherein the second opening is formed so as to expose part of the eleventh insulator, the top surface of the oxide layer, and at least part of the side surface of the oxide layer,
wherein the third opening is formed so as to expose part of the tenth insulator, part of the eleventh insulator, the top surface of the oxide layer, and at least part of the side surface of the oxide layer, and
wherein the third opening is formed between the first opening and the second opening.

16. The method for manufacturing a semiconductor device, according to claim 14,
wherein the third insulating film and the fourth insulating film are processed by anisotropic etching utilizing a dry etching method.

17. The method for manufacturing a semiconductor device, according to claim 14,
wherein the fifth insulating film is processed by anisotropic etching utilizing a dry etching method.
